(19) United States
(12) Patent Application Publication
(10) Pub. No.: US 2025/0341459 A1
(43) Pub. Date: Nov. 6, 2025

(54) TAMM POLARITON EMITTERS AND METHODS OF MAKING AND USE THEREOF

(71) Applicants: VANDERBILT UNIVERSITY, Nashville, TN (US); THE PENN STATE RESEARCH FOUNDATION, University Park, PA (US)

(72) Inventors: Joshua D. CALDWELL, Nashville, TN (US); Jon-Paul MARIA, University Park, PA (US); Mingze HE, Nashville, TN (US); Joshua Ryan NOLEN, Nashville, TN (US); Joshua NORDLANDER, University Park, PA (US); Angela CLERI, University Park, PA (US)

(21) Appl. No.: 18/854,244

(22) PCT Filed: Apr. 6, 2023
(86) PCT No.: PCT/US2023/017674

§ 371 Date: Oct. 4, 2024

Related U.S. Application Data
(60) Provisional application No. 63/327,982, filed on Apr. 6, 2022.

(51) Int. Cl. G01N 21/25; G01N 21/3504

(52) U.S. Cl. CPC G01N 21/255; G01N 21/3504; G01N 2201/061; G01N 2201/0636

(57) ABSTRACT

Disclosed herein are Tamm polariton emitters and methods of making and use thereof. The Tamm polariton emitters disclosed herein comprise: a distributed Bragg reflector; and a layer comprising a conductive and/or polaritonic material; wherein the distributed Bragg reflector is disposed on the layer of the conductive and/or polaritonic material. The Tamm polariton emitters can further include a layer of a polar material. Also disclosed herein are non-dispersive infrared sensors comprising: any of the Tamm polariton emitters disclosed herein, wherein the Tamm polariton emitter is configured to selectively emit radiation at a frequency corresponding to a rotational or vibrational resonance frequency of an analyte of interest; and a detector configured to receive an electromagnetic signal from the Tamm polariton emitter and/or the analyte of interest. Also disclosed herein are methods for designing Tamm polariton emitters. The methods can, for example, comprise an inverse design protocol and/or machine learning.

### CROSS-REFERENCE TO RELATED APPLICATIONS

This application claims the benefit of priority to U.S. Provisional Application No. 63/327,982 filed Apr. 6, 2022, which is hereby incorporated herein by reference in its entirety.

### STATEMENT OF GOVERNMENT SUPPORT

This invention was made with government support under Grant No. N00014-18-1-2107 awarded by the Office of Naval Research. The government has certain rights in the invention.

### BACKGROUND

Wavelength-selective thermal emitters (WS-EMs) are of interest due to the lack of cost-effective, narrow-band sources in the mid- to long-wave infrared. Most proposed Wavelength-selective thermal emitters employ patterned nanostructures, thereby requiring high-cost, low-throughput lithographic methods, and are therefore inappropriate for many applications. An alternative solution is Tamm polariton heterostructures. Despite the broad potential of Tamm polariton emitters, design of such structures is challenging.

Wavelength-selective thermal and methods of making thereof are still needed. The compositions, devices, methods, and systems discussed herein address these and other needs.

### SUMMARY

In accordance with the purposes of the disclosed compositions, devices, methods, and systems as embodied and broadly described herein, the disclosed subject matter relates to Tamm polariton emitters and methods of making and use thereof.

For example, disclosed herein are Tamm polariton emitters comprising: a distributed Bragg reflector; and a layer comprising a conductive and/or polaritonic material; wherein the distributed Bragg reflector is disposed on the layer of the conductive and/or polaritonic material.

In some examples, the Tamm polariton emitter further comprises a layer of a polar material disposed on top of the distributed Bragg reflector, such that the distributed Bragg reflector is sandwiched between the layer of the conductive and/or polaritonic material and the polar material.

Also disclosed herein are Tamm polariton emitters comprising: a layer of a polar material; a distributed Bragg reflector; and a layer comprising a conductive and/or polaritonic material; wherein the distributed Bragg reflector is disposed on the layer of the conductive and/or polaritonic material; and wherein: the layer of the polar material is disposed on top of the distributed Bragg reflector, such that the distributed Bragg reflector is sandwiched between the layer of the conductive and/or polaritonic material and the polar material: or the layer of the polar material is disposed below the layer of the conductive and/or polaritonic material, such that the layer of the conductive and/or polaritonic material is sandwiched between the layer of the polar material and the distributed Bragg reflector.

In some examples, the polar material layer has an average thickness of from 1 nanometer (nm) to 100 millimeters (mm). In some examples, the polar material comprises hexagonal boron nitride, silicon carbide, aluminum nitride, gallium nitride, or a combination thereof. In some examples, the polar material comprises hexagonal boron nitride.

In some examples, the Tamm polariton emitter further comprises a substrate, wherein: the layer of the conductive and/or polaritonic material is disposed on the substrate, and the layer of the conductive and/or polaritonic material is sandwiched between the substrate and the distributed Bragg reflector: the distributed Bragg reflector is disposed on the substrate, and the distributed Bragg reflector is sandwiched between the substrate and the layer of the conductive and/or polaritonic material; the layer of the polar material is present and is disposed on the substrate, and the layer of the polar material is sandwiched between the substrate and the distributed Bragg reflector: or the layer of the polar material is present and is disposed on the substrate, and the layer of the polar material is sandwiched between the substrate and the layer of the conductive and/or polaritonic material.

In some examples, the layer of the conductive and/or polaritonic material comprises a polaritonic material. In some examples, the polaritonic material comprises a phonon polariton material. In some examples, the polaritonic material has a tunable carrier density. In some examples, the polaritonic material comprises a transparent conducting oxide, a group III-V semiconductor, or a combination thereof. In some examples, the polaritonic material comprises a transparent conducting oxide. In some examples, the polaritonic material comprises a cadmium oxide. In some examples, the polaritonic material further comprises a dopant. In some examples, the presence and/or concentration of the dopant tunes the carrier density of the polaritonic material. In some examples, the polaritonic material comprises doped cadmium oxide, such as n-doped cadmium oxide. In some examples, the polaritonic material comprises n-type In-doped CdO.

In some examples, the layer of the of the conductive and/or polaritonic material has an average thickness of from 1 nanometer (nm) to 100 millimeters (mm). In some examples, the layer of the conductive and/or polaritonic material has a carrier density of from 1×10¹⁰ cm⁻³ to 1×10²⁵ cm⁻³.

In some examples, the distributed Bragg reflector comprises an aperiodic distributed Bragg reflector. In some examples, the distributed Bragg reflector comprises a plurality of layers of a plurality of materials with varying refractive index. In some examples, the distributed Bragg reflector comprises a plurality of alternating layers of a first material having a first refractive index and a second material having a second refractive index, wherein the first refractive index and the second refractive index are different. In some examples, the first material comprises Ge. In some examples, the second material comprises an aluminum oxide or ZnSe. In some examples, the total number of layers is from 1 to 10,000. In some examples, each of the plurality of layers independently has an average thickness of from 1 nanometer (nm) to 100 millimeters (mm).

In some examples, the Tamm polariton emitter emits radiation at a frequency, said frequency being an emission frequency. In some examples, the Tamm polariton emitter has a single emission frequency. In some examples, the Tamm polariton emitter has a plurality of emission frequencies. In some examples, the Tamm polariton emitter has an emission frequency in the visible spectral region. In some examples, the Tamm polariton emitter has an emission frequency in the ultraviolet spectral region. In some examples, the Tamm polariton emitter has an emission frequency in the terahertz spectral region. In some examples, the Tamm polariton emitter has an emission frequency in the infrared spectral region. In some examples, the Tamm polariton emitter has an emission frequency in the short- to long-wave infrared spectral region, in the mid-to long-wave infrared region, in the long-wave infrared region to the telecommunications band region, or a combination thereof.

In some examples, the Tamm polariton emitter comprises a Tamm plasmon polariton emitter, a Tamm phonon polariton emitter, or a Tamm hybrid polariton emitter.

Also disclosed herein are methods of making any of the Tamm polariton emitters disclosed herein. In some examples, the method comprises disposing the distributed Bragg reflector on the layer of the conductive and/or polaritonic material. In some examples, the method comprises complementary metal-oxide-semiconductor (CMOS) processing.

Also disclosed herein are methods of use of any of the Tamm polariton emitters disclosed herein, for example in a free-space communication application, as a beacon, in a bar-code application, in an encryption application, in a sensing application, or a combination thereof.

Also disclosed herein are infrared beacons comprising any of the Tamm polariton emitters disclosed herein. Also disclosed herein are methods of use of the infrared beacons, for example in a search and rescue, police, and/or military application.

Also disclosed herein are sensors comprising any of the Tamm polariton emitters disclosed herein.

Also disclosed herein are non-dispersive infrared sensors comprising: any of the Tamm polariton emitters disclosed herein, wherein the Tamm polariton emitter is configured to selectively emit radiation at a frequency corresponding to a rotational or vibrational resonance frequency of an analyte of interest; and a detector configured to receive an electromagnetic signal from the Tamm polariton emitter and/or the analyte of interest. In some examples, the sensor further comprises a fluid cell extending from a proximal end to distal end and having an inlet and an outlet, wherein the Tamm polariton emitter is disposed towards the proximal end of the fluid cell and the detector is disposed towards the distal end of the fluid cell, such that, when the sensor is assembled together with a fluid sample, the fluid cell is configured to contain the fluid sample and the detector is configured to receive an electromagnetic signal from the Tamm polariton emitter and/or the fluid sample. In some examples, the detector is configured to selectively receive the electromagnetic signal from the Tamm polariton emitter and/or the analyte of interest. In some examples, the detector comprises a Tamm polariton detector, the Tamm polariton detector comprising the Tamm polariton emitter of any one of claims 1-35. In some examples, the Tamm polariton emitter and/or the Tamm polariton detector (when present) independently comprise a Tamm plasmon polariton emitter, a Tamm phonon polariton emitter, or a Tamm hybrid polariton emitter. In some examples, the sensor further comprises a computing device configured to receive and process a signal from the detector to determine a property of the fluid sample. In some examples, the sensor is further configured to output the property of the fluid sample and/or a feedback signal based on the property of the fluid sample. In some examples, the feedback signal comprises haptic feedback, auditory feedback, visual feedback, or a combination thereof. In some examples, the property of the fluid sample comprises the presence of the analyte of interest in the fluid sample, the concentration of the analyte of interest in the fluid sample, the identity of the analyte of interest, or a combination thereof. In some examples, the fluid sample comprises a gaseous sample. In some examples, the analyte of interest comprises a gas. In some examples, the analyte of interest comprises a plurality of analytes.

In some examples, the analyte of interest comprises a plurality of analytes, and: the Tamm polariton emitter is configured to selectively emits radiation at a plurality of frequencies; or the sensor comprises a plurality of Tamm polariton emitters, wherein each of the plurality of Tamm polariton emitters is configured to selectively emit radiation at a frequency such that the plurality of Tamm polariton emitters are selectively configured to emit radiation at a plurality of frequencies; and wherein at least a portion of each of the plurality of frequencies corresponds to a rotational or vibrational resonance frequency of each of the plurality of analytes of interest, such that the sensor can detect the plurality of analytes simultaneously.

In some examples, the detector comprises a Tamm polariton detector and the Tamm polariton detector is configured to selectively receive radiation at the plurality of frequencies; or the detector comprises a plurality of Tamm polariton detectors, wherein each of the plurality of Tamm polariton detectors is configured to selectively receive radiation at a frequency such that the plurality of Tamm polariton detectors are selectively configured to receive radiation at the plurality of frequencies.

In some examples, the analyte of interest comprises a single analyte, and: the Tamm polariton emitter is configured to selectively emit radiation at a plurality of frequencies; or the sensor comprises a plurality of Tamm polariton emitters, wherein each of the plurality of Tamm polariton emitters is configured to selectively emit radiation at a frequency such that the plurality of Tamm polariton emitters are selectively configured to emit radiation at a plurality of frequencies; and wherein at least a portion of each of the plurality of frequencies corresponds to a plurality of rotational or vibrational resonance frequencies of the analyte of interest, such that the sensor can detect the analyte of interest with high sensitivity.

In some examples, the detector comprises a Tamm polariton detector and the Tamm polariton detector is configured to selectively receive radiation at the plurality of frequencies; or the detector comprises a plurality of Tamm polariton detectors, wherein each of the plurality of Tamm polariton detectors is configured to selectively receive radiation at a frequency such that the plurality of Tamm polariton detectors are selectively configured to receive radiation at the plurality of frequencies.

In some examples, the analyte of interest comprises a toxin, a contaminant, a pollutant, a warfare agent, or a combination thereof. In some examples, the analyte of interest comprises a greenhouse gas. In some examples, the analyte of interest comprises a gas used, produced in, and/or produced as a by-product of semiconductor fabrication, industrial manufacture, chemical synthesis, or a combination thereof. In some examples, the analyte of interest is a gas or chemical that needs to be maintained at a certain concentration. In some examples, the analyte of interest comprises CO₂, SO₂, formaldehyde. CO, NH₃, N₂O, O₃, CH₄. NO, dimethyl methyl phosphonate (DMMP), or a combination thereof.

In some examples, the sensor is filterless.

Also disclosed herein are methods of use of any of the sensors disclosed herein, for example for gas sensing. Also disclosed herein are methods of use of any of the sensors disclosed herein, for example for environmental sensing, atmospheric sensing, chemical sensing, or a combination thereof.

Also disclosed herein are methods for designing any of the Tamm polariton emitters disclosed herein. In some examples, the method comprises an inverse design protocol. In some examples, the method comprises machine learning.

Also disclosed herein are methods for designing a Tamm polariton emitter, the Tamm polariton emitter comprising: a distributed Bragg reflector, the distributed Bragg reflector comprising a stack of a plurality of layers of a plurality of materials with varying refractive index, wherein each layer comprises a material having a refractive index and each layer has an average thickness, wherein the refractive index of each layer is different than the preceding and/or subsequent layer; and a layer comprising a conductive and/or polaritonic material; wherein the distributed Bragg reflector is disposed on the layer of the conductive and/or polaritonic material; wherein the Tamm polariton emitter emits radiation at a frequency; wherein the method comprises: a) defining a target spectrum for the radiation emitted by the Tamm polariton emitter; b) defining an initial set of values for a set of parameters for a designed Tamm polariton emitter; wherein the set of parameters comprises the total number of layers of the distributed Bragg reflector, the composition of each of the plurality of layers, the thickness of each of the plurality of layers, the composition of the layer of the conductive and/or polaritonic material, the carrier density of the layer of the conductive and/or polaritonic material, and the thickness of the layer of the conductive and/or polaritonic material; wherein, for the initial set of values, the initial total number of layers is user defined and the remaining parameters are randomly initialized; c) modeling an emission spectrum for the designed Tamm polariton emitter having the initial set of parameters, written as vector (t), said modeled emission spectrum being a designed emission spectrum; d) comparing the designed emission spectrum to the target emission spectrum to determine an error; wherein the designed emission spectrum is modeled and compared with the target emission spectrum using a transfer matrix method; wherein the error is a scalar error that is a combination of mean-squared error and mean absolute error; when the error is greater than a predefined threshold, then the error is back-propagated to find a gradient over t via stochastic gradient descent, and the gradient is used to update t in the next iteration of steps c and d:

$${t}_{n} = {t}_{n - 1} - step \frac{\partial {error}_{n - 1}}{\partial {t}_{n - 1}}$$

wherein the iterations continue until the predefined maximum number of iterations is reached or the error is minimized; when the number of iterations reaches the predefined maximum number without reaching the error threshold, then the number of layers is increased and the method is repeated; and when the error is less than or equal to the defined threshold, then the method comprises outputting the set of parameters, the designed emission spectrum, the target emission spectrum, or a combination thereof.

Also disclosed herein are methods for designing a Tamm polariton emitter, the Tamm polariton emitter comprising: a layer of a polar material; a distributed Bragg reflector, the distributed Bragg reflector comprising a stack of a plurality of layers of a plurality of materials with varying refractive index, wherein each layer comprises a material having a refractive index and each layer has an average thickness, wherein the refractive index of each layer is different than the preceding and/or subsequent layer; and a layer comprising a conductive and/or polaritonic material; wherein the distributed Bragg reflector is disposed on the layer of the conductive and/or polaritonic material; wherein the layer of the polar material is disposed on top of the distributed Bragg reflector, such that the distributed Bragg reflector is sandwiched between the layer of the conductive and/or polaritonic material and the polar material; wherein the Tamm polariton emitter emits radiation at a frequency; wherein the method comprises: a) defining a target spectrum for the radiation emitted by the Tamm polariton emitter; b) defining an initial set of values for a set of parameters for a designed Tamm polariton emitter: wherein the set of parameters comprises the total number of layers of the distributed Bragg reflector, the composition of each of the plurality of layers, the thickness of each of the plurality of layers, the composition of the layer of the conductive and/or polaritonic material, the carrier density of the layer of the conductive and/or polaritonic material, the thickness of the layer of the conductive and/or polaritonic material; the composition of the layer of the polar material, the carrier density of the layer of the polar material, and the thickness of the layer of the polar material; wherein, for the initial set of values, the initial total number of layers is user defined and the remaining parameters are randomly initialized; c) modeling an emission spectrum for the designed Tamm polariton emitter having the initial set of parameters, written as vector (t), said modeled emission spectrum being a designed emission spectrum; d) comparing the designed emission spectrum to the target emission spectrum to determine an error; wherein the designed emission spectrum is modeled and compared with the target emission spectrum using a transfer matrix method; wherein the error is a scalar error that is a combination of mean-squared error and mean absolute error; when the error is greater than a predefined threshold, then the error is back-propagated to find a gradient over t via stochastic gradient descent, and the gradient is used to update t in the next iteration of steps c and d:

$${t}_{n} = {t}_{n - 1} - \frac{\partial {error}_{n - 1}}{\partial {t}_{n - 1}}$$

wherein the iterations continue until the predefined maximum number of iterations is reached or the error is minimized: when the number of iterations reaches the predefined maximum number without reaching the error threshold, then the number of layers is increased and the method is repeated; and when the error is less than or equal to the defined threshold, then the method comprises outputting the set of parameters, the designed emission spectrum, the target emission spectrum, or a combination thereof.

In some examples, the error is defined by the following equation

$$Error = Mean ( ratio 1 {( DS - TS )}^{2} + r a tio 2 \vert DS - TS \vert )$$

where ratio1 and ratio2 are hyperparameters customized for different purposes, and DS and TS are vectors with each element standing for the absorptance at corresponding wavelength.

In some examples, steps c and/or d of the method includes a weighted sampling technique. In some examples, the weighted sample technique is based on the desired application, frequency region of interest, analyte of interest, or a combination thereof. In some examples, the parameters further include the frequency, amplitude, and/or line-width of the emitted radiation.

In some examples, the parameters further include a quality factor (e.g., Q factor). In some examples, the Q factor is from 1 to 1,000,000.

In some examples, the Tamm polariton emitter comprises any of the Tamm polariton emitters disclosed herein.

In some examples, the method comprises machine learning.

In some examples, the Tamm polariton emitter comprises a plurality of Tamm polariton emitters and the parameters further include the number of Tamm polariton emitters in the plurality of Tamm polariton emitters.

In some examples, the method comprises designing a first Tamm polariton emitter and a second Tamm polariton emitter, wherein the second Tamm polariton emitter comprises a Tamm polariton detector. In some examples, the first Tamm polariton emitter is configured to selectively emit radiation at one or more frequencies and the second Tamm polariton emitter is configured to selectively receive at least a portion of the radiation emitted by the first Tamm polariton emitter (e.g., the first Tamm polariton emitter and the Tamm polariton detector are matched). In some examples, the method further comprises maximizing the overlap between the radiation emitted by the Tamm polariton emitter and the radiation received by the detector. In some examples, the first Tamm polariton emitter comprises a first plurality of Tamm polariton emitters, the second Tamm polariton emitter comprises a second plurality of Tamm polariton emitters, or a combination thereof. In some examples, the first Tamm polariton emitter comprises a first plurality of Tamm polariton emitters and the parameters include the number of first Tamm polariton emitters in the first plurality, the second Tamm polariton emitter comprises a second plurality of Tamm polariton emitters and the parameters include the number of second Tamm polariton emitters in the plurality, or a combination thereof.

Additional advantages of the disclosed compositions, devices, systems, and methods will be set forth in part in the description which follows, and in part will be obvious from the description. The advantages of the disclosed compositions, devices, systems, and methods will be realized and attained by means of the elements and combinations particularly pointed out in the appended claims. It is to be understood that both the foregoing general description and the following detailed description are exemplary and explanatory only and are not restrictive of the disclosed compositions, devices, systems, and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure.

FIG. 1. Flowchart of the design process. Left: the designable parameters of the Tamm plasmon polariton emitter structure (thickness and carrier concentration), t, are randomly initialized (green box): then it is evaluated by the transfer matrix method, resulting in the designed spectrum. The designed spectrum is compared with the target spectrum, leading to a scalar error. In the current iteration (n−1), the gradient of scalar error over tₙ₋₁, that is,

$$\frac{\partial {error}_{n - 1}}{\partial {t}_{n - 1}}$$

is calculated by stochastic gradient descent and used to update tₙ₋₁ to tₙ by equation (2). The updated tₙ will then be evaluated by transfer matrix method, getting anew designed spectrum, comparing with target spectrum and updating to a new version; and the process will repeat until a given number of iterations are reached. Right: the optimized structure.

FIG. 2. Schematic illustration of an exemplary optimizing process; the target spectrum are plotted in dashed lines, and the designed spectrum are plotted as solid lines with different colors each pertaining to a different point along the iteration path. One photo of the two-inch wafer-scale sample is shown in FIG. 19.

FIG. 3. Experimental demonstration of Tamm plasmon polariton emitters. The inverse design algorithm was employed to realize Tamm plasmon polariton emitter structures featuring a single emission mode in the long-wave infrared with a three-layer distributed Bragg reflector. The target spectrum and designed spectrum are plotted as blue dashed and solid lines, respectively. The emissivity experimentally measured at 150° C. is plotted as red solid lines, and red dashed lines are the calculated absorption spectra of as-grown structures.

FIG. 4. Experimental demonstration of Tamm plasmon polariton emitters. The inverse design algorithm was employed to realize Tamm plasmon polariton emitter structures featuring a resonant emission designed for non-dispersive infrared sensing of CO₂ with a three-layer distributed Bragg reflector. The target spectrum and designed spectrum are plotted as blue dashed and solid lines, respectively. The emissivity experimentally measured at 150° C. is plotted as red solid lines, and red dashed lines are the calculated absorption spectra of as-grown structures.

FIG. 5. Experimental demonstration of Tamm plasmon polariton emitters. The inverse design algorithm was employed to realize Tamm plasmon polariton emitter structures featuring resonant emission designed for non-dispersive infrared sensing of CO₂ and SO₂ with a five-layer distributed Bragg reflector. The target spectrum and designed spectrum are plotted as blue dashed and solid lines, respectively. The emissivity experimentally measured at 150° C. is plotted as red solid lines, and red dashed lines are the calculated absorption spectra of as-grown structures. Green dashed curves are the combined absorption spectrum of the gases.

FIG. 6. Experimental demonstration of Tamm plasmon polariton emitters. The inverse design algorithm was employed to realize Tamm plasmon polariton emitter structures featuring resonant emission designed for non-dispersive infrared sensing of CO and formaldehyde dual-gas sensing with a seven-layer distributed Bragg reflector. The target spectrum and designed spectrum are plotted as blue dashed and solid lines, respectively. The emissivity experimentally measured at 150° C. is plotted as red solid lines, and red dashed lines are the calculated absorption spectra of as-grown structures. Green dashed curves are the combined absorption spectrum of the gases.

FIG. 7. Inversely designed Tamm plasmon polariton emitters for isolated emission with different Q-factors. The same figure is provided with a narrower frequency range (FIG. 42) to show near-unity emission for all of them.

FIG. 8. Inversely designed multiple-peak Tamm plasmon polariton emitter.

FIG. 9. Inversely designed Tamm plasmon polariton emitter featuring emissions at long-wave infrared, mid-wave infrared, and the telecommunication range simultaneously.

FIG. 10. Inversely designed Tamm plasmon polariton emitters for matching the absorption spectrum of nitrogen monoxide (NO) gas for filterless non-dispersive infrared. The absorption spectrum of NO is normalized to be between 0 and 1.

FIG. 11. Tamm plasmon polariton emitter designs targeting the dimethyl methyl phosphonate (DMMP) spectrum with CdO and gold as conductive layers.

FIG. 12. Functionality enabled by the tunability of CdO plasma frequency. The emissivity (red lines, experimental data) and reflectance (black lines, calculated by transfer matrix method) of the same distributed Bragg reflector on CdO layers of different carrier densities and on a sapphire substrate. The plasma frequency of CdO with a carrier density of 7×10¹⁹ cm⁻³ is displayed by the vertical dashed line, while the plasma frequency of the other CdO is above 4,000 cm 1. The emissivity of the low-doped CdO has several notable differences from that of the higher-doped heterostructure. (1) The Tamm resonance frequency is lower and exhibits a higher absorption intensity between 1,000 and 2,000 cm⁻¹; (2) there is a stronger absorption at the reflection dip of the distributed Bragg reflector (˜2,300 cm⁻¹), which is not a Tamm mode; and (3) Tamm resonances are not supported above the plasma frequency (˜3,500 cm⁻¹).

FIG. 13. Spectrum in full range, same structure in FIG. 9. Semi-transparent boxes are the frequency ranges shown in FIG. 9.

FIG. 14. The comparison of stochastic gradient descent and canonical gradient descent. Error of optimized structure in 20 runs, performed with stochastic gradient descent and canonical gradient descent, respectively. Stars are the points used in FIG. 4-FIG. 6.

FIG. 15. Designed spectra featuring different errors (40, 60) plotted against the target spectrum.

FIG. 16. Designed spectrum featuring an error of 125 plotted against the target spectrum.

FIG. 17. Designed spectra featuring different errors (222, 495) plotted against the target spectrum.

FIG. 18. XSEM image of the 7-layer sample in FIG. 6. The scale bar is 500 nm.

FIG. 19. A photo of the wafer-scale Tamm plasmon polariton emitter. The substrate is a 2-inch sapphire wafer.

FIG. 20. Dielectric function fitting and ellipsometry measurements of Ge on sapphire.

FIG. 21. Dielectric function fitting and ellipsometry measurements of AlOₓ on silicon.

FIG. 22. Fitted dielectric function of Ge.

FIG. 23. Fitted dielectric function of AlOₓ.

FIG. 24. Reflectance at room temperature.

FIG. 25. Reflectance at 150° C.

FIG. 26. Highest Q factor achievable at a given frequency (2450 cm⁻¹ here) with different numbers of dielectric layers (3, 5, 7, 9, 11). Q factors listed in parentheses.

FIG. 27. Achievable complexity of spectra for triple peak design shown in FIG. 6 with different numbers of dielectric layers (3, 5, 7, 9, 11).

FIG. 28. Achievable complexity of spectra matching the absorption of DMMP nerve agent with different numbers of dielectric layers (7, 11, 19, 29).

FIG. 29. Schematic of non-dispersive infrared device with a broadband light source with filter.

FIG. 30. Schematic of s filterless non-dispersive infrared enabled by wavelength selective emitters (WS-EMs).

FIG. 31. Target spectrum for dual gas sensing of CO₂ and SO₂.

FIG. 32. Target spectrum for dual gas sensing of CO and formaldehyde.

FIG. 33. Comparison of spectrum for structure with different thickness error case 1 and original design.

FIG. 34. Comparison of spectrum for structure with different thickness error case 2 and original design.

FIG. 35. Comparison of spectrum for structure with different thickness error case 3 and original design.

FIG. 36. Comparison of spectrum for structure with different thickness error case 4 and original design.

FIG. 37. Experimental setup for benchmark measurements to compare the Tamm plasmon polariton emitters with commercial technologies.

FIG. 38. Emissivity measured for sample in FIG. 6 at different incident angles, and the light is TE (Transverse Electric) polarized.

FIG. 39. Emissivity measured for sample in FIG. 6 at different incident angles, and the light is TM (Transverse Magnetic) polarized.

FIG. 40. Emissivity measured for sample in FIG. 5 at different incident angles, and the light is TE (Transverse Electric) polarized.

FIG. 41. Emissivity measured for sample in FIG. 5 at different incident angles, and the light is TM (Transverse Magnetic) polarized.

FIG. 42. The same as FIG. 7, yet with much smaller frequency range to show the near-unity emissivity.

FIG. 43. The linewidth of the highest Q-factor spectra. Fitting was performed with OriginLab software with Lorentz fitting. Center and FWHM are given by the software.

FIG. 44. Optimized Tamm plasmon polariton emitter for triple-peak design with target frequency range: 1600-2900 cm⁻¹.

FIG. 45. Optimized Tamm plasmon polariton emitter for triple-peak design with target frequency range: 1500-3000 cm⁻¹.

FIG. 46. Optimized Tamm plasmon polariton emitter for triple-peak design with target frequency range: 1000-4000 cm⁻¹.

FIG. 47. Optimized Tamm plasmon polariton emitter for triple-peak design with target frequency range: 1000-5000 cm⁻¹.

FIG. 48. Demonstration of inversely designed (ID)-Tamm plasmon polariton emitter matching CO. Chemical absorption spectra are from NIST website.

FIG. 49. Demonstration of inversely designed-Tamm plasmon polariton emitter matching the envelope spectrum of O₃. Chemical absorption spectra are from NIST website.

FIG. 50. Demonstration of inversely designed-Tamm plasmon polariton emitter matching the envelope spectrum of CH₄. Chemical absorption spectra are from NIST website.

FIG. 51. Demonstration of inversely designed-Tamm plasmon polariton emitter matching the envelope spectrum of NH₃. Chemical absorption spectra are from NIST website.

FIG. 52. Adjust the target to a specific working temperature. Target emissivity and blackbody emission power spectrum.

FIG. 53. Adjust the target to a specific working temperature. Target and designed emitter power.

FIG. 54. The comparison between Gold and CdO supported Tamm.

FIG. 55. Mechanism of aperiodic Tamm plasmon polariton emitter. Reflectance of distributed Bragg reflector on silicon and the emissivity of the same distributed Bragg reflector on CdO (N_{d}=3.5×10²⁰ cm⁻³).

FIG. 56. Mechanism of aperiodic Tamm plasmon polariton emitter. Reflectance of distributed Bragg reflector on sapphire and the emissivity of Tamm plasmon polariton emitters with the same distributed Bragg reflector but different carrier densities of CdO (N_{d}=7×10¹⁹ cm⁻³—dashed red line, N_{d}=4.3×10²⁰ cm⁻³—solid red line). The vertical, dashed black line displays the plasma frequency of the N_{d}=7×10¹⁹ cm⁻³ CdO film.

FIG. 57. Equivalent circuit model representation of the Tamm plasmon polariton emitter film in the metal-on-bottom geometry.

FIG. 58. Imaginary impedance of distributed Bragg reflector (Im[Z_{DBR}], black line) and CdO (−Im[Z_{CdO}], red line) from the Tamm plasmon polariton emitter in FIG. 55.

FIG. 59. Imaginary impedance of distributed Bragg reflector (black line) and two carrier densities of CdO (N_{d}=7×10¹⁹ cm⁻³—red line, N_{d}=4.3×10²⁰ cm⁻³—blue line) from the Tamm plasmon polariton emitters in FIG. 56.

FIG. 60. Real impedance of distributed Bragg reflector (black line) and two carrier densities of CdO (N_{d}=7×10¹⁹ cm⁻³—red line, N_{d}=4.3×10²⁰ cm⁻³—blue line) from the Tamm plasmon polariton emitters in FIG. 56.

FIG. 61. Optimized Tamm plasmon polariton emitter when CdO carrier concentrations are fixed at different values. The errors are included in the parentheses.

FIG. 62. Optimized Tamm plasmon polariton emitter when CdO carrier concentrations are fixed at different values. The errors are included in the parentheses.

FIG. 63. The dielectric function of CdO at different carrier concentrations.

FIG. 64. Impedance model when CdO carrier concentrations are fixed at different values.

FIG. 65. Highest possible Q-factor for optimized Tamm plasmon polariton emitter with different mobilities; Q-factors are included in the parentheses.

FIG. 66. Dielectric function of CdO with different mobilities, while the N_{d} is 4×10²⁰ cm⁻³.

FIG. 67. Inversely designed Tamm plasmon polariton emitter with different mobilities while the N_{d} is fixed at 4×10²⁰ cm⁻³. Q-factors are included in the parentheses.

FIG. 68. Inversely designed Tamm plasmon polariton emitter with different mobilities while the N_{d} is fixed at 4×10²⁰ cm-3. Errors are included in the parentheses.

FIG. 69. Inversely designed Tamm plasmon polariton emitter with different mobilities while the N_{d} is designable. Q-factors are included in the parentheses.

FIG. 70. Inversely designed Tamm plasmon polariton emitter with different mobilities while the N_{d} is designable. Errors are included in the parentheses.

FIG. 71. A schematic illustration of an example computing device.

FIG. 72. Representative cross-sectional view of THP supporting structure. N_{d} stands for the number of dielectric layers in the DBR.

FIG. 73. Representative cross-sectional view of TPP supporting structure. N_{d} stands for the number of dielectric layers in the DBR.

FIG. 74. THPs can be used as multi-frequency emitters with simpler structures than TPPs. To realize high sensitivity sulfuryl fluoride gas sensing. N_{d} of 3 is sufficient for THPs (the blue curve), while N_{d} of 9 is required for TPP structure (the yellow curve).

FIG. 75. Calculated field profile of Tamm plasmon polaritons by a distributed Bragg reflector structure.

FIG. 76. Calculated field profile of Tamm phonon polaritons supported by the same distributed Bragg reflector structure as in FIG. 75. The hBN thickness employed in the simulations is 150 nm.

FIG. 77. Calculated field profile of Tamm hybrid polaritons supported by the same distributed Bragg reflector structure as in FIG. 75 and FIG. 76. The hBN thickness employed in the simulations is 150 nm.

FIG. 78. The cross-sectional SEM for the Tamm plasmon polariton-absorber, and the thicknesses are used in the field profile calculations.

FIG. 79. Spectra of Tamm plasmon polaritons. Tamm phonon polaritons and Tamm hybrid polaritons. The thickness of hBN is 19 nm for both the Tamm phonon polariton and Tamm hybrid polariton devices. While experimental data are plotted with solid curves, transfer matrix method (TMM) calculations are plotted as dashed curves with the same color.

FIG. 80. Reflectance spectra of Tamm phonon polaritons supported by hBN-distributed Bragg reflector structure with different hBN thicknesses.

FIG. 81. The extracted Tamm phonon polariton resonance frequencies and FWHMs at different hBN thicknesses.

FIG. 82. Reflectance spectra of Tamm-hybrid supported with different hBN thicknesses.

FIG. 83. The extracted upper polariton branch and lower polariton branch resonance properties at different hBN thicknesses, and the resonance gap between the two branches.

FIG. 84. The dependence of coupling criteria over the thickness of hBN.

FIG. 85. The accuracy of the coupled harmonic oscillator model. The modal frequencies are calculated by transfer matrix method and harmonic oscillator models, respectively.

FIG. 86. The dispersion of Tamm plasmon polaritons in the momentum space. The contour plot is calculated with transfer matrix method, while symbols are experimental data measured with different objectives. Various modes are plotted with corresponding symbols: white triangles for distributed Bragg reflector reflectance dips, half-filled circles for Tamm plasmon polaritons and Tamm phonon polaritons, and white filled circles for Tamm hybrid polaritons.

FIG. 87. The dispersion of Tamm phonon polaritons in the momentum space. The contour plot is calculated with transfer matrix method, while symbols are experimental data measured with different objectives. Various modes are plotted with corresponding symbols: white triangles for distributed Bragg reflector reflectance dips, half-filled circles for Tamm plasmon polaritons and Tamm phonon polaritons, and white filled circles for Tamm hybrid polaritons. The hBN thickness for the Tamm phonon polariton-absorber is 66 nm.

FIG. 88. The dispersion of Tamm hybrid polaritons in the momentum space. The contour plot is calculated with transfer matrix method, while symbols are experimental data measured with different objectives. Various modes are plotted with corresponding symbols: white triangles for distributed Bragg reflector reflectance dips, half-filled circles for Tamm plasmon polaritons and Tamm phonon polaritons, and white filled circles for Tamm hybrid polaritons. The hBN thickness for the Tamm hybrid polariton-absorber is 82 nm.

FIG. 89. The extracted modal dispersions from the transfer matrix method calculations from FIG. 86-FIG. 88. Dashed curves are fitted function with Eq. (3) to determine the band curvature.

FIG. 90. The achievable band curvature of Tamm plasmon polariton-absorbers realized through inverse design. By adding 100 nm thick hBN over the smallest band curvature design (single black curve), Tamm hybrid polariton-absorber with flatter dispersion (green curve) is realized, and the b values are the resultant band curvature.

FIG. 91. Matching the spectrum of Tamm hybrid polariton-absorber with Tamm plasmon polariton-absorbers by inverse design. The dashed curve is the normalized experimentally measured Tamm hybrid polariton-absorber reflectance. n_{DBR} stands for the number of dielectric layers used in the distributed Bragg reflector.

FIG. 92. The Tamm hybrid polaritons were inversely designed to possess two peaks, with one above transverse optical phonon of hBN and one below. Lower polariton branch (upper polariton branch) resonance is fixed, and the other branch is designed to be at different frequencies. Dashed vertical reference lines are the target frequencies correspondingly.

FIG. 93. The Tamm hybrid polaritons were inversely designed to possess two peaks, with one above transverse optical phonon of hBN and one below. Lower polariton branch (upper polariton branch) resonance is fixed, and the other branch is designed to be at different frequencies. Dashed vertical reference lines are the target frequencies correspondingly.

FIG. 94. Inversely designed Tamm-hybrid and Tamm plasmon polariton for spectra barcoding applications. Compared to Tamm plasmon polaritons, the task can be achieved with Tamm hybrid polaritons with significantly fewer dielectric layers.

FIG. 95. Inversely designed Tamm-hybrid and Tamm plasmon polariton for high-sensitivity non-dispersive infrared applications. Compared to Tamm plasmon polaritons, the task can be achieved with Tamm hybrid polaritons with significantly fewer dielectric layers.

FIG. 96. Reflectance spectra of Tamm plasmon polariton (distributed Bragg reflector-CdO), Tamm phonon polariton (hBN-distributed Bragg reflector) and distributed Bragg reflector itself.

FIG. 97. The imaginary part of the impedance of different components. The sign of Imag (Z_{DBR}) is reversed for visualization purposes.

FIG. 98. Imag (Z_{hBN}) with different hBN thicknesses. With thicker hBN, the intercept frequency between Imag (Z_{hBN}) and −Imag (Z_{DBR}) increases, which explains the blue-shifted Tamm phonon polariton shown in FIG. 80.

FIG. 99. Tamm plasmon polaritons supported by CdO with real (160 cm⁻²/(V·s)) and infinite mobility.

FIG. 100. Tamm phonon polaritons supported by hBN with different phonon lifetimes: 2.9 ps (isotopically enriched hBN), 0.145 ps (similar material Q-factor to CdO), infinite lifetime (lossless hBN).

FIG. 101. Material dispersion induced Tamm polariton radiative loss. Tamm phonon polaritons with different material dispersion. The larger the material dispersion (smaller transverse optic-longitudinal optical phonon splitting), the larger is the quality factor.

FIG. 102. Matching Tamm hybrid polariton-absorber with different band curvature.

The target and resultant band curvatures (unit of cm⁻¹/degree²) are 0.03 and 0.066, respectively.

FIG. 103. Matching Tamm hybrid polariton-absorber with different band curvature.

The target and resultant band curvatures (unit of cm⁻¹/degree²) are 0.05 and 0.068, respectively.

FIG. 104. Matching Tamm hybrid polariton-absorber with different band curvature.

The target and resultant band curvatures (unit of cm⁻¹/degree²) are 0.06 and 0.058, respectively.

FIG. 105. Matching Tamm hybrid polariton-absorber with different band curvature.

The target and resultant band curvatures (unit of cm⁻¹/degree²) are 0.08 and 0.092, respectively.

FIG. 106. Matching Tamm hybrid polariton-absorber with different band curvature.

The target and resultant band curvatures (unit of cm⁻¹/degree²) are 0.11 and 0.108, respectively.

FIG. 107. Matching Tamm hybrid polariton-absorber with different band curvature.

The target and resultant band curvatures (unit of cm⁻¹/degree²) are 0.14 and 0.106, respectively.

FIG. 108. Band curvature of Tamm hybrid polariton-absorber with artificial materials. The longitudinal optical phonon frequency is artificially assigned to 1450 cm⁻¹, while transverse optical phonon frequency is 1400 cm⁻¹.

FIG. 109. Band curvature of Tamm hybrid polariton-absorber with artificial materials. The longitudinal optical phonon frequency is artificially assigned to be 1550 cm⁻¹, while transverse optical phonon frequency is 1400 cm⁻¹.

FIG. 110. Band curvature of Tamm hybrid polariton-absorber with artificial material. The longitudinal optical phonon frequency is artificially assigned to be 1650 cm⁻¹, while transverse optical phonon frequency is 1400 cm⁻¹.

FIG. 111. Band curvature of Tamm hybrid polariton-absorber with artificial material. The longitudinal optical phonon frequency is artificially assigned to be 1950 cm⁻¹, while transverse optical phonon frequency is 1400 cm⁻¹.

FIG. 112. The dispersion plot of a Tamm plasmon polariton-absorber.

FIG. 113. The dispersion of a Tamm hybrid polariton-absorber corresponding to the Tamm plasmon polariton-absorber in FIG. 112.

FIG. 114. The convoluted spectral of Tamm plasmon polariton and Tamm hybrid polariton absorbers considering different collection angles.

FIG. 115. The dispersion plot of a high Q-factor Tamm plasmon polariton-absorber.

FIG. 116. The dispersion of a Tamm hybrid polariton-absorber corresponding to the Tamm plasmon polariton-absorber of FIG. 115.

FIG. 117. The convoluted spectral of Tamm plasmon polariton and Tamm hybrid polariton absorbers considering different collection angles.

FIG. 118. Tamm phonon polariton resonance with different hBN thicknesses.

FIG. 119. The same calculation in FIG. 118, while hBN is artificially modeled as isotropic media, by assigning ε_{z}=ε_{xy}.

FIG. 120. One representative comparison between Tamm phonon polariton supported by hBN and artificially isotropic hBN. The hBN thickness is 100 nm.

FIG. 121. Tamm hybrid polariton resonance with different hBN thicknesses.

FIG. 122. The same calculation in FIG. 121, while hBN is artificially modeled as isotropic media, by assigning ε_{z}=ε_{xy}.

FIG. 123. One representative comparison between Tamm hybrid polariton supported by hBN and artificially isotropic hBN. The hBN thickness is 100 nm.

FIG. 124. Tamm phonon polariton resonance at different incident angles in the momentum domain.

FIG. 125. The same calculation in FIG. 124, while hBN is artificially modeled as isotropic media, by assigning ε_{z}=ε_{xy}.

FIG. 126. One representative comparison between Tamm phonon polariton supported by hBN and artificially isotropic hBN, and the incident angle is 60°.

FIG. 127. Tamm hybrid polariton resonance at different incident angles in the momentum domain.

FIG. 128. The same calculation in FIG. 127, while hBN is artificially modeled as isotropic media, by assigning εz=εxy.

FIG. 129. One representative comparison between Tamm hybrid polariton supported by hBN and artificially isotropic hBN, and the incident angle is 60°.

FIG. 130. The absorption spectrum of the design shown in FIG. 88.

FIG. 131. The emitted power of the design shown in FIG. 130 at a 600° C. working temperature. Emitter powers are calculated by integrating within two ranges: one is between 1000 cm⁻¹ and 2000 cm⁻¹, the other is in the highlighted range, which is caused by the transverse optical phonon vibration.

FIG. 132. The field distribution of a Tamm phonon polariton-absorber with a hBN thickness of 19 nm.

FIG. 133. The field distribution of a Tamm phonon polariton-absorber with an hBN thickness of 150 nm.

FIG. 134. The field distribution of Tamm plasmon polariton, Tamm phonon polariton and Tamm hybrid polaritons and corresponding modal frequencies, with 19 nm thick hBN.

FIG. 135. The field distribution of Tamm plasmon polariton, Tamm phonon polariton and Tamm hybrid polaritons and corresponding modal frequencies, with 150 nm thick hBN.

FIG. 136. Tamm hybrid polariton-absorbers realized with SiO₂.

FIG. 137. Tamm hybrid polariton-absorbers realized with SiC.

FIG. 138. Emitted power spectra Tamm plasmon polariton and Tamm hybrid polariton emitters assuming normal incidence angle in an NDIR configuration. BP stands for bandpass filter (100 nm bandwidth).

FIG. 139. The power difference between the reference port and sample port of Tamm plasmon polariton and Tamm hybrid polariton emitters assuming normal incidence angle in an NDIR configuration. A signal difference above three times of detector noise floor is considered detectable.

FIG. 140. Percentage of power change of Tamm plasmon polariton and Tamm hybrid polariton emitters assuming normal incidence angle in an NDIR configuration with different concentrations.

FIG. 141. The resonance splitting of simulated and experimental data.

### DETAILED DESCRIPTION

The compositions, devices, methods, and systems described herein may be understood more readily by reference to the following detailed description of specific aspects of the disclosed subject matter and the Examples included therein.

Before the present compositions, devices, methods, and systems are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps.

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

“Exemplary” means “an example of” and is not intended to convey an indication of a preferred or ideal embodiment. “Such as” is not used in a restrictive sense, but for explanatory purposes.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

As used herein the term “plurality” means 2 or more (e.g., 3 or more; 4 or more; 5 or more; 10 or more; 15 or more: 20 or more; 25 or more; 30 or more: 40 or more; 50 or more; 75 or more; 100 or more; 150 or more; 200 or more; 250 or more; 300 or more; 400 or more; 500 or more; 750 or more; 1000 or more; 1500 or more; 2000 or more; 2500 or more; 3000 or more; 4000 or more; or 5000 or more).

The term “artificial intelligence” is defined herein to include any technique that enables one or more computing devices or comping systems (i.e., a machine) to mimic human intelligence. Artificial intelligence (AI) includes, but is not limited to, knowledge bases, back-propagation bases, machine learning, representation learning, and deep learning.

The term “machine learning” is defined herein to be a subset of AL that enables a machine to acquire knowledge by extracting patterns from raw data. Machine learning techniques include, but are not limited to, logistic regression, support vector machines (SVMs), decision trees, Naïve Bayes classifiers, and artificial neural networks. The term “representation learning” is defined herein to be a subset of machine learning that enables a machine to automatically discover representations needed for feature detection, prediction, or classification from raw data. Representation learning techniques include, but are not limited to, autoencoders. The term “deep learning” is defined herein to be a subset of machine learning that that enables a machine to automatically discover representations needed for feature detection, prediction, classification, etc. using layers of processing. Deep learning techniques include, but are not limited to, artificial neural network or multilayer perceptron (MLP).

Machine learning models include supervised, semi-supervised, and unsupervised learning models. In a supervised learning model, the model learns a function that maps an input (also known as feature or features) to an output (also known as target or target) during training with a labeled data set (or dataset). In an unsupervised learning model, the model learns a function that maps an input (also known as feature or features) to an output (also known as target or target) during training with an unlabeled data set. In a semi-supervised model, the model learns a function that maps an input (also known as feature or features) to an output (also known as target or target) during training with both labeled and unlabeled data.

### Tamm Polariton Emitters

Disclosed herein are Tamm polariton emitters comprising: a distributed Bragg reflector (e.g., one or more distributed Bragg reflectors); and a layer (e.g., one or more layers) comprising a conductive and/or polaritonic material; wherein the distributed Bragg reflector is disposed on (e.g., fabricated or grown on) the layer of the conductive and/or polaritonic material.

In some examples, the Tamm polariton emitter further comprises a layer (e.g., one or more layers) of a polar material. The layer of the polar material can, for example, be disposed on top of the distributed Bragg reflector, such that the distributed Bragg reflector is sandwiched between the polaritonic material and the polar material, or disposed below the layer of the conductive and/or polaritonic material, such that the layer of the conductive and/or polaritonic material is sandwich between the layer of the polar material and the distributed Bragg reflector. In some examples, the layer of the polar material is disposed on top of the distributed Bragg reflector, such that the distributed Bragg reflector is sandwiched between the polaritonic material and the polar material. The polar material can comprise any suitable material. In some examples, the polar material comprises hexagonal boron nitride, silicon carbide, silicon dioxide, aluminum nitride, gallium nitride, and the like, or a combination thereof. In some examples, the polar material comprises hexagonal boron nitride, silicon carbide, aluminum nitride, gallium nitride, and the like, or a combination thereof. In some examples, the polar material comprises hexagonal boron nitride.

The polar material layer can have an average thickness, for example, that is a few times that of the free-space wavelength of operation or less. e.g., on the order of from to a monolayer to ˜free-space wavelength scale thickness.

In some examples, the polar material layer can have an average thickness of 1 nanometer (nm) or more (e.g., 2 nm or more, 3 nm or more, 4 nm or more, 5 nm or more, 10 nm or more, 15 nm or more. 20 nm or more, 30 nm or more, 40 nm or more. 50 nm or more, 75 nm or more, 100 nm or more, 125 nm or more, 150 nm or more, 200 nm or more, 250 nm or more, 300 nm or more, 400 nm or more, 500 nm or more, 750 nm or more, 1 micrometer (micron, μm) or more, 1.25 μm or more, 1.5 μm or more, 1.75 μm or more, 2 μm or more, 2.5 μm or more, 3 μm or more, 3.5 μm or more, 4 μm or more, 4.5 μm or more, 5 μm or more, 6 μm or more, 7 μm or more, 8 μm or more, 9 μm or more, 10 μm or more, 15 μm or more, 20 μm or more, 30 μm or more, 40 μm or more, 50 μm or more, 75 μm or more, 100 μm or more, 125 μm or more, 150 μm or more, 200 μm or more, 250 μm or more, 300 μm or more, 400 μm or more, 500 μm or more, 750 μm or more, 1 millimeter (mm) or more, 1.25 mm or more, 1.5 mm or more, 1.75 mm or more, 2 mm or more, 2.5 mm or more, 3 mm or more, 3.5 mm or more, 4 mm or more, 4.5 mm or more, 5 mm or more, 6 mm or more, 7 mm or more, 8 mm or more, 9 mm or more, 10 mm or more, 15 mm or more, 20 mm or more, 25 mm or more, 30 mm or more, 35 mm or more, 40 mm or more, 45 mm or more, 50 mm or more, 60 mm or more, 70 mm or more, 80 mm or more, or 90 mm or more). In some examples, the polar material layer can have an average thickness of 100 millimeters (mm) or less (e.g., 90 mm or less, 80 mm or less, 70 mm or less, 60 mm or less, 50 mm or less, 45 mm or less, 40 mm or less, 35 mm or less, 30 mm or less, 25 mm or less, 20 mm or less, 15 mm or less, 10 mm or less, 9 mm or less, 8 mm or less, 7 mm or less, 6 mm or less, 5 mm or less, 4.5 mm or less, 4 mm or less, 3.5 mm or less, 3 mm or less, 2.5 mm or less, 2 mm or less, 1.75 mm or less, 1.5 mm or less, 1.25 mm or less, 1 mm or less, 750 micrometers (μm) or less, 500 μm or less, 400 μm or less, 300 μm or less, 250 μm or less, 200 μm or less, 150 μm or less, 125 μm or less, 100 μm or less, 75 μm or less, 50 μm or less. 40 μm or less, 30 μm or less, 20 μm or less, 15 μm or less, 10 μm or less, 9 μm or less, 8 μm or less, 7 μm or less, 6 μm or less, 5 μm or less, 4.5 μm or less, 4 μm or less, 3.5 μm or less, 3 μm or less, 2.5 μm or less, 2 μm or less, 1.75 μm or less, 1.5 μm or less, 1.25 μm or less, 1 μm or less, 750 nanometers (nm) or less, 500 nm or less, 400 nm or less, 300 nm or less, 250 nm or less, 200 nm or less, 150 nm or less. 125 nm or less, 100 nm or less, 75 nm or less. 50 nm or less, 40 nm or less, 30 nm or less, 20 nm or less, 15 nm or less, 10 nm or less, or 5 nm or less). The average thickness of the polar material layer can range from any of the minimum values described above to any of the maximum values described above. For example, the polar material layer can have an average thickness of from 1 nanometer (nm) to 100 millimeters (mm) (e.g., from 1 nm to 10 microns, from 10 microns to 100 millimeters, from 1 nm to 100 nm, from 100 nm to 10 microns, from 10 microns to 1 millimeter, from 1 millimeter to 100 millimeters, from 5 nm to 100 mm, from 1 nm to 90 mm, from 5 nm to 90 mm, from 1 nm to 1 mm, from 1 nm to 500 microns, or from 1 nm to 1 μm).

In some examples, the Tamm polariton emitter can further comprise a substrate. In some examples, the polaritonic material is disposed on the substrate, and the layer of the conductive and/or polaritonic material is sandwiched between the substrate and the distributed Bragg reflector. In some examples, the distributed Bragg reflector is disposed on the substrate, and the distributed Bragg reflector is sandwiched between the substrate and the layer of the conductive and/or polaritonic material. In some examples, the layer of the polar material is present and is disposed on the substrate, and the layer of the polar material is sandwiched between the substrate and the distributed Bragg reflector. In some examples, the layer of the polar material is present and is disposed on the substrate, and the layer of the polar material is sandwiched between the substrate and the layer of the conductive and/or polaritonic material.

The substrate can comprise any suitable material. For example, the substrate can comprise a dielectric, a semiconductor, a ceramic, a transparent conducing oxide, a polymer, a metal, or a combination thereof. In some examples, the substrate can be transparent. As used herein, a “transparent substrate” is meant to include any substrate that is transparent at the wavelength or wavelength region of interest. Examples of substrates include, but are not limited to, silicon, group III-V semiconductors, glass, quartz, parylene, silicon dioxide, sapphire, mica, poly(methyl methacrylate), polyamide, polycarbonate, polyester, polypropylene, polytetrafluoroethylene, polvdimethylsiloxane (PDMS), hafnium oxide, hafnium silicate, tantalum pentoxide, zirconium dioxide, zirconium silicate, and combinations thereof. The substrate can, for example, comprise glass, quartz, silicon dioxide, silicon nitride, a polymer, or a combination thereof. In some examples, the substrate comprises sapphire.

The layer of the conductive and/or polaritonic material can comprise any suitable material such as those known in the art. In some examples, the layer comprises a plurality of layers and each layer can independently comprise any suitable material. In some examples, the layer comprises a polaritonic material. The polaritonic material can comprise any suitable material supporting polaritons such as those known in the art. In some examples, the polaritonic material comprises a phonon polariton material. Examples of polaritonic materials include, but are not limited to metals, transparent conducting oxides, group III-V semiconductors, and combinations thereof. In some examples, the polaritonic material has a tunable carrier density.

In some examples, the polaritonic material comprises a group III-V semiconductor. For example, the polaritonic material can comprise a group III element selected from the group consisting of B, Al, Ga, In, TI, and combinations thereof and a group V element selected from the group consisting of N, P, As, Sb, Bi, and combinations thereof. In some examples, the polaritonic material comprises can comprise a group III-Nitride semiconductor, such as, for example, InAs. InP, InN. GaN, AlN. BN and their alloys.

In some examples, the polaritonic material comprises a transparent conducting oxide. Transparent conducting oxides (TCOs) can comprise a metal oxide, AₓO_{z}, wherein A is one or more metals. The oxygen in combination with different metals or metal-combinations lead to compound semiconductors, AₓO_{z}, with different opto-electrical characteristics. These opto-electrical characteristics can be changed by doping, AₓO_{z}:D (D=dopant), with metals, metalloids, or nonmetals. Hence, metals can be part of the compound semiconductor itself, A, or can be a dopant, D. Examples of transparent conducting oxides include, but are not limited to, indium doped tin oxide (ITO), fluorine doped tin oxide (FTO), aluminum zinc oxide (AZO), tin doped indium oxide, and combinations thereof.

In some examples, the polaritonic material comprises a transparent conducting oxide which comprises a metal oxide. Examples of metal oxides include simple metal oxides (e.g., with a single metal element) and mixed metal oxides (e.g., with different metal elements). The metal oxide can, for example, comprise a metal selected from the group consisting of Cd, Cr, Cu, Ga, In, Ni, Sn, Ti, W, Zn, and combinations thereof. In some examples, the polaritonic material can comprise, CdO, CdIn₂O₄, Cd₂SnO₄, Cr₂O₃, CuCrO₂, CuO₂, Ga₂O₃, In₂₀₃, NiO, SnO₂, TiO₂, ZnGa₂O₄, ZnO, InZnO, InGaZnO, InGaO, ZnSnO, Zn₂SnO₄, CdSnO, WO₃, or combinations thereof. In some examples, the polaritonic material comprises a cadmium oxide.

In some examples, the polaritonic material further comprises a dopant. The dopant can comprise any suitable dopant for the polaritonic material. The dopant can, for example, be selected to tune the optical and/or electronic properties of the polaritonic material. In some examples, the presence and/or concentration of the dopant can tune the carrier density of the polaritonic material. In some examples, the concentration and/or identity of the dopant within the polaritonic material can vary, for example with thickness and/or lateral dimension (e.g., concentration gradient with thickness).

In some examples, the dopant can comprise an n-type dopant. The dopant can, for example, comprise Al, B, Ce, Cl, Cs, Dy, Er, Eu, F, Ga, Gd, Ho, In, La, Mg, Mo, N, Nb, N_{d}, Sb, Sn, Sm, Tb, or combinations thereof.

In some examples, the polaritonic material comprises doped cadmium oxide, such as n-doped cadmium oxide. In some examples, the polaritonic material comprises n-type In-doped CdO.

The layer of the conductive and/or polaritonic material can, for example, have an average thickness of 1 nanometer (nm) or more (e.g., 2 nm or more, 3 nm or more, 4 nm or more, 5 nm or more, 10 nm or more, 15 nm or more, 20 nm or more, 30 nm or more, 40 nm or more, 50 nm or more, 75 nm or more, 100 nm or more, 125 nm or more, 150 nm or more, 200 nm or more, 250 nm or more, 300 nm or more, 400 nm or more, 500 nm or more, 750 nm or more, 1 micrometer (micron, μm) or more, 1.25 μm or more, 1.5 μm or more, 1.75 μm or more, 2 μm or more, 2.5 μm or more, 3 μm or more, 3.5 m or more, 4 μm or more, 4.5 μm or more, 5 μm or more, 6 μm or more, 7 μm or more, 8 μm or more, 9 μm or more. 10 μm or more, 15 μm or more, 20 μm or more, 30 μm or more, 40 μm or more, 50 μm or more, 75 μm or more, 100 μm or more, 125 μm or more, 150 μm or more, 200 μm or more, 250 μm or more, 300 μm or more, 400 μm or more, 500 μm or more, 750 μm or more, 1 millimeter (mm) or more, 1.25 mm or more, 1.5 mm or more. 1.75 mm or more, 2 mm or more, 2.5 mm or more, 3 mm or more, 3.5 mm or more. 4 mm or more. 4.5 mm or more, 5 mm or more, 6 mm or more, 7 mm or more, 8 mm or more, 9 mm or more, 10 mm or more, 15 mm or more, 20 mm or more, 25 mm or more, 30 mm or more, 35 mm or more, 40 mm or more, 45 mm or more, 50 mm or more, 60 mm or more, 70 mm or more, 80 mm or more, or 90 mm or more). In some examples, the layer of the conductive and/or polaritonic material can, for example, have an average thickness of 100 millimeters (mm) or less (e.g., 90 mm or less, 80 mm or less, 70 mm or less, 60 mm or less, 50 mm or less, 45 mm or less, 40 mm or less, 35 mm or less, 30 mm or less, 25 mm or less, 20 mm or less, 15 mm or less, 10 mm or less, 9 mm or less, 8 mm or less, 7 mm or less, 6 mm or less, 5 mm or less, 4.5 mm or less, 4 mm or less, 3.5 mm or less. 3 mm or less, 2.5 mm or less, 2 mm or less, 1.75 mm or less, 1.5 mm or less, 1.25 mm or less, 1 mm or less, 750 micrometers (μm) or less, 500 μm or less, 400 μm or less, 300 μm or less, 250 μm or less, 200 μm or less, 150 μm or less, 125 μm or less, 100 μm or less, 75 μm or less, 50 μm or less, 40 μm or less, 30 μm or less, 20 μm or less, 15 μm or less, 10 μm or less, 9 μm or less, 8 μm or less, 7 μm or less, 6 μm or less, 5 μm or less, 4.5 μm or less, 4 μm or less, 3.5 μm or less, 3 μm or less, 2.5 μm or less, 2 μm or less, 1.75 μm or less, 1.5 μm or less, 1.25 μm or less, 1 μm or less, 750 nanometers (nm) or less, 500 nm or less, 400 nm or less, 300 nm or less, 250 nm or less, 200 nm or less, 150 nm or less, 125 nm or less. 100 nm or less, 75 nm or less, 50 nm or less, 40 nm or less, 30 nm or less, 20 nm or less, 15 nm or less, 10 nm or less, or 5 nm or less). The average thickness of the layer of the conductive and/or polaritonic material can range from any of the minimum values described above to any of the maximum values described above. For example, the layer of the conductive and/or polaritonic material can have an average thickness of from 1 nanometer (nm) to 100 millimeters (mm) (e.g., from 1 nm to 10 microns, from 10 microns to 100 millimeters, from 1 nm to 100 nm, from 100 nm to 10 microns, from 10 microns to 1 millimeter, from 1 millimeter to 100 millimeters, from 5 nm to 100 mm, from 1 nm to 90 mm, from 5 nm to 90 mm, from 1 nm to 1 mm, from 1 nm to 500 microns, or from 1 nm to 1 μm).

The layer of the conductive and/or polaritonic material has a carrier density, which can be fixed or tunable. For example, the layer of the conductive and/or polaritonic material can have a carrier density of 1×10¹⁰ cm⁻³ or more (e.g., 1×10¹¹ cm⁻³ or more, 1×10¹² cm⁻³ or more, 1×10¹³ cm⁻³ or more, 1×10¹⁴ cm⁻³ or more, 1×10¹⁵ cm⁻³ or more, 1×10¹⁶ cm⁻³ or more, 1×10¹⁷ cm⁻³ or more, 1×10¹⁸ cm⁻³ or more, 1×10¹⁹ cm⁻³ or more, 1×10²⁰ cm⁻³ or more, 1×10²¹ cm⁻³ or more, 1×10²² cm⁻³ or more, 1×10²³ cm⁻³ or more, or 1×10²⁴ cm⁻³ or more). In some examples, the layer of the conductive and/or polaritonic material can have a carrier density of 1×10²⁵ cm⁻³ or less (e.g., 1×10²⁴ cm⁻³ or less, 1×10²³ cm⁻³ or less, 1×10²² cm⁻³ or less, 1×10²¹ cm⁻³ or less, 1×10²⁰ cm⁻³ or less, 1×10¹⁹ cm⁻³ or less, 1×10¹⁸ cm⁻³ or less, 1×10¹⁷ cm⁻³ or less, 1×10¹⁶ cm⁻³ or less, 1×10¹⁵ cm⁻³ or less, 1×10¹⁴ cm⁻³ or less, 1×10¹³ cm⁻³ or less, 1×10¹² cm⁻³ or less, or 1×10¹¹ cm⁻³ or less). The carrier density of the layer of the conductive and/or polaritonic material can range from any of the minimum values described above to any of the maximum values described above. For example, the layer of the conductive and/or polaritonic material can have a carrier density of from 1×10¹⁰ cm⁻³ to 1×10²⁵ cm⁻³ (e.g., from 1×10¹⁰ cm⁻³ to 5×10¹⁷ cm⁻³, from 5×10¹⁷ cm⁻³ to 1×10²⁵ cm⁻³, from 1×10¹⁰ cm⁻³ to 1×10¹⁵ cm⁻³, from 1×10¹⁵ cm⁻³ to 1×10²⁰ cm⁻³, from 1×10²⁰ cm⁻³ to 1×10²⁵ cm⁻³, from 5×10¹⁰ cm⁻³ to 1×10²⁵ cm⁻³, from 1×10¹⁰ cm⁻³ to 5×10²⁴ cm⁻³, or from 5×10¹⁰ cm⁻³ to 5×10²⁴ cm⁻³).

In some examples, the layer of the conductive and/or polaritonic material can have a carrier density of 0.2×10²⁰ cm⁻³ or more (e.g., 0.5×10²⁰ cm⁻³ or more, 1×10²⁰ cm⁻³ or more, 1.5×10²⁰ cm⁻³ or more, 2×10²⁰ cm⁻³ or more, 2.5×10²⁰ cm⁻¹ or more, 3×10²⁰ cm⁻³ or more, 4×10²⁰ cm⁻³ or more, 5×10²⁰ cm⁻³ or more, 10×10²⁰ cm⁻³ or more, 15×10²⁰ cm⁻³ or more, 20×10²⁰ cm⁻³ or more, 25×10²⁰ cm⁻³ or more. 30×10²⁰ cm⁻³ or more, 35×10²⁰ cm⁻³ or more. 40×10²⁰ cm⁻³ or more, 45×10²⁰ cm⁻³ or more, 50×10²⁰ cm⁻³ or more, 60×10²⁰ cm⁻³ or more, 70×10²⁰ cm⁻³ or more, 80×10²⁰ cm⁻³ or more, 90×10²⁰ cm⁻³ or more, or 100×10²⁰ cm⁻³ or more). In some examples, the layer of the conductive and/or polaritonic material can have a carrier density of 120×10²⁰ cm⁻³ or less (e.g., 110×10²⁰ cm⁻³ or less, 100×10²⁰ cm⁻³ or less. 90×10²⁰ cm⁻³ or less, 80×10²⁰ cm⁻³ or less, 70×10²⁰ cm⁻³ or less, 60×10²⁰ cm⁻³ or less, 50×10²⁰ cm⁻³ or less, 45×10²⁰ cm⁻³ or less, 40×10²⁰ cm⁻³ or less, 35×10²⁰ cm⁻³ or less, 30×10²⁰ cm⁻³ or less, 25×10²⁰ cm⁻³ or less, 20×10²⁰ cm⁻³ or less, 15×10²⁰ cm⁻³ or less, 10×10²⁰ cm⁻³ or less, 5×10²⁰ cm⁻³ or less, 4×10²⁰ cm⁻³ or less, 3×10²⁰ cm⁻³ or less, 2.5×10²⁰ cm⁻³ or less, 2×10²⁰ cm⁻³ or less, 1.5×10²⁰ cm⁻³ or less, or 1×10²⁰ cm⁻³ or less). The carrier density of the layer of the conductive and/or polaritonic material can range from any of the minimum values described above to any of the maximum values described above. For example, the layer of the conductive and/or polaritonic material can have a carrier density of from 0.2×10²⁰ cm⁻³ to 120×10²⁰ cm⁻³ (e.g., from 0.2×10²⁰ cm⁻³ to 60×10²⁰ cm⁻³, from 60×10²⁰ cm⁻³ to 120×10²⁰ cm⁻³, from 0.2×10²⁰ cm⁻³ to 40×10²⁰ cm⁻³, from 40×10²⁰ cm⁻³ to 80×10²⁰ cm⁻³, from 80×10²⁰ cm⁻³ to 120×10²⁰ cm⁻³, from 0.5×10²⁰ cm⁻³ to 120×10²⁰ cm⁻³, from 0.2×10²⁰ cm⁻³ to 110×10²⁰ cm⁻³, from 0.5×10²⁰ cm⁻³ to 110×10²⁰ cm⁻³, from 0.2×10²⁰ cm⁻³ to 12×10²⁰ cm⁻³, from 1×10²⁰ cm⁻³ to 12×10²⁰ cm⁻³, or from 1×10²⁰ cm⁻³ to 4×10²⁰ cm⁻³).

The distributed Bragg reflector can comprise any suitable distributed Bragg reflector. In some examples, the distributed Bragg reflector comprises an aperiodic distributed Bragg reflector.

In some examples, the distributed Bragg reflector comprises a plurality of layers (e.g., a stack) of a plurality of materials with varying refractive index. For example, the distributed Bragg reflector comprises a plurality of layers, wherein each layer comprises a material having a refractive index, and the refractive index of a given layer is different than the refractive index of the preceding and/or subsequent layer(s). In some examples, the distributed Bragg reflector comprises a plurality of alternating layers of a first material having a first refractive index and a second material having a second refractive index, wherein the first refractive index and the second refractive index are different. The materials can, for example, comprise any suitable material, including, but not limited to, dielectric materials, semiconductors, ceramics, transparent conducing oxides, phase change materials, polymers, and combinations thereof.

In some examples, the distributed Bragg reflector comprises a plurality of alternating layers of a first material having a first refractive index and a second material having a second refractive index, wherein the first refractive index and the second refractive index are different. The first material and the second material can comprise any suitable material, including, but not limited to, dielectric materials, semiconductors, ceramics, transparent conducing oxides, phase change materials, polymers, and combinations thereof. In some examples, the first material comprises Ge, Si, or a combination thereof. In some examples, the second material comprises an oxide (e.g., AlOₓ, SiO₂), ZnSe, or a combination thereof.

In some examples, the total number of layers in the distributed Bragg reflector can be 1 or more (e.g., 2 or more; 3 or more; 4 or more: 5 or more; 10 or more: 15 or more; 20 or more; 30 or more; 40 or more; 50 or more; 75 or more; 100 or more; 125 or more; 150 or more; 175 or more; 200 or more: 250 or more: 300 or more: 350 or more: 400 or more: 450 or more: 500 or more; 600 or more: 700 or more: 800 or more: 900 or more: 1,000 or more: 1,250 or more: 1,500 or more; 1,750 or more; 2,000 or more; 2,250 or more: 2,500 or more: 3,000 or more: 3,500 or more; 4,000 or more; 4,500 or more; 5,000 or more; 6,000 or more; 7,000 or more; or 8,000 or more). In some examples, the total number of layers in the distributed Bragg reflector can be 10,000 or less (e.g., 9,000 or less; 8,000 or less; 7.000 or less: 6,000 or less; 5,000 or less; 4,500 or less; 4,000 or less; 3,500 or less; 3,000 or less; 2,500 or less; 2,250 or less; 2,000 or less; 1,750 or less; 1,500 or less; 1,250 or less; 1,000 or less; 900 or less; 800 or less; 700 or less; 600 or less; 500 or less; 450 or less; 400 or less; 350 or less; 300 or less; 250 or less; 200 or less; 175 or less; 150 or less: 125 or less; 100 or less; 75 or less; 50 or less; 40 or less; 30 or less; 25 or less; 15 or less: 10 or less; 5 or less; 4 or less; or 3 or less). The total number of layers in the distributed Bragg reflector can range from any of the minimum values described above to any of the maximum values described above. For example, the total number of layers in the distributed Bragg reflector can be from 1 to 10,000 (e.g., from 1 to 5,000; from 5,000 to 10,000; from 1 to 100; from 100 to 1,000, from 1,000 to 10,000: from 2 to 10.000, from 1 to 9,000: from 2 to 9,000: from 2 to 8,000; from 2 to 5,000; from 2 to 1,000; or from 2 to 100).

Each of the plurality of layers in the distributed Bragg reflector can independently have an average thickness, for example, that is a few times that of the free-space wavelength of operation or less. e.g., on the order of from to a monolayer to ˜free-space wavelength scale thickness.

For example, each of the plurality of layers in the distributed Bragg reflector can independently have an average thickness of 1 nanometer (nm) or more (e.g., 2 nm or more, 3 nm or more, 4 nm or more, 5 nm or more. 10 nm or more, 15 nm or more, 20 nm or more, 30 nm or more, 40 nm or more, 50 nm or more, 75 nm or more, 100 nm or more, 125 nm or more, 150 nm or more, 200 nm or more, 250 nm or more, 300 nm or more, 400 nm or more, 500 nm or more, 750 nm or more, 1 micrometer (micron, μm) or more, 1.25 m or more, 1.5 μm or more, 1.75 μm or more, 2 μm or more, 2.5 μm or more. 3 μm or more, 3.5 μm or more, 4 μm or more, 4.5 μm or more, 5 μm or more, 6 μm or more, 7 μm or more, 8 μm or more, 9 μm or more, 10 μm or more, 15 μm or more, 20 μm or more, 30 μm or more, 40 μm or more, 50 μm or more, 75 μm or more, 100 μm or more, 125 μm or more, 150 μm or more, 200 μm or more, 250 jm or more, 300 μm or more, 400 μm or more, 500 μm or more, 750 μm or more, 1 millimeter (mm) or more, 1.25 mm or more, 1.5 mm or more, 1.75 mm or more, 2 mm or more, 2.5 mm or more, 3 mm or more, 3.5 mm or more, 4 mm or more, 4.5 mm or more, 5 mm or more, 6 mm or more, 7 mm or more, 8 mm or more, 9 mm or more, 10 mm or more, 15 mm or more, 20 mm or more, 25 mm or more, 30 mm or more, 35 mm or more. 40 mm or more, 45 mm or more, 50 mm or more, 60 mm or more, 70 mm or more. 80 mm or more, or 90 mm or more). In some examples, each of the plurality of layers in the distributed Bragg reflector can independently have an average thickness of 100 millimeters (mm) or less (e.g., 90 mm or less, 80 mm or less, 70 mm or less, 60 mm or less, 50 mm or less, 45 mm or less, 40 mm or less, 35 mm or less, 30 mm or less, 25 mm or less, 20 mm or less, 15 mm or less, 10 mm or less, 9 mm or less, 8 mm or less, 7 mm or less, 6 mm or less, 5 mm or less, 4.5 mm or less, 4 mm or less, 3.5 mm or less, 3 mm or less, 2.5 mm or less, 2 mm or less, 1.75 mm or less, 1.5 mm or less, 1.25 mm or less, 1 mm or less, 750 micrometers (μm) or less, 500 μm or less, 400 μm or less, 300 μm or less, 250 μm or less, 200 μm or less, 150 μm or less, 125 μm or less, 100 μm or less, 75 μm or less, 50 μm or less. 40 μm or less, 30 μm or less, 20 μm or less, 15 μm or less, 10 μm or less, 9 μm or less, 8 μm or less, 7 μm or less, 6 μm or less, 5 μm or less, 4.5 μm or less, 4 μm or less, 3.5 μm or less, 3 μm or less, 2.5 μm or less, 2 μm or less, 1.75 μm or less, 1.5 μm or less, 1.25 μm or less, 1 μm or less, 750 nanometers (nm) or less, 500 nm or less, 400 nm or less, 300 nm or less, 250 nm or less, 200 nm or less, 150 nm or less. 125 nm or less, 100 nm or less, 75 nm or less. 50 nm or less, 40 nm or less, 30 nm or less, 20 nm or less, 15 nm or less, 10 nm or less, or 5 nm or less). The average thickness of each of the plurality of layers in the distributed Bragg reflector can independently range from any of the minimum values described above to any of the maximum values described above. For example, each of the plurality of layers in the distributed Bragg reflector can independently have an average thickness of from 1 nanometer (nm) to 100 millimeters (mm) (e.g., from 1 nm to 10 microns, from 10 microns to 100 millimeters, from 1 nm to 100 nm, from 100 nm to 10 microns, from 10 microns to 1 millimeter, from 1 millimeter to 100 millimeters, from 5 nm to 100 mm, from 1 nm to 90 mm, from 5 nm to 90 mm, from 1 nm to 1 mm, from 1 nm to 500 microns, or from 1 nm to 1 μm).

In some examples, the Tamm polariton emitter emits radiation at a frequency (e.g., one or more frequencies), said frequency being an emission frequency. In some examples, the Tamm polariton emitter has a single emission frequency. In some examples, the Tamm polariton emitter has a plurality of emission frequencies.

In some examples, the Tamm polariton emitter has an emission frequency in the visible spectral region. In some examples, the Tamm polariton emitter has an emission frequency in the ultraviolet spectral region. In some examples, the Tamm polariton emitter has an emission frequency in the terahertz spectral region. In some examples, the Tamm polariton emitter has an emission frequency in the infrared spectral region. In some examples, the Tamm polariton emitter has an emission frequency in the short-wave infrared spectral region, in the mid-wave infrared spectral region (e.g., 2600-2800 cm⁻¹), in the long-wave infrared spectral region (e.g., 1100-1300 cm⁻¹), in the telecommunications band region (e.g., 1.5-1.6 μm), or a combination thereof. In some examples, the Tamm polariton emitter has an emission frequency in the short-wave to long-wave infrared spectral region, in the mid- to long-wave infrared region, in the long-wave infrared region to the telecommunications band region, or a combination thereof.

The Tamm polariton emitter can, for example, comprise a Tamm plasmon polariton emitter, a Tamm phonon polariton emitter, or a Tamm hybrid polariton emitter.

### Methods of Making

Also disclosed herein are methods of making any of the Tamm polariton emitters disclosed herein. The methods can, for example, comprise disposing the distributed Bragg reflector on the layer of the conductive and/or polaritonic material. In some examples, the methods can further comprise, before disposing the distributed Bragg reflector on the layer of the conductive and/or polaritonic material, disposing the distributed Bragg reflector or the layer of the conductive and/or polaritonic material on the substrate. In some examples, the methods can further comprise disposing the layer of the polar material on the distributed Bragg reflector.

In some examples, methods can comprise using techniques, such as, for example, electroplating, lithographic deposition, electron beam deposition, thermal deposition, spin coating, drop-casting, zone casting, dip coating, blade coating, spraying, vacuum filtration, chemical vapor deposition (CVD), atomic layer deposition (ALD), physical vapor deposition (PVD), sputtering, pulsed layer deposition, molecular beam epitaxy, evaporation, or combinations thereof. In some examples, the method comprises complementary metal-oxide-semiconductor (CMOS) processing.

### Methods of Use

Also disclosed herein are methods of use of any of the Tamm polariton emitters disclosed herein. The methods can, for example, comprise using the Tamm polariton emitter in a free-space communication application, as a beacon, in a bar-code application, in an encryption application, in a sensing application, or a combination thereof.

For example, also disclosed herein are infrared beacons comprising any of the Tamm polariton emitters disclosed herein. The infrared beacon can, for example, be used in a search and rescue, police, and/or military application.

### Devices and Sensors

Also disclosed herein are devices comprising any of the Tamm polariton emitters disclosed herein. For example, also disclosed herein are sensors comprising any of the Tamm polariton emitters disclosed herein.

In some examples, also disclosed herein are non-dispersive infrared (NDIR) sensors comprising: any of the Tamm polariton emitters disclosed herein, wherein the Tamm polariton emitter is configured to selectively emit radiation at a frequency (e.g., one or more frequencies) corresponding to a rotational or vibrational resonance frequency (e.g., one or more rotational or vibrational resonance frequencies) of an analyte (e.g., one or more analytes) of interest; and a detector configured to receive an electromagnetic signal from the Tamm polariton emitter and/or the analyte of interest.

In some examples, the non-dispersive infrared sensor further comprises a fluid cell extending from a proximal end to distal end and having an inlet and an outlet, wherein the Tamm polariton emitter is disposed towards the proximal end of the fluid cell and the detector is disposed towards the distal end of the fluid cell, such that, when the sensor is assembled together with a fluid sample, the fluid cell is configured to contain the fluid sample and the detector is configured to receive an electromagnetic signal from the Tamm polariton emitter and/or the fluid sample. As used herein, a “fluid” includes a liquid, a gas, a supercritical fluid, or a combination thereof. In some examples, the fluid sample comprises a gaseous sample. In some examples, the analyte of interest comprises a gas.

In some examples, the detector is configured to selectively receive the electromagnetic signal from the Tamm polariton emitter and/or the analyte of interest (e.g., the detector is not a broad band detector).

In some examples, the detector comprises a Tamm polariton detector, the Tamm polariton detector comprising any of the Tamm polariton emitters disclosed herein.

In some examples, the Tamm polariton emitter and/or the Tamm polariton detector (when present) independently comprise a Tamm plasmon polariton emitter, a Tamm phonon polariton emitter, or a Tamm hybrid polariton emitter.

In some examples, the non-dispersive infrared sensor further comprises a computing device configured to receive and process a signal from the detector to determine a property of the fluid sample.

In some examples, the sensor is further configured to output the property of the fluid sample and/or a feedback signal based on the property of the fluid sample. The feedback signal can, for example, comprise haptic feedback, auditory feedback, visual feedback, or a combination thereof.

The property of the fluid sample can, for example, comprise the presence of the analyte of interest in the fluid sample, the concentration of the analyte of interest in the fluid sample (e.g., the concentration of the gas of interest in the gas sample), the identity of the analyte of interest, or a combination thereof.

In some examples, the analyte of interest comprises a plurality of analytes. In some examples, the analyte of interest comprises a plurality of analytes and the Tamm polariton emitter is configured to selectively emits radiation at a plurality of frequencies, wherein at least a portion of each of the plurality of frequencies corresponds to a rotational or vibrational resonance frequency (e.g., one or more rotational or vibrational frequencies) of each of the plurality of analytes of interest, such that the sensor can detect the plurality of analytes simultaneously. In some examples, the sensor comprises a plurality of Tamm polariton emitters, wherein each of the plurality of Tamm polariton emitters is configured to selectively emit radiation at a frequency such that the plurality of Tamm polariton emitters are selectively configured to emit radiation at a plurality of frequencies, wherein at least a portion of each of the plurality of frequencies corresponds to a rotational or vibrational resonance frequency of each of the plurality of analytes of interest, such that the sensor can detect the plurality of analytes simultaneously. In some examples, the detector comprises a Tamm polariton detector and the Tamm polariton detector is configured to selectively receive radiation at the plurality of frequencies: or the detector comprises a plurality of Tamm polariton detectors, wherein each of the plurality of Tamm polariton detectors is configured to selectively receive radiation at a frequency such that the plurality of Tamm polariton detectors are selectively configured to receive radiation at the plurality of frequencies.

In some examples, the analyte of interest comprises a single analyte and the Tamm polariton emitter is configured to selectively emit radiation at a plurality of frequencies corresponding to a plurality of rotational or vibrational resonance frequencies of the analyte of interest, such that the sensor can detect the analyte of interest with high sensitivity. In some examples, the analyte of interest comprises a single analyte and the sensor comprises a plurality of Tamm polariton emitters, wherein each of the plurality of Tamm polariton emitters is configured to selectively emit radiation at a frequency such that the plurality of Tamm polariton emitters are selectively configured to emit radiation at a plurality of frequencies, wherein at least a portion of each of the plurality of frequencies corresponds to a plurality of rotational or vibrational resonance frequencies of the analyte of interest, such that the sensor can detect the analyte of interest with high sensitivity. In some examples, the detector comprises a Tamm polariton detector and the Tamm polariton detector is configured to selectively receive radiation at the plurality of frequencies; or the detector comprises a plurality of Tamm polariton detectors, wherein each of the plurality of Tamm polariton detectors is configured to selectively receive radiation at a frequency such that the plurality of Tamm polariton detectors are selectively configured to receive radiation at the plurality of frequencies.

In some examples, the analyte of interest comprises a toxin, a contaminant, a pollutant, a warfare agent (e.g., a chemical or biological warfare agent), or a combination thereof.

In some examples, the analyte of interest comprises an organic molecule, a biological agent (e.g., bacteria, virus, protozoan, parasite, fungus, biological warfare agent, or combination thereof), or a combination thereof. In some examples, the analyte of interest comprises a pathogen, such as an infectious microbe (e.g., bacteria, virus, fungi, protozoa, etc.).

In some examples, the analyte of interest can comprise a chemical or biological warfare agent. Examples of chemical warfare agents include, but are not limited to, nerve agents (e.g., sarin, soman, cyclosarin, tabun, Ethyl ({2-[bis(propan-2-yl)amino]ethyl}sulfanyl)(methyl)phosphinate (VX). O-pinacolylmethylphosphonofluoridate), vesicating or blistering agents (e.g., mustards, lewisite), respiratory agents (e.g., chlorine, phosgene, diphosgene), cyanides, antimiscarinic agents (e.g., anticholinergic compounds), opioid agents, lachrvmatory agents (e.g., a-cholorotoluene, benzvl bromide, boromoacetone (BA), boromobenzvlcyanide (CA), capsaicin (OC), chloracetophenone (MACE), chlormethyl choloroformate, dibenoxazepine (CR), ethyl iodoacetate, ortho-chlorobenzlidene malonitrile (CS), trichloromethyl chloroformate, xylyl bromide), and vomiting agents (e.g., adamsite (DM), diphenylchloroarsine (DA), diphenylcanoarsine (DC)). Biological warfare agents include, but are not limited to bacteria (e.g., Bacillus anthracis, Bacillus abortus, Brucella suis. Vibrio cholerae. Corynebacterium diptheriae, Shigella dysenteriae, Escherichia coli, burkholderia mallei, Listeria monocytogenes, Burkholderia pseudomallei, Yersinia pestis, Francisella tularensis, Chlamydophila psittaci, Coxiella burnetii, rickettsia, rickettsia prowazekii, rickettsia typhi), viruses (e.g., Eastern equine encephalitis virus. Venezuelan equine encephalitis virus, Western equine encephalitis virus, Japanese encephalitis virus, Rift Valley fever virus, Variola virus, Yellow Fever virus, Ebola virus, Marburg virus, coronaviruses), protozoa, parasites, fungi (Coccidioides immitis), pathogens, toxins, and biotoxins (Abrin. Botulinum toxin, Ricin, Saxitoxin, Staphylococcal enterotoxin B, tetrodotoxin, trichothecene mycotoxins).

In some examples, the analyte of interest comprises a greenhouse gas. Examples of greenhouse gases include, but are not limited to, water vapor, CO₂, CH₄, N₂O, O₃, and combinations thereof.

In some examples, the analyte of interest comprises a gas used, produced in, and/or produced as a by-product of semiconductor fabrication, industrial manufacture, chemical synthesis, or a combination thereof. In some examples, the analyte of interest comprises gases or chemicals used in semiconductor fabrication, examples of which include, but are not limited to C₄F₈, SF₆, and CF₄. In some examples, the analyte of interest comprises by-product gases or chemicals in semiconductor fabrication, examples of which include, but are not limited to, HCl. In some examples, the analyte of interest comprises gases or chemicals used in industrial manufacturing, examples of which include, but are not limited to, NO₂. In some examples, the analyte of interest comprises product or by-product gases or chemicals in industrial manufacturing, examples of which include, but are not limited to, NO₂ and NO. In some examples, the analyte of interest comprises gases or chemicals used in chemical synthesis, examples of which include, but are not limited to, acetone. In some examples, the analyte of interest comprises product or by-product gases or chemicals in chemical synthesis, examples of which include, but are not limited to, HNO₃.

In some examples, the analyte of interest comprises a gas or chemical that needs to be maintained at certain concentration examples of which include, but are not limited to, chemicals used in pest control, such as SO₂F₂.

In some examples, the analyte of interest comprises CO₂, SO₂, formaldehyde. CO, NH₃, N₂O, O₃, CH₄, NO, dimethyl methyl phosphonate (DMMP), or a combination thereof.

In some examples, the sensor is filterless (e.g., wherein the sensor comprises a filterless NDIR sensor).

Also disclosed herein are methods of use of any of the devices or sensors disclosed herein. For example, also disclosed herein are methods of use of any of the sensors disclosed herein for gas sensing. Also disclosed herein, for example, are methods of use of any of the sensors disclosed herein for environmental sensing, atmospheric sensing, chemical sensing, or a combination thereof.

### Methods of Designing

Also disclosed herein are methods for designing a Tamm polariton emitter. For example, also disclosed herein are methods for designing any of the Tamm polariton emitters disclosed herein. The methods can, for example, comprise an inverse design protocol. In some examples, the methods can comprise machine learning.

For example, also disclosed herein are methods for designing a Tamm polariton emitter, the Tamm polariton emitter comprising:
a distributed Bragg reflector, the distributed Bragg reflector comprising a stack of a plurality of layers of a plurality of materials with varying refractive index, wherein each layer comprises a material having a refractive index and each layer has an average thickness, wherein the refractive index of each layer is different than the preceding and/or subsequent layer; and
a layer comprising a conductive and/or polaritonic material;
wherein the distributed Bragg reflector is disposed on the layer of the conductive and/or polaritonic material;
wherein the Tamm polariton emitter emits radiation (e.g., electromagnetic radiation) at a frequency (e.g., one or more frequencies);
wherein the method comprises:
a. defining a target spectrum for the radiation emitted by the Tamm polariton emitter;
b. defining an initial set of values for a set of parameters for a designed Tamm polariton emitter;
   wherein the set of parameters comprises the total number of layers of the distributed Bragg reflector, the composition of each of the plurality of layers, the thickness of each of the plurality of layers, the composition of the layer of the conductive and/or polaritonic material, the carrier density of the layer of the conductive and/or polaritonic material, and the thickness of the layer of the conductive and/or polaritonic material;
   wherein, for the initial set of values, the initial total number of layers is user defined and the remaining parameters are randomly initialized;
c. modeling an emission spectrum for the designed Tamm polariton emitter having the initial set of parameters, written as vector (t), said modeled emission spectrum being a designed emission spectrum;
d. comparing the designed emission spectrum to the target emission spectrum to determine an error;
wherein the designed emission spectrum is modeled and compared with the target emission spectrum using a transfer matrix method;
wherein the error is a scalar error that is a combination of mean-squared error and mean absolute error;
when the error is greater than a predefined threshold, then the error is back-propagated to find a gradient over t via stochastic gradient descent, and the gradient is used to update t in the next iteration of steps c and d:

$${t}_{n} = {t}_{n - 1} - step \frac{\partial {error}_{n - 1}}{\partial {t}_{n - 1}}$$

wherein the iterations continue until the predefined maximum number of iterations is reached or the error is minimized;
when the number of iterations reaches the predefined maximum number without reaching the error threshold, then the number of layers is increased and the method is repeated; and
when the error is less than or equal to the defined threshold, then the method comprises outputting the set of parameters, the designed emission spectrum, the target emission spectrum, or a combination thereof.

Also disclosed herein, for example, are methods for designing a Tamm polariton emitter, the Tamm polariton emitter comprising:
a layer of a polar material;
a distributed Bragg reflector, the distributed Bragg reflector comprising a stack of a plurality of layers of a plurality of materials with varying refractive index, wherein each layer comprises a material having a refractive index and each layer has an average thickness, wherein the refractive index of each layer is different than the preceding and/or subsequent layer; and
a layer comprising a conductive and/or polaritonic material;
wherein the distributed Bragg reflector is disposed on the layer of the conductive and/or polaritonic material;
wherein the layer of the polar material is disposed on top of the distributed Bragg reflector, such that the distributed Bragg reflector is sandwiched between the layer of the conductive and/or polaritonic material and the polar material:
wherein the Tamm polariton emitter emits radiation at a frequency;
wherein the method comprises:
a. defining a target spectrum for the radiation emitted by the Tamm polariton emitter;
b. defining an initial set of values for a set of parameters for a designed Tamm polariton emitter;
   wherein the set of parameters comprises the total number of layers of the distributed Bragg reflector, the composition of each of the plurality of layers, the thickness of each of the plurality of layers, the composition of the layer of the conductive and/or polaritonic material, the carrier density of the layer of the conductive and/or polaritonic material, the thickness of the layer of the conductive and/or polaritonic material: the composition of the layer of the polar material, the carrier density of the layer of the polar material, and the thickness of the layer of the polar material;
   wherein, for the initial set of values, the initial total number of layers is user defined and the remaining parameters are randomly initialized;
c. modeling an emission spectrum for the designed Tamm polariton emitter having the initial set of parameters, written as vector (t), said modeled emission spectrum being a designed emission spectrum;
d. comparing the designed emission spectrum to the target emission spectrum to determine an error;
wherein the designed emission spectrum is modeled and compared with the target emission spectrum using a transfer matrix method;
wherein the error is a scalar error that is a combination of mean-squared error and mean absolute error;
when the error is greater than a predefined threshold, then the error is back-propagated to find a gradient over it via stochastic gradient descent, and the gradient is used to update t in the next iteration of steps c and d:

$${t}_{n} = {t}_{n - 1} - step \frac{\partial {error}_{n - 1}}{\partial {t}_{n - 1}}$$

wherein the iterations continue until the predefined maximum number of iterations is reached or the error is minimized;
when the number of iterations reaches the predefined maximum number without reaching the error threshold, then the number of layers is increased and the method is repeated; and
when the error is less than or equal to the defined threshold, then the method comprises outputting the set of parameters, the designed emission spectrum, the target emission spectrum, or a combination thereof.

In some examples, the error is defined by the following equation

$$Error = Mean ( ratio 1 {( DS - TS )}^{2} + r a tio 2 \vert DS - TS \vert )$$

where ratio1 and ratio2 are hyperparameters customized for different purposes, and DS and TS are vectors with each element standing for the absorptance at corresponding wavelength.

In some examples, steps c and/or d of the method includes a weighted sampling technique. In some examples, the weighted sample technique is based on the desired application, frequency region of interest, analyte of interest, or a combination thereof.

In some examples, the parameters can further include the frequency, amplitude, and/or line-width (e.g., FWHM) of the emitted radiation. In some examples, the parameters can further include a quality factor (e.g., Q factor). In some examples, the Q factor can be 1 or more (e.g., 2 or more; 3 or more; 4 or more; 5 or more; 10 or more; 15 or more; 20 or more; 30 or more; 40 or more; 50 or more; 75 or more; 100 or more; 125 or more; 150 or more; 175 or more; 200 or more; 250 or more; 300 or more; 350 or more; 400 or more; 450 or more; 500 or more; 600 or more; 700 or more; 800 or more; 900 or more; 1,000 or more; 1,250 or more; 1,500 or more; 1,750 or more; 2,000 or more; 2,250 or more; 2,500 or more; 3,000 or more; 3,500 or more; 4.000 or more; 4.500 or more; 5.000 or more; 6,000 or more; 7,000 or more; 8,000 or more; 9.000 or more; 10,000 or more; 12,500 or more: 15.000 or more; 17,500 or more; 20,000 or more; 22,500 or more; 25,000 or more: 30,000 or more; 35,000 or more; 40,000 or more; 45,000 or more; 50,000 or more; 60,000 or more; 70,000 or more; 80,000 or more; 90,000 or more; 100,000 or more; 125,000 or more; 150,000 or more; 175,000 or more; 200,000 or more; 250,000 or more: 300,000 or more; 350,000 or more; 400,000 or more; 450,000 or more; 500,000 or more; 600,000 or more; 700,000 or more; or 800,000 or more). In some examples, the Q factor can be 1,000,000 or less (e.g., 900,000 or less; 800,000 or less; 700,000 or less; 600,000 or less; 500,000 or less; 450,000 or less; 400,000 or less; 350,000 or less; 300,000 or less; 250.000 or less; 200,000 or less; 175.000 or less: 150,000 or less; 125,000 or less: 100,000 or less: 90,000 or less; 80,000 or less; 70,000 or less; 60,000 or less; 50,000 or less; 45,000 or less; 40,000 or less: 35,000 or less; 30,000 or less; 25,000 or less; 20,000 or less; 17,500 or less; 15,000 or less; 12,500 or less; 10,000 or less; 9,000 or less; 8,000 or less; 7,000 or less; 6,000 or less; 5,000 or less; 4,500 or less; 4,000 or less; 3,500 or less; 3,000 or less; 2,500 or less; 2,250 or less; 2,000 or less: 1,750 or less; 1,500 or less; 1.250 or less; 1.000 or less: 900 or less; 800 or less; 700 or less; 600 or less; 500 or less; 450 or less; 400 or less; 350 or less; 300 or less; 250 or less; 200 or less; 175 or less; 150 or less; 125 or less; 100 or less; 75 or less; 50 or less; 40 or less; 30 or less; 25 or less; 15 or less; 10 or less; 5 or less; 4 or less; or 3 or less). The Q factor can range from any of the minimum values described above to any of the maximum values described above. For example, the Q factor can be from 1 to 1,000,000 (e.g., from 1 to 1,000; from 1,000 to 1,000,000; from 1 to 100; from 100 to 10,000; from 10,000 to 1,00,000; from 10 to 1,000,000; from 1 to 900,000; from 10 to 900,000; from 1 to 900,000; from 1 to 500,000; from 1 to 100,000: from 5 to 1,000,000: from 50 to 1.000,000; from 100 to 1,00,000: or from 500 to 1,000,000).

In some examples, the method comprises machine learning.

In some examples, the Tamm polariton emitter comprises a plurality of Tamm polariton emitters and the parameters further include the number of Tamm polariton emitters in the plurality of Tamm polariton emitters.

In some examples, the method comprises designing a first Tamm polariton emitter and a second Tamm polariton emitter, wherein the second Tamm polariton emitter comprises a Tamm polariton detector. In some examples, the first Tamm polariton emitter is configured to selectively emit radiation at one or more frequencies and the second Tamm polariton emitter is configured to selectively receive at least a portion of the radiation emitted by the first Tamm polariton emitter (e.g., the first Tamm polariton emitter and the Tamm polariton detector are matched). In some examples, the method further comprises maximizing the overlap between the radiation emitted by the Tamm polariton emitter and the radiation received by the detector.

In some examples, the first Tamm polariton emitter comprises a first plurality of Tamm polariton emitters, the second Tamm polariton emitter comprises a second plurality of Tamm polariton emitters, or a combination thereof. In some examples, the first Tamm polariton emitter comprises a first plurality of Tamm polariton emitters and the parameters include the number of first Tamm polariton emitters in the first plurality, the second Tamm polariton emitter comprises a second plurality of Tamm polariton emitters and the parameters include the number of second Tamm polariton emitters in the plurality, or a combination thereof.

### Computing Device

The devices (e.g., sensors) can, in some examples, comprise a computing device. Any of the methods disclosed herein can be carried out in whole or in part on one or more computing or processing devices.

FIG. 71 illustrates an example computing device 1000 upon which examples disclosed herein may be implemented. The computing device 1000 can include a bus or other communication mechanism for communicating information among various components of the computing device 1000. In its most basic configuration, computing device 1000 typically includes at least one processing unit 1002 (a processor) and system memory 1004. Depending on the exact configuration and type of computing device, system memory 1004 may be volatile (such as random access memory (RAM)), non-volatile (such as read-only memory (ROM), flash memory, etc.), or some combination of the two. This most basic configuration is illustrated in FIG. 71 by a dashed line 1006. The processing unit 1002 may be a standard programmable processor that performs arithmetic and logic operations necessary for operation of the computing device 1000.

The computing device 1000 can have additional features/functionality. For example, computing device 1000 may include additional storage such as removable storage 1008 and non-removable storage 1010 including, but not limited to, magnetic or optical disks or tapes. The computing device 1000 can also contain network connection(s) 1016 that allow the device to communicate with other devices. The computing device 1000 can also have input device(s) 1014 such as a keyboard, mouse, touch screen, antenna or other systems configured to communicate with the camera in the system described above, etc. Output device(s) 1012 such as a display, speakers, printer, etc. may also be included. The additional devices can be connected to the bus in order to facilitate communication of data among the components of the computing device 1000.

The processing unit 1002 can be configured to execute program code encoded in tangible, computer-readable media. Computer-readable media refers to any media that is capable of providing data that causes the computing device 1000 (i.e., a machine) to operate in a particular fashion. Various computer-readable media can be utilized to provide instructions to the processing unit 1002 for execution. Common forms of computer-readable media include, for example, magnetic media, optical media, physical media, memory chips or cartridges, a carrier wave, or any other medium from which a computer can read. Example computer-readable media can include, but is not limited to, volatile media, non-volatile media, and transmission media. Volatile and non-volatile media can be implemented in any method or technology for storage of information such as computer readable instructions, data structures, program modules or other data and common forms are discussed in detail below. Transmission media can include coaxial cables, copper wires and/or fiber optic cables, as well as acoustic or light waves, such as those generated during radio-wave and infra-red data communication. Example tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In an example implementation, the processing unit 1002 can execute program code stored in the system memory 1004. For example, the bus can carry data to the system memory 1004, from which the processing unit 1002 receives and executes instructions. The data received by the system memory 1004 can optionally be stored on the removable storage 1008 or the non-removable storage 1010 before or after execution by the processing unit 1002.

The computing device 1000 typically includes a variety of computer-readable media. Computer-readable media can be any available media that can be accessed by device 1000 and includes both volatile and non-volatile media, removable and non-removable media. Computer storage media include volatile and non-volatile, and removable and non-removable media implemented in any method or technology for storage of information such as computer readable instructions, data structures, program modules or other data. System memory 1004, removable storage 1008, and non-removable storage 1010 are all examples of computer storage media. Computer storage media include, but are not limited to, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by computing device 1000. Any such computer storage media can be part of computing device 1000.

It should be understood that the various techniques described herein can be implemented in connection with hardware or software or, where appropriate, with a combination thereof. Thus, the methods, systems, and associated signal processing of the presently disclosed subject matter, or certain aspects or portions thereof, can take the form of program code (i.e., instructions) embodied in tangible media, such as floppy diskettes, CD-ROMs, hard drives, or any other machine-readable storage medium wherein, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs can implement or utilize the processes described in connection with the presently disclosed subject matter, e.g., through the use of an application programming interface (API), reusable controls, or the like. Such programs can be implemented in a high level procedural or object-oriented programming language to communicate with a computer system. However, the program(s) can be implemented in assembly or machine language, if desired. In any case, the language can be a compiled or interpreted language and it may be combined with hardware implementations.

In certain examples, the methods can be carried out in whole or in part on a computing device 1000 comprising a processor 1002 and a memory 1004 operably coupled to the processor 1002, the memory 1004 having further computer-executable instructions stored thereon that, when executed by the processor 1002, cause the processor 1002 to carry out one or more of the method steps described above.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the systems and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1—Deterministic Inverse Design of Tamm Plasmon Thermal Emitters with Multi-Resonant Control

Abstract. Herein, stochastic gradient descent is used to optimize Tamm plasmon polariton emitters (TPP-EMs) composed of an aperiodic distributed Bragg reflector deposited on doped cadmium oxide (CdO) film, where layer thicknesses and carrier density are inversely designed. The combination of the aperiodic distributed Bragg reflector with the designable plasma frequency of CdO enables multiple Tamm plasmon polariton emitter modes to be simultaneously designed with arbitrary spectral control not accessible with metal-based Tamm plasmon polaritons. Using this approach, Tamm plasmon polariton emitters exhibiting single or multiple emission bands with designable frequencies, line-widths and amplitudes were experimentally demonstrated and numerically proposed. This thereby enables lithography-free, wafer-scale wavelength-selective thermal emitters that are complementary metal-oxide-semiconductor compatible for applications such as free-space communications and gas sensing.

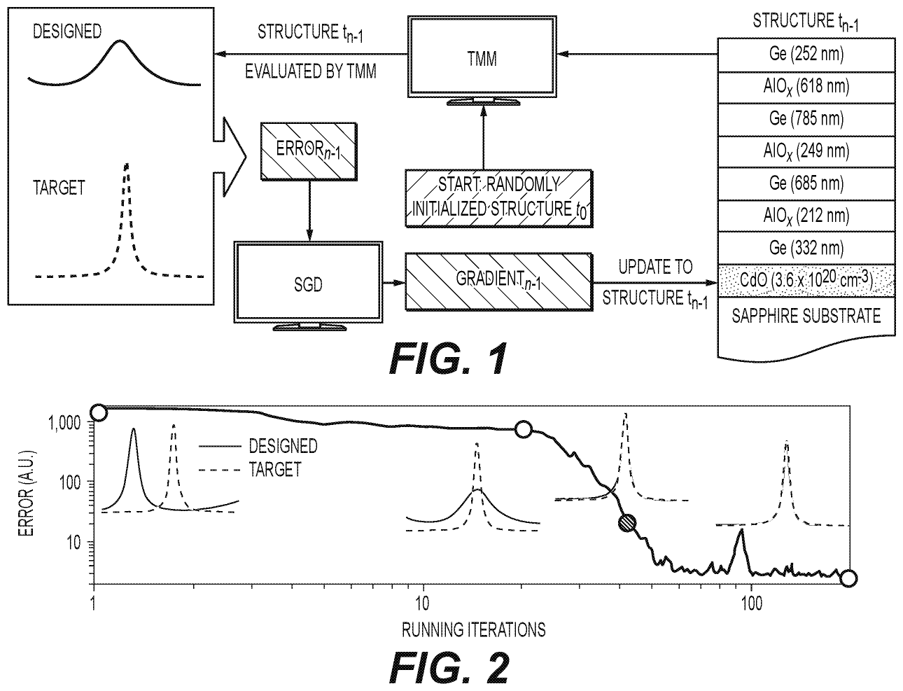

Introduction. The development of cheap and effective light sources in the infrared is highly desired for numerous applications. These range from free-space communications and infrared beacons to bar-codes and could improve the ability to monitor environmental pollutants and toxins through molecular sensing metrologies, such as non-dispersive infrared (NDIR) sensing. Thus, wavelength-selective thermal emitters are of particular interest due to the lack of cost-effective light sources in the mid- to long-wave infrared (MWIR, LWIR) (Baranov D G et al. Nat. Mater. 2019, 18, 920-930). Most proposed Wavelength-selective thermal emitters employ patterned nanostructures, thereby requiring high-cost, low-throughput lithographic methods, and are therefore inappropriate for many applications. An alternative solution is Tamm plasmon polariton heterostructures (Kaliteevski M et al. Phys. Rev. B 2007, 76, 165415). Such Tamm plasmon polariton structures consist of a distributed Bragg reflector (DBR) on a conductor (FIG. 1), typically a noble metal, where the distributed Bragg reflector provides optical phase matching to the metal surface, resulting in an absorptive resonance with a high quality factor (Q-factor; narrow line-width) at near-normal incident angles (Kaliteevski M et al. Phys. Rev. B 2007, 76, 165415; Sasin M E et al. Appl. Phys. Lett. 2008, 92, 251112; Sakurai A et al. ACS Cent. Sci. 2019, 5, 319-326; Wang Z et al. ACS Photon. 2020, 7, 1569-1576: Wang Z et al. ACS Photon. 2018, 5, 2446-2452). As only thin-film deposition is required for fabrication, Tamm plasmon polariton emitters can be grown at the wafer scale with relatively low-cost and minimal fabrication steps, offering a promising candidate for wavelength-selective thermal emitters (Sakurai A et al. ACS Cent. Sci. 2019, 5, 319-326; Wang Z et al. ACS Photon. 2020, 7, 1569-1576; Wang Z et al. ACS Photon. 2018, 5, 2446-2452).

Despite the broad potential of Tamm plasmon polariton emitters, design of such structures is challenging, as most applications require simultaneous control over both emission frequencies and corresponding Q-factors, and suppression of emission at other frequencies. Compared with traditional Tamm plasmon polariton emitters based on periodic distributed Bragg reflectors (Yang Z Y et al. ACS Photon. 2017, 4, 2212-2219), aperiodic structures provide additional spectral control, allowing for the suppression of spurious emission peaks (Botros J et al. J Appl. Phys. 2020, 127, 114502), while simultaneously achieving ultra-high Q-factors (Sakurai A et al. ACS Cent. Sci. 2019, 5, 319-326: Wang Z et al. ACS Photon. 2020, 7, 1569-1576). However, due to the large parameter space associated with the design of aperiodic distributed Bragg reflectors, forward-design methodologies are not efficient and thus, inverse design protocols must be used, with high-Q-factor Tamm plasmon polariton emitters demonstrated at a single desired wavelength via Bayesian optimization and a genetic algorithm (Botros J et al. J. Appl. Phys. 2020, 127, 114502) with high accuracy. However, such earlier works exhibited poor optimization efficiencies, requiring upwards of 24-day-long simulations per optimized structure (Sakurai A et al. ACS Cent. Sci. 2019, 5, 319-326). More importantly, the design of multiple emission peaks, where the frequency, amplitude and line-width of each resonance can be controlled independently, has not been realized. Using such a multi-peak Tamm plasmon polariton emitter, the sensing of multiple gases of interest simultaneously as well as high-sensitivity gas detection could both be achieved when the Tamm plasmon polariton emitter resonances were matched to several vibrational modes of one or multiple chemicals. Furthermore, in experimental reports, only noble metals have been used so far, which due to the plasma frequency falling in the visible range thereby severely restricts the spectral control, while also being incompatible with complementary metal-oxide-semiconductor (CMOS) processing.

Herein, an inverse design algorithm is presented to efficiently optimize Tamm plasmon polariton emitters composed of an aperiodic distributed Bragg reflector grown on an n-type, In-doped cadmium oxide (CdO) film, offering individual control of multi-peak wavelength-selective thermal emitters. The inverse design protocol is based on stochastic gradient descent (SGD) that allows for the individual layer thicknesses, as well as the carrier density (and thus the dielectric function) of CdO to be optimized efficiently (minutes on a consumer-grade desktop) (Nolen J R et al. Phys. Rev. Mater. 2020, 4, 025202). The design approach is experimentally validated and single-, dual- and triple-band Tamm plasmon polariton emitters are realized over a broad spectral range, with all structures exhibiting excellent agreement between experiments and simulations. Importantly, the advantages of multi-peak Tamm plasmon polariton emitters for non-dispersive infrared applications, such as enabling simultaneous detection of multiple gases with high sensitivity, are numerically verified. Furthermore, the design capabilities of CdO-based Tamm plasmon polariton emitters are illustrated by demonstrating the ability to match the resonant frequencies, line shapes, and amplitudes of arbitrarily shaped spectra extending from the long-wave infrared to telecommunication bands, including the ability to define Q-factors over a broad range of values at any given frequency (for example, 27-10,117 was demonstrated at 2,360 cm⁻¹). Finally, it is stressed that such functionality is not possible within noble-metal-based Tamm plasmon polariton emitters but instead is enabled by the broadly tunable plasma frequency of CdO (Nolen J R et al. Phys. Rev. Mater. 2020, 4, 025202; Liu C P et al. Phys. Rev. Appl. 2016, 6, 064018; Runnerstrom E L et al. ACS Photonics, 2017, 4, 1885-1892; Sachet E et al. Nat. Mater. 2015, 14, 414-420; Cleri A et al. Phys. Rev. Mater. 2021, 5, 035202). The combination of the efficient inverse design algorithm with these material advancements facilitates the realization of cost-effective, wafer-scale, CMOS-compatible, and lithography-free Tamm plasmon polariton emitters for numerous applications, including multi-gas non-dispersive infrared; environmental, atmospheric and chemical sensing; free-space communications; and infrared beacons.

Stochastic Gradient Descent-based inverse design protocol. The Tamm plasmon polariton emitters discussed here are composed of aperiodic distributed Bragg reflectors comprising Ge and AlOₓ alternating layers grown on thin (˜500 nm) CdO films on sapphire substrates (FIG. 1). The individual layer thicknesses and CdO carrier density (thus the dielectric function (Nolen J R et al. Phys. Rev. Mater. 2020, 4, 025202)) are all included as design parameters, written as a vector (t). A stochastic gradient descent-based inverse design technique is employed to determine t, so that the difference between the absorption spectrum of the designed structure (the designed spectrum. DS) and the target spectrum (TS) is minimized. The design process is initiated by assigning the user-preferred maximum number of layers for the distributed Bragg reflector, with t being randomly initialized. Through the transfer matrix method (TMM), the designed spectrum of the corresponding structure t is calculated and compared to the target spectrum, resulting in a scalar error. The error is written as a combination of mean-squared error (the first term) and mean absolute error (the second term):

$$Error = Mean ( ratio 1 {( DS - TS )}^{2} + r a tio 2 \vert DS - TS \vert ) \qquad ( 1 )$$

where ratio1 and ratio2 are hyperparameters customized for different purposes, and DS and TS are vectors with each element standing for the absorptance at corresponding wavelength. Note this combination of error is commonly employed in the deep-learning field, and related techniques are powerful for optimizing Tamm plasmon polariton emitter design, such as weighted sampling approaches (Section S1). This error is then back-propagated to find the gradient over t via stochastic gradient descent. Upon each iteration, the gradient is used to update t:

$${t}_{n} = {t}_{n - 1} - step \frac{\partial {error}_{n - 1}}{\partial {t}_{n - 1}} \qquad ( 2 )$$

After each successive iteration, the error is decreased, and the iterations will continue until a predefined maximum number. As such, the structure of the Tamm plasmon polariton emitter will be optimized to a point where the error between the target spectrum and designed spectrum is minimized.

While optimization processes take a different form on each run, one example is presented in FIG. 2. Initially, the absorption spectrum of the randomly initialized structure (red solid line) differs significantly from the target spectrum. After several iterations, the designed spectrum converges towards the target spectrum (see solid red→blue→green→purple lines in FIG. 2). Unlike the canonical gradient descent calculations used in commercial software and previous publications (Xue W et al. Arxiv, 2021, https://arxiv.org/abs/2101.03160; Jiang J et al. Nanophotonics 2021, 10, 361-369), the stochastic gradient descent approach employed here reduces the possibility of getting trapped at poor local minimums and improves the optimization performance (Section S2) (Bordes A et al. J. Mach. Learn. Res. 2009, 10, 1737-1754; Sohl-Dickstein J et al. Proc. Mach. Learn. Res. 2014, 32, 604-612: Kingma D P et al. Arxiv, 2015, https://arxiv.org/abs/1412.6980; Robbins H et al. Ann. Math. Stat. 1951, 22, 400-407). Although the method is still a local optimization, the stochastic gradient descent methodology approaches that of global optimization, offering high accuracy and efficiency compared with other methods (Table 1). The code is downloadable online (https://my.vanderbilt.edu/caldwellgroup/).

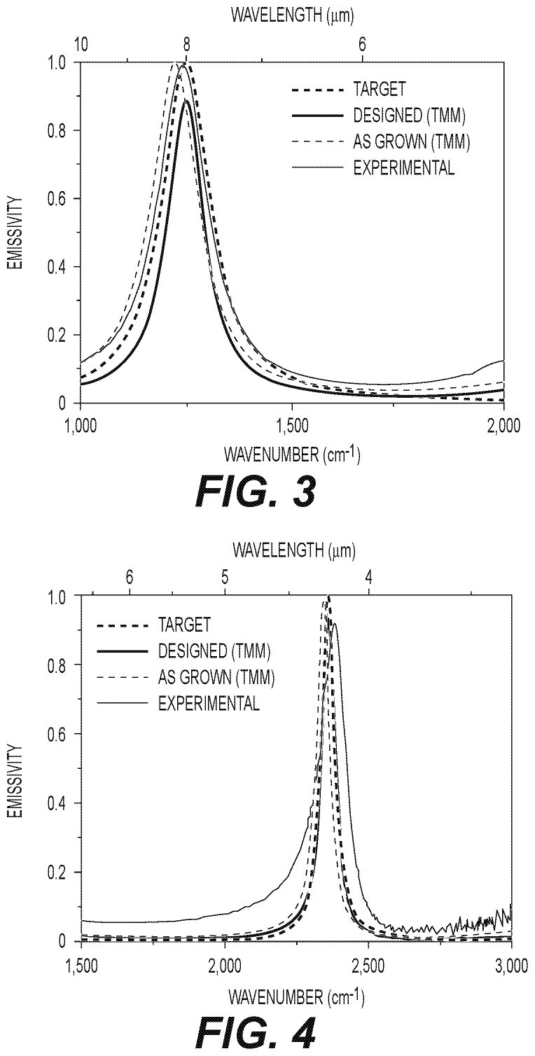

Experimental demonstration of inversely designed Tamm plasmon polariton emitters. Based on the inverse design algorithm, several Tamm plasmon polariton emitter structures were designed and fabricated, exhibiting a wide range of unique spectral features. The CdO carrier densities and the designed and as-grown layer thicknesses of these structures are provided in Section S4 below, and the growth process is discussed in the Methods. Note that more complicated spectra (higher Q-factors, more peaks and so on) can be realized when a distributed Bragg reflector featuring more layers is utilized; yet, once a target can be realized with a certain number of layers, adding additional layers does not provide any additional advantage (Section S6). Thus, in the experimental demonstrations, the least possible number of layers were employed to match the target spectrum to simplify fabrication. To demonstrate the power of inversely designed Tamm plasmon polariton emitters, an experimental device featuring a single emission peak in the long-wave infrared (800-1,250 cm⁻¹) for free-space communications was first provided. The target spectrum was modeled as a flat line with a single, sharp absorption peak centered at 1,250 cm⁻¹ and the stochastic gradient descent method was employed to match the designed spectrum to the narrowest possible target spectrum line-width (FIG. 3). Following this optimization, the spectrum of the designed structure exhibits a single peak centered at 1,250 cm⁻¹ with a Q-factor of 13, while the experimentally resultant Q-factor is ˜9. The target, experimentally measured, and calculated spectra based on the designed and as-grown thicknesses all show excellent agreement, with all four exhibiting nearly overlapping resonance lines (FIG. 3).

In addition to emitters for communications, the long-wave infrared and mid-wave infrared contain molecular absorption features; thus, one application of wavelength-selective thermal emitters is filterless non-dispersive infrared gas sensing. A filterless non-dispersive infrared sensor comprises a wavelength-selective thermal emitter, a gas cell, and a broadband detector (Section S7). The emission frequency of the wavelength-selective thermal emitter is centered at the absorption frequency of the gas of interest with a sufficiently high Q-factor to eliminate false positives resulting from absorption by other gases present. For such applications, a heterostructure supporting a single emissivity peak at one absorption band of CO₂ (2,349 cm⁻¹) was first demonstrated. Again, excellent agreement is observed, with the measured (target) emission peak centered at 2,360 cm⁻¹ (2,350 cm⁻¹) with a Q-factor of 21 (40), as shown in FIG. 4. However, while these single-peak emitters can be efficiently designed with the protocol described herein, they can also be realized via other approaches such as intuition-guided forward design (Yang Z Y et al. ACS Photon. 2017, 4, 2212-2219), Bayesian optimization (Sakurai A et al. ACS Cent. Sci. 2019, 5, 319-326; Zhang W et al. ACS Appl. Energy Mater. 2021, 4, 2004-2013), and genetic algorithms (Botros J et al. J Appl. Phys. 2020, 127, 114502), albeit requiring substantially more effort.

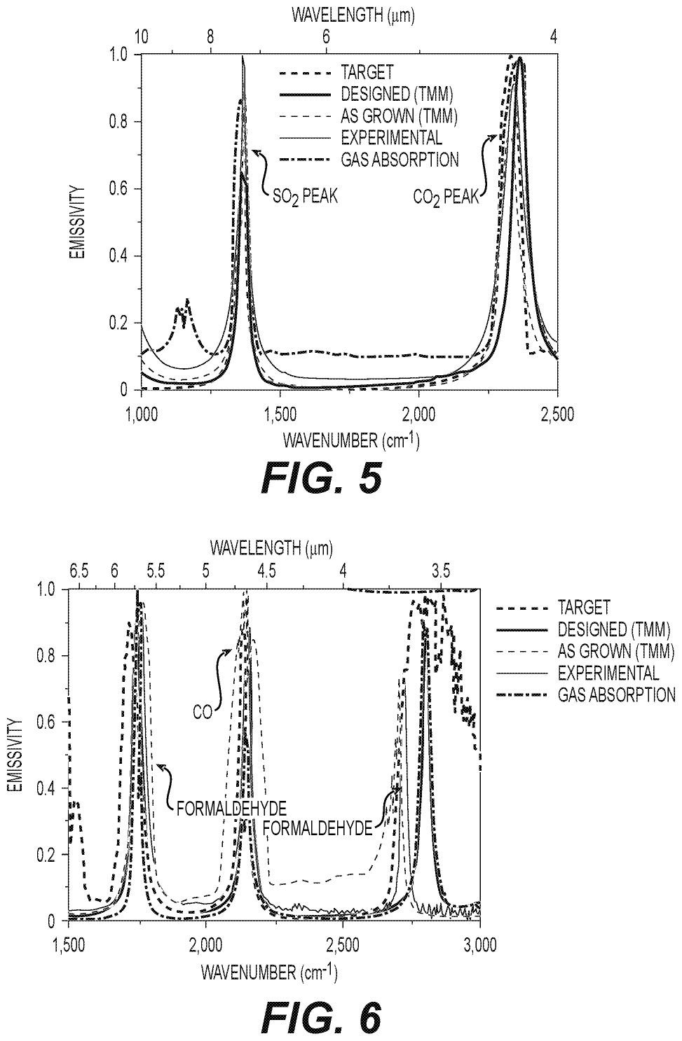

So far, Tamm plasmon polariton emitter designs have been demonstrated with an isolated, tunable emissivity peak, making these devices suitable for applications such as single, simple gas detection. In addition to the applications enabled by such single-peak Tamm plasmon polariton emitters, more advanced functions can be realized via multi-frequency Tamm plasmon polariton emitters, such as infrared signature management and multi-channel non-dispersive infrared. For non-dispersive infrared, additional emission channels can be used to either detect more gases of interest or enhance the sensitivity to a specific gas by aligning the emission to multiple vibrational modes. Yet, wavelength-selective thermal emitters with independent design control for multiple distinct emission peaks have not been previously demonstrated. First, the functionality of the Tamm plasmon polariton emitters is exemplified by demonstrating a device suitable for simultaneous SO₂ and CO₂ dual-gas sensing, with the rationale for the target spectrum provided in Section S8 below. Additionally, SO₂ and CO₂ concentrations can be independently evaluated using this Tamm plasmon polariton emitter operating at different temperatures (Section S9). Here, five dielectric layers were used, yielding a designed spectrum with two absorption peaks centered at 1,367 and 2,339 cm⁻¹ (FIG. 5), which closely match the amplitudes, peak positions, and full-width-half-maximums (FWHMs) of the target spectrum. The experimental data also agree well, albeit with some minor exceptions. While the center frequencies are closely matched (1,358 and 2,360 cm⁻¹), some degradation in the Q-factors and emissivity amplitudes are observed. Spectral discrepancies are minimal despite differences between the as-grown and designed thicknesses, indicating robustness against fabrication errors (Section S10). Notably, limited thickness error is expected in foundry-level fabrication.

The functionality of the Tamm plasmon polariton emitter is not limited to dual-band emission, and more bands at user-designed frequencies can be realized. To exemplify this capability, a target spectrum featuring three emission peaks centered at the absorption bands of CO and formaldehyde (1,750 cm⁻¹, 2,150 cm⁻¹ and 2.800 cm⁻¹) was also modelled, with increasing FWHMs to compensate for the black-body emission shape (20, 30 and 40 cm⁻¹, respectively) imposed on the resultant Tamm plasmon polariton emitter spectrum. Again, excellent agreement between the target spectrum, designed spectrum, and experimental structures for the designed Tamm plasmon polariton emitter is realized for each of the curves (FIG. 6) with the peak analyses provided in Table 3. Although the thickness difference from fabrication shifts one resonance by 70 cm⁻¹, it remains within the formaldehyde absorption band, thereby still allowing enhanced sensitivity for non-dispersive infrared applications.

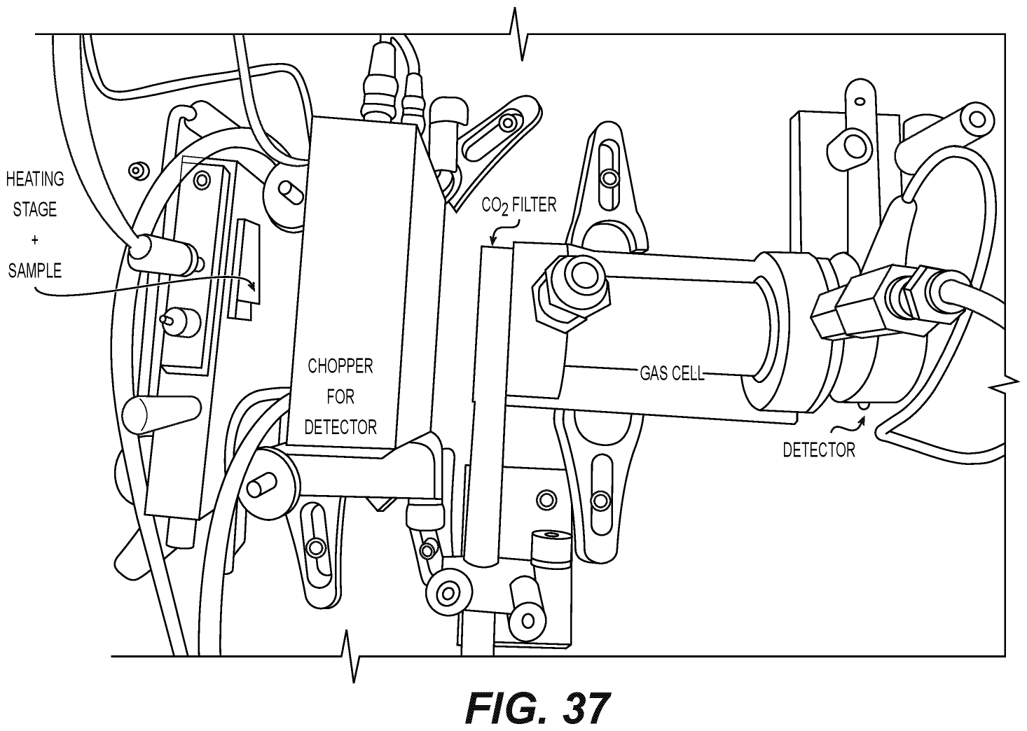

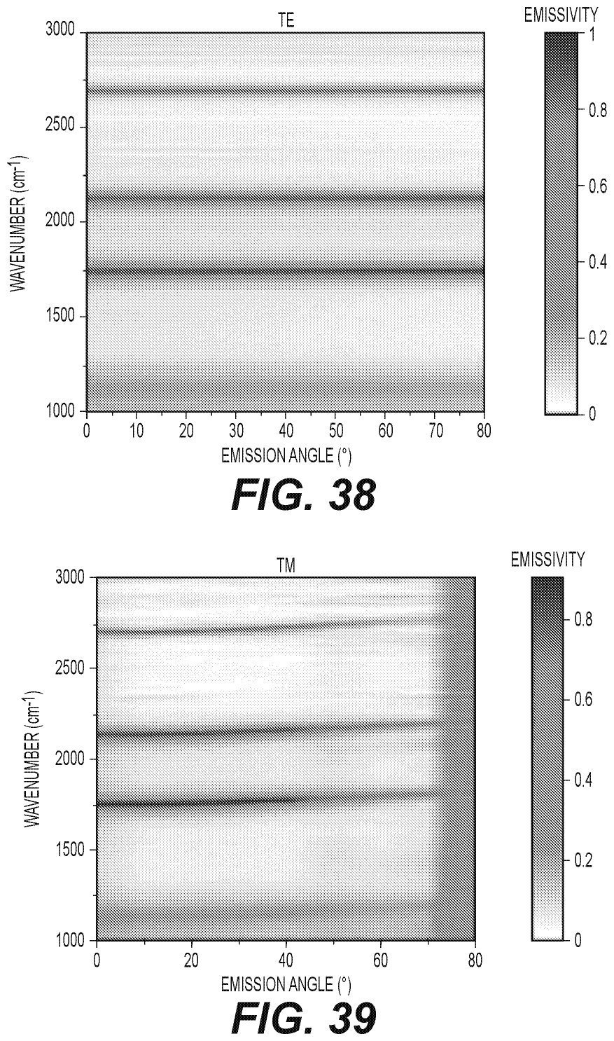

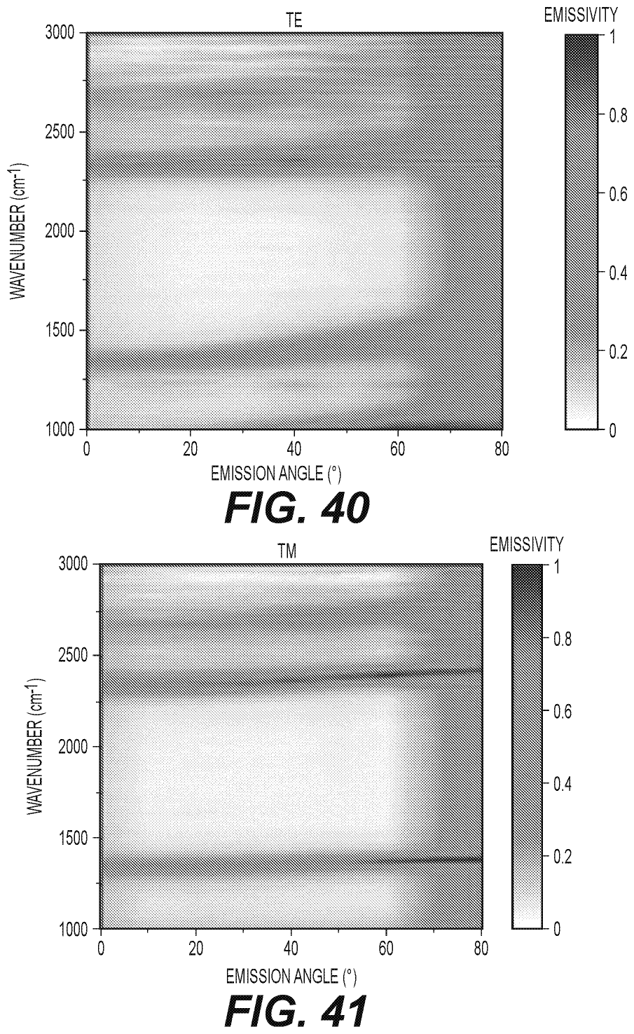

The multi-resonance control demonstrated above is critical for numerous applications such as multi-frequency infrared beacons for encryption purposes and advanced non-dispersive infrared applications. Here, the implications of the experimental devices in filterless non-dispersive infrared applications are theoretically illustrated and compared with conventional non-dispersive infrared devices enabled by black-body emitters and filters (Table 4 and Table 5). The advantages of multi-peak Tamm plasmon polariton emitters are (1) improved sensitivity when multiple absorption bands are aligned; (2) the potential of multi-gas sensing within a single compact package; and (3) reduced power consumption. Note that the single-peak Tamm plasmon polariton emitters provide identical sensitivity with ˜5-10 times lower power consumption (FIG. 37 and Table 6). Importantly, the angular dispersions of Tamm plasmon polariton emitters are inherently low (FIG. 38-FIG. 41), eliminating issues from viewing angles as well. Thus, the experimentally demonstrated ability to control the emission frequencies with desired Q-factors provides substantial advantages for such applications, including low false-positive rates and high-sensitivity gas sensing of multiple gases simultaneously within a single, compact non-dispersive infrared package.

Potential for inversely designed Tamm plasmon polariton emitters. For advanced Wavelength-selective thermal emitter applications, such as spectral bar-coding and multi-gas sensing, user-defined FWHMs and amplitudes at single or multiple frequencies must be realized. Yet, no earlier design approaches have been proposed to accomplish these tasks with the necessary accuracy. To address these challenges and demonstrate further the potential of the inversely designed Tamm plasmon polariton emitters, the design capabilities were explored by utilizing a Ge/ZnSe distributed Bragg reflector with 29 layers on a bilayer of CdO (all designed structures are included in Section S14).

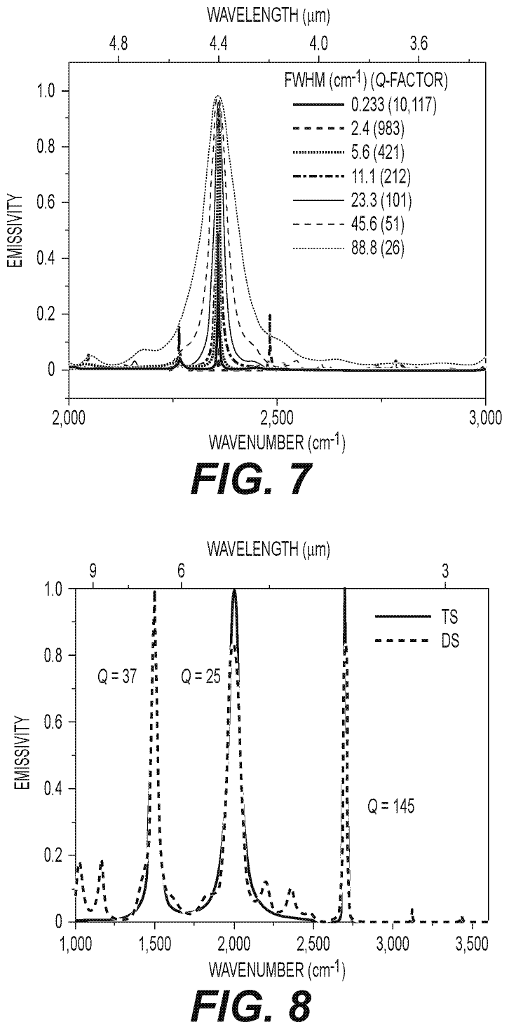

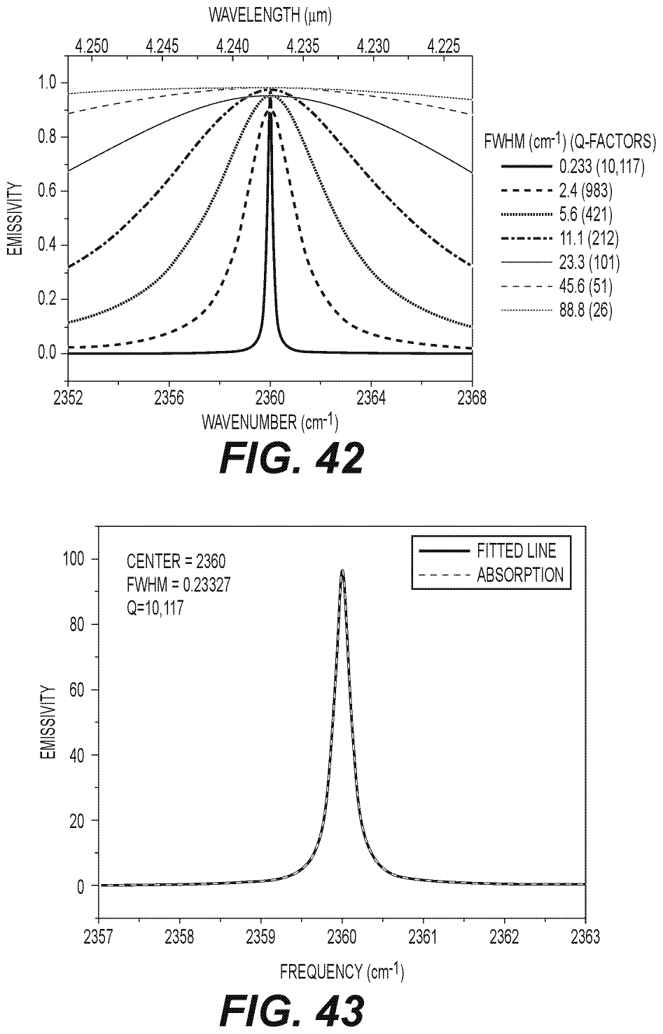

First, the outstanding control over the line-width at a fixed frequency was demonstrated by presenting structures with Q-factors ranging from 26 to 10,117 while maintaining near-unity emission for all designs (FIG. 7 and FIG. 42). Thus, the potential not only to achieve ultra-high Q-factors for Tamm-based structures (fitting in FIG. 43), but also to match the required Q-factor at a given frequency was shown. Such a capability is imperative as different applications have varied requirements for signal-to-noise ratio. Building on this, the potential for such multi-peak designs was expanded upon by providing a target spectrum that exhibits three emission peaks with varying line-widths (Q-factors=25, 37 and 145). Such Tamm plasmon polariton emitter designs are suitable for spectral bar-coding and sensing, yet have not been demonstrated or proposed, presumably due to the extensive design challenges in matching such complex spectra. Despite this difficulty, the designed spectrum can be matched to the target spectrum exceptionally well, with only minor discrepancies (FIG. 8).

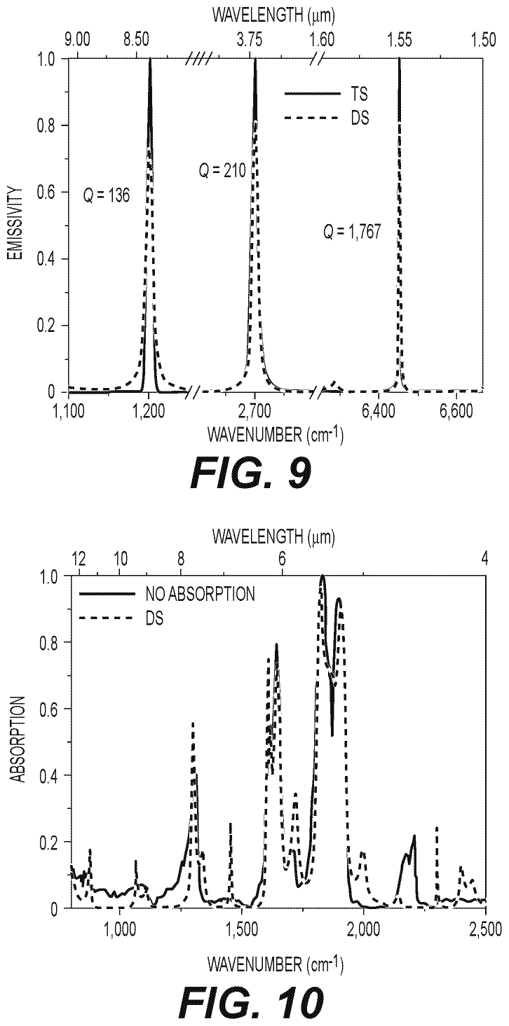

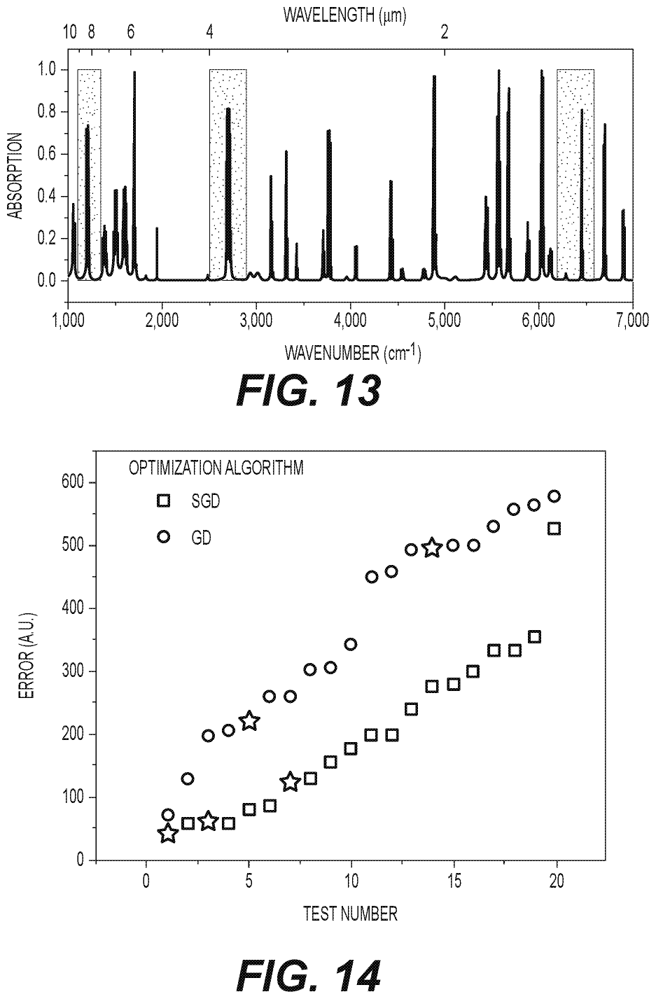

Empowered by the broadly tunable plasma frequency of CdO (between ˜1,200 cm⁻¹ and 7,800 cm⁻¹), Tamm plasmon polariton emitters with absorption peaks spanning from the short-wave infrared to the long-wave infrared can also be realized. To demonstrate such capabilities, another Tamm plasmon polariton emitter structure featuring three spectrally distinct emission peaks, located in the long-wave infrared (1,200 cm⁻¹), mid-wave infrared (2,700 cm⁻¹) and short-wave infrared (1.55 m) simultaneously (FIG. 9), was optimized. Again, the resultant designed spectrum matches the target spectrum exceptionally well. Additional modes are present in the spectral regions between these desired emission resonances (FIG. 13), which is a fundamental restriction of the multi-modal nature of distributed Bragg reflectors. However, the influence of these additional peaks can be mitigated by the weighted sampling technique (Section S1 and Section S15).

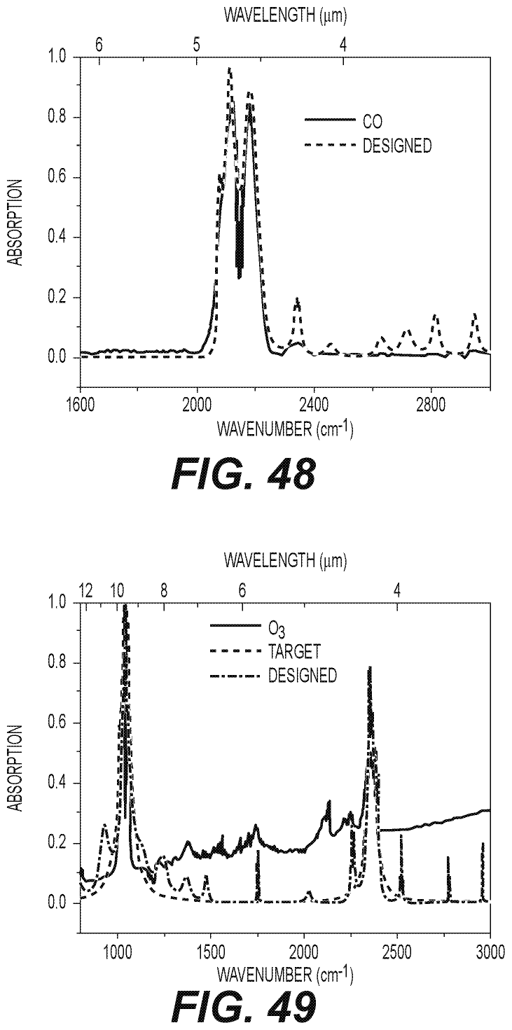

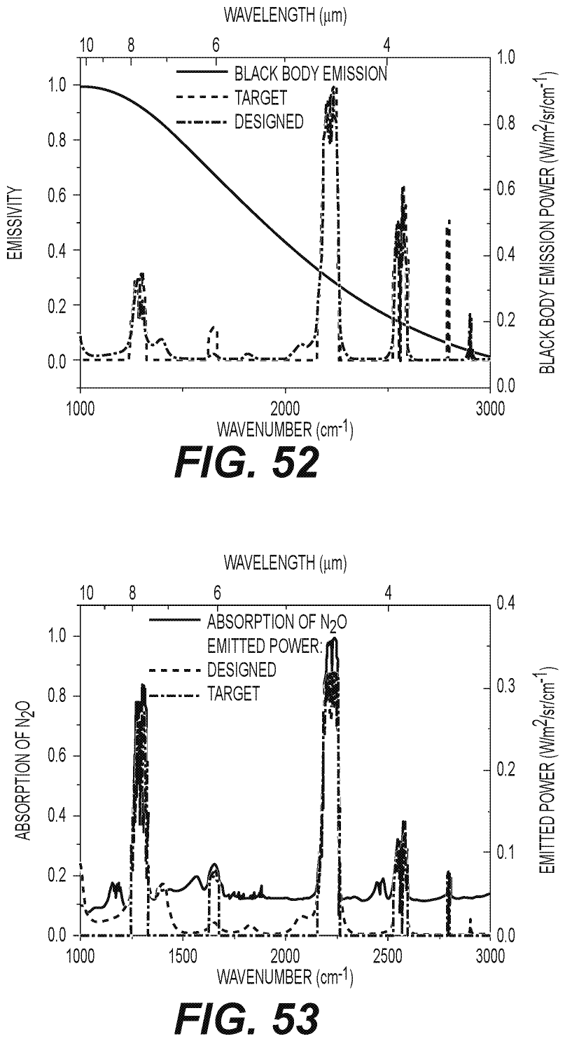

Finally, the potential of Tamm plasmon polariton emitters in advanced non-dispersive infrared applications is emphasized. Here, it is desirable to match the emitted power to the chemical absorption spectra for two reasons: (1) the amount of emitted power should be absorbed as much as possible—that is, it should emit energy at all chemical absorption bands; and (2) emitted power should only be absorbed by the gas of interest to avoid false positives, meaning the FWHM of the target spectrum cannot be substantially broader than the gas spectra. As the emitted power is temperature dependent, this concept is generalized by matching the Tamm plasmon polariton emitter to the chemical absorption spectra. One example is provided for nitrogen monoxide non-dispersive infrared gas sensing in FIG. 10. This molecule features multiple arbitrarily distributed absorption bands with varying FWHMs and amplitudes between 800 and 2,400 cm⁻¹, making forward-design approaches unrealistic. Yet, the inverse design algorithm herein provides an optimized Tamm plasmon polariton emitter structure with a designed spectrum closely matched to the spectral positions, amplitudes and FWHMs of the target spectrum peaks, with undesirable additional modes greatly suppressed (FIG. 10). The same approach is applied to non-dispersive infrared sensing of greenhouse gases such as CO, O₃, NH₃ and CH₄, as shown in FIG. 48-FIG. 51. In addition, the shape of the black-body emission can be deconvoluted in the design process so that the emitted power, rather than the emissivity, can be matched to an arbitrarily shaped target spectrum, which is exemplified for N₂O non-dispersive infrared sensing at 250° C. working temperature (FIG. 52-FIG. 53). None of the designs in FIG. 7-FIG. 10 have been previously proposed, as the user-defined control of the FWHMs and amplitudes at single/multiple frequencies is not realistic within traditional forward-design approaches. Thus, the design capabilities highlighted here facilitate wavelength-selective thermal emitter-based applications for free-space communications, spectral bar-coding, multi-band chemical sensing with high signal-to-noise ratio for highly selective non-dispersive infrared or alternative gas-sensing metrologies.

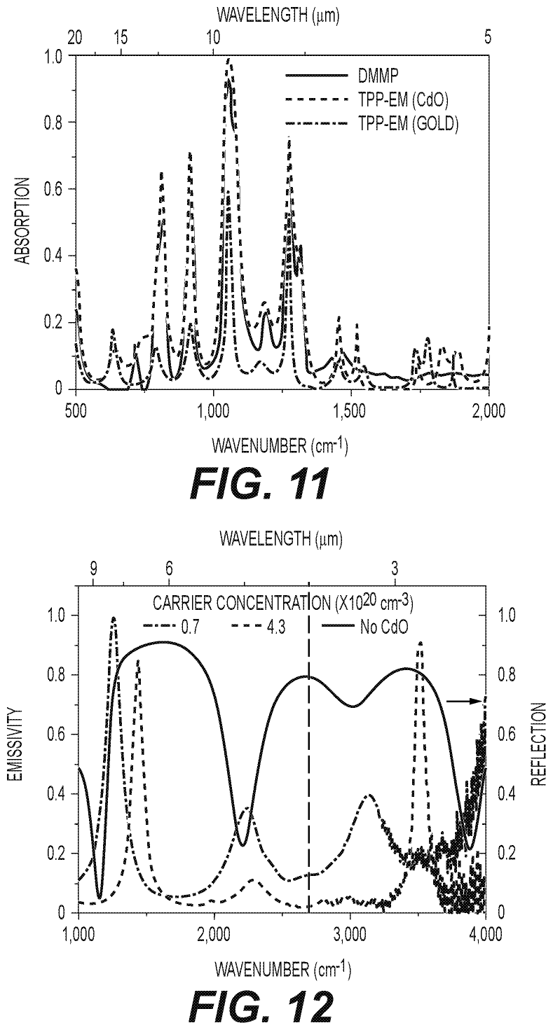

CdO as the enabling component for our Tamm plasmon polariton emitters. So far, the exceptional design freedom offered by the inverse design approach for dictating the emissivity and/or spectrally emitted power of Tamm plasmon polariton emitter devices has been demonstrated. The deterministic design capabilities benefit from two things: the stochastic gradient descent-optimized aperiodic distributed Bragg reflectors and the use of In-doped CdO with a designable dielectric function. It is the aperiodic distributed Bragg reflector that exploits the control over the photonic band structure, yet, it is the designable dielectric function of CdO that improves this spectral control to an unprecedented level, allowing for more advanced designs to be realized. To illustrate this point, the stochastic gradient descent-based algorithm was employed to design a CdO-based and a gold-based Tamm plasmon polariton emitter to match the absorption spectrum of the nerve agent simulant dimethyl methyl phosphonate for high-sensitivity gas detection. Related detailed optimizations are discussed in Section S18. Here, an exceptional agreement between the target spectrum and the CdO-based Tamm plasmon polariton emitter designed spectrum is achieved (FIG. 11), including spectral positions, line shapes and even amplitudes. However, for the gold-based structure, the absorption spectrum cannot be matched well (FIG. 11, blue line). This increased spectral control is attributable to the designable plasma frequency of CdO.

To unfold the underlying advantages offered by CdO, multiple Tamm plasmon polariton emitters composed of the same distributed Bragg reflector grown simultaneously on multiple CdO layers featuring different plasma frequencies were fabricated, that is, 2,700 cm⁻¹ (red dashed curve; FIG. 12) and 4,300 cm⁻¹ (red solid curve; FIG. 12). Although both samples feature the same distributed Bragg reflector structures, the different dielectric functions (carrier concentrations) of CdO result in distinct impedance models for the two systems (Section S19). This leads to noticeable differences in the emission spectra, for example, frequencies and amplitudes. Therefore, the adjustable carrier concentrations can tune the Tamm plasmon polariton and non-Tamm plasmon polariton modes and thus allow more-arbitrarily-shaped spectra to be matched than what can be achieved with a fixed carrier density. A series of comparisons were further performed among inversely designed Tamm plasmon polariton emitters with CdO featuring fixed carrier concentrations and/or mobility (Section S20), validating that the tunable dielectric function provides the spectral control necessary for full user design of the emission spectrum amplitudes, line-widths, and resonant frequencies. Although the loss of CdO (mobility) affects the Tamm plasmon polariton emitter (Brand S et al. Phys. Rev. B 2009, 79, 085416; Morozov K M et al. Sci. Rep. 2019, 9, 9604; Kaliteevski M A et al. Plasmonics 2015, 10, 281-284), the code and platform herein can mitigate the influence of this loss by modifying the corresponding carrier density (Section S20). As such, the wide tunability of CdO plasma frequency increases the design capability of Tamm plasmon polariton emitters to an unprecedented level compared with traditional noble-metal-based Tamm plasmon polariton emitters. In addition to the spectral control, replacing the noble metal with n-type In-doped CdO also makes the fabrication process CMOS compatible, potentially permitting integrated applications. Notably, this approach can also be applied to other doped materials, such as III-V semiconductors and other transparent conducting oxides (Bikbaev R G et al. J. Opt. Soc. Am. B 2019, 36, 2817-2823).

Conclusion. In conclusion, the combination of the broadly tunable plasma frequency of CdO and the efficient stochastic gradient descent-based inverse design enables the deterministic design of Tamm plasmon polariton emitters, which is numerically and experimentally validated. Using stochastic gradient descent, the structure of Tamm plasmon polariton emitters can be efficiently optimized (minutes on a consumer-grade desktop) for arbitrary target spectrum. Equipped with this method, single- and multi-band Tamm plasmon polariton emitters broadly suitable for different applications (including free-space communications, infrared beacons and single- and multi-gas filterless non-dispersive infrared sensing) were experimentally demonstrated, all showing great agreement between experiments and simulations. Importantly, the multi-peak demonstrations open up possibilities for the sensing of multiple gases and single gases with multiple vibrational bands that cannot be achieved with a single-filter, compact non-dispersive infrared black-body-based device. Further, the unprecedented ability of matching the target spectrum, that is, the frequencies, FWHMs, and even amplitudes (emissivity or spectral irradiance), was illustrated by exemplifying several designs ranging from the long-wave infrared to the telecommunications band (1.55 m), including isolated emission at a desired frequency with user-defined Q-factor (from 28 to 10,117), multi-peak emission for spectral bar-codes and non-dispersive infrared for matching complex gas absorption spectra. Such broad functionality is not inherent to Tamm plasmon polariton emitters; instead, it is enabled by the wide tunability of the CdO plasma frequency. Empowered by the stochastic gradient descent algorithm and this tunability, the demonstrated spectral control of Tamm plasmon polariton emitters promises cost-effective, wafer-scale, CMOS-compatible and lithography-free solutions for numerous applications throughout the infrared.

### Methods

Device fabrication. In-doped CdO (n-type) was deposited on two-inch r-plane (012) sapphire single-crystal substates at 400° C. by a reactive co-sputtering process employing high-power impulse magnetron sputtering and radio frequency sputtering from two-inch-diameter metal cadmium and indium targets, respectively. High-power impulse magnetron sputtering drive conditions were 800 Hz frequency and 80 ρs pulse time, yielding a 1,250 ρs period and 6.4% duty cycle. Film growth occurs in a mixed argon (20 sccm) and oxygen (14.4 sccm) environment at a total pressure of 10 mtorr. Post deposition, samples were annealed in a static oxygen atmosphere at 635° C. for 30 min.

Dielectric stacks (Ge and AlOₓ) were deposited at ambient temperature using electron beam evaporation from Ge (99.999%) and sapphire sources in vacuum. Thickness was monitored throughout the deposition using a quartz crystal microbalance. Post deposition, samples were cleaved and the layer thicknesses were measured using cross-sectional scanning electron microscopy.

Thermal emission measurements. All the thermal emissions were measured at normal incident angle. Thermal emission was measured using a Bruker VERTEX 70v Fourier transform infrared (FTIR) spectrometer by placing the device on a vertically oriented temperature controller located at the back port of the Fourier transform infrared spectrometer. The emission from the sample was then guided and collected through a KBr window and into the Fourier transform infrared spectrometer internal beam path. In this configuration, the emitted signal passes through the interferometer block, taking the place of the spectrometer's internal broadband source, which is turned off. An aperture was placed in the sample compartment to limit the detected solid angle from the device and reduce the detected emission from within the Fourier transform infrared spectrometer. The signal was measured using an IR Labs mercury-cadmium-telluride detector. In order to calculate the emissivity, thermal emission measurements were collected from our device at 150° C. These measurements were then compared to the thermal emission measured from an emissivity standard at the same temperature and angle of emission. For an emissivity standard (ε≈0.97), 500-μm-tall vertically aligned carbon nanotubes grown on a Si substrate from an Fe-nanoparticle catalyst, grown by Nanotechlabs, were used. These vertically aligned carbon nanotubes (VACNT) provide a high, consistent value for emissivity that is spectrally flat throughout the infrared and stable with temperature. The signal collected by the mercury-cadmium-telluride detector in these measurements contains the emission from both the sample as well as the internal optics of the Fourier transform infrared spectrometer.

$$M ( {T}_{sample} , {T}_{ambient} , λ , θ ) = R ( {T}_{ambient} , λ ) ( S ( {T}_{sαmple} , λ , θ ) + G ( {T}_{ambient} , λ ) ) \qquad ( 3 )$$

Here M is the total measured signal, R is a response function for the internal and external optics, Sis the signal originating from the sample and G is the ‘background’ emission from the internal optics, 0 is the measured emission angle, A is the corresponding wavelength, T_{ambient} is the ambient temperature, and Tₛₐₘₚₗₑ is the sample temperature. Thus, to isolate the signal from the sample, a background measurement was taken by replacing the sample with a gold mirror. The resultant spectrum is a product of the response function R with the background emission G. Once the sample, emissivity standard and background emission have been measured, equation (3) can be rearranged:

$$R ( {T}_{ambient} , λ ) {S}_{sample} ( {T}_{sample} , λ , θ ) = {M}_{sample} ( {T}_{sample} , {T}_{ambient} λ , θ ) - R ( {T}_{ambient} , λ ) G ( {T}_{ambient} , λ ) \qquad ( 4 )$$

$$R ( {T}_{ambient} , λ ) {S}_{standard} ( {T}_{sample} , λ , θ ) = {M}_{standαrd} ( {T}_{sample} , {T}_{ambient} , λ , θ ) - R ( {T}_{ambient} , λ ) G ( {T}_{ambient} , λ ) \qquad ( 5 )$$

where M_{standard} and S_{standard} are the total measured signal and the signal originating from the standard blackbody (VACNT), respectively. The response function can be normalized out by taking the ratio of equation (4) and Equation (5), and the emissivity relative to the standard can be determined.

$$\frac{R ( {T}_{ambient} , λ ) {S}_{sample} ( {T}_{ambient} , λ , θ )}{R ( {T}_{ambient} , λ ) {S}_{standard} ( {T}_{sample} , λ , θ )} = \frac{{S}_{sample} ( {T}_{sample} , λ , θ )}{{S}_{standard} ( {T}_{sample} , λ , θ )} = ε ( {T}_{sample} , λ , θ ) \qquad ( 6 )$$

Note that this technique is much quicker than the conventional approach to measuring emissivity using Fourier transform infrared spectroscopy and allows for multiple background measurements to be taken throughout the day. Therefore, fluctuations in the ambient temperature can be accounted for readily.

Numerical calculation of Tamm plasmon polariton emitters. The transfer matrix method calculation employed in the inverse design is from textbooks. As the materials are absorbing and dispersive, transfer matrix method calculations performed herein are from literature for cross-validation purposes (Passler N C et al. J. Opt. Soc. Am. B 2017, 34, 2128-2139; Passler N C et al. Phys. Rev. B 2020, 101, 165425). The dielectric functions of Ge and AlOₓ are fitted with ellipsometry measurements with WVase software from J. A. Woollam (Li H H. J. Phys. Chem. Ref. Data 1980, 9, 561-658), and temperature-dependent values are adjusted with reflectance data (Section S5). The dielectric function model of CdO with varying carrier concentration is from literature (Nolen J R et al. Phys. Rev. Mater. 2020, 4, 025202), and a corresponding MATLAB code to generate CdO dielectric functions in the mid- to long-wave infrared is provided on a website (https://my.vanderbilt.edu/caldwellgroup/). The Outlook section treats the dielectric function of Ge (Burnett J H et al. SPIE 2016, 9974, 99740X) and ZnSe (Gao W. SPIE 2009, 7283, 72832L) as constants in the entire frequency range: 16+0i and 5.0625+0i, respectively.

Computation resources used for the algorithm. All the optimizations are performed on a consumer-grade desktop equipped with an Intel I7-8700K CPU (˜$400 USD when first launched in 2017) and 16 GB memory, and no GPU units are used. The algorithm is written in Python 3.6 with TensorFlow 2.3.0. The specific stochastic gradient descent version used is adaptive momentum estimation (Adam), provided by TensorFlow, and the optimization step is 0.005. All optimizations performed in this paper took ˜1-10 minutes. The code is open-sourced online (https://my.vanderbilt.edu/caldwellgroup/) and can be freely used for non-profit purposes.

Absorption data of various chemicals. All chemical absorption spectra are taken from the National Institute of Standards and Technology website.

Section S1. Highly customized error for special designs. In the description above, it was mentioned that the error is written in a combination of mean-squared error (MSE, the first term) and mean absolute error (MAE, the second term) terms:

$$error = mean \{ ratio 1 \cdot {( \vec{D S} - \vec{T S} )}^{2} + r a tio 2 \cdot \vert ( \vec{D S} - \vec{T S} ) \vert \} \qquad ( S 1 )$$

While the mean-squared error regulates the algorithm to focus on spectral ranges where the difference between designed (DS) and target spectra (TS) is greatest, mean absolute error treats every frequency point as equally important. If the target spectrum is a spectrum that can be matched perfectly, e.g., a single peak design over a narrow frequency range, the hyperparameter choice does not matter. Yet, when the design cannot be accomplished as well, e.g., matching a complicated spectrum of a chemical, if one cares more about the overall matching (such as baseline) than the peak matching, the mean absolute error should have a larger component than the mean-squared error. Here, the design details in FIG. 9 are used as an example to show the technique of weighed sampling. Since the Tamm plasmon polariton emitter is being optimized based on the frequency points, some frequency range can be artificially made more/less important by sampling it more densely/sparsely, and certain frequency ranges can also be artificially ignored. For example, for free-space communications, the performance of wavelength-selective thermal emitter in the water absorption band can be ignored since the energy will be attenuated through space propagation. However, for non-dispersive infrared sensing, the emission in the water absorption band is required to be minimal so that the signal will not be influenced by humidity.

In the case presented in FIG. 9, only three discrete frequency ranges are optimized: long-wave infrared (1100-1300 cm⁻¹), mid-wave infrared (2600-2800 cm⁻¹), and telecommunications (1.5-1.6 μm) bands, so that a single Tamm plasmon polariton emitter working over such a dramatically broad frequency range can be realized. The spectrum of this device in full range is shown in FIG. 13. In a commercially designed scenario, such a technique can be used to specifically optimize the frequency ranges where band-pass filters are not available or are cost-prohibitive.

Still, in the case presented in FIG. 9, it was assumed that the performance in the telecommunications band is more important than in the long-wave infrared, so the former was sampled more densely: one frequency point every 0.5 cm⁻¹ in the telecommunications band, while only every 2 cm⁻¹ in the long-wave infrared and mid-wave infrared. This is of extreme importance, since trade-offs are unavoidable for a product design, and the algorithm quantifies this trade-off to “prioritize” certain ranges, as dictated by human intervention.

Section S2. The superiority of stochastic gradient descent in Tamm plasmon polariton emitter designs. In the optimization process, each frequency (wavelength) point is considered as an individual sample, and the absorption at that frequency is compared with the target value. Within the canonical gradient descent (GD) method, the difference across the entire data distribution is calculated and summed together to find the gradient, and all parameters are evaluated with the same computational complexity. With stochastic gradient descent (SGD), in each iteration, only a sub-sample of data points is used to find the gradient and update the vector representing the thickness and carrier concentration. The selected portion is randomly chosen from the entire collection of data points, so the algorithm is known as “stochastic” gradient descent, (SGD) (Robbins H et al. The Annals Of Mathematical Statistics, 1951, 400-407; Bordes A et al. Journal of Machine Learning Research, 2009, 10, 1737-1754; Sohl-Dickstein J et al. PMLR, 2014, 32(2), 604-612; Kingma D P et al. arXiv, 2014, arXiv:1412.6980). The specific version employed here is adaptive moment estimation (Adam) optimization (Kingma D P et al. arXiv, 2014, arXiv:1412.6980). Exemplary code is published online (Xiong Y et al. Applied Physics Letters 2009, 94, 203108). In deep learning, stochastic gradient descent is considered to outperform canonical gradient descent and avoid poor local minimums (Robbins H et al. The Annals Of Mathematical Statistics, 1951, 400-407: Bordes A et al. Journal of Machine Learning Research, 2009, 10, 1737-1754; Sohl-Dickstein J et al. PMLR, 2014, 32(2), 604-612; Kingma D P et al. arXiv, 2014, arXiv:1412.6980).

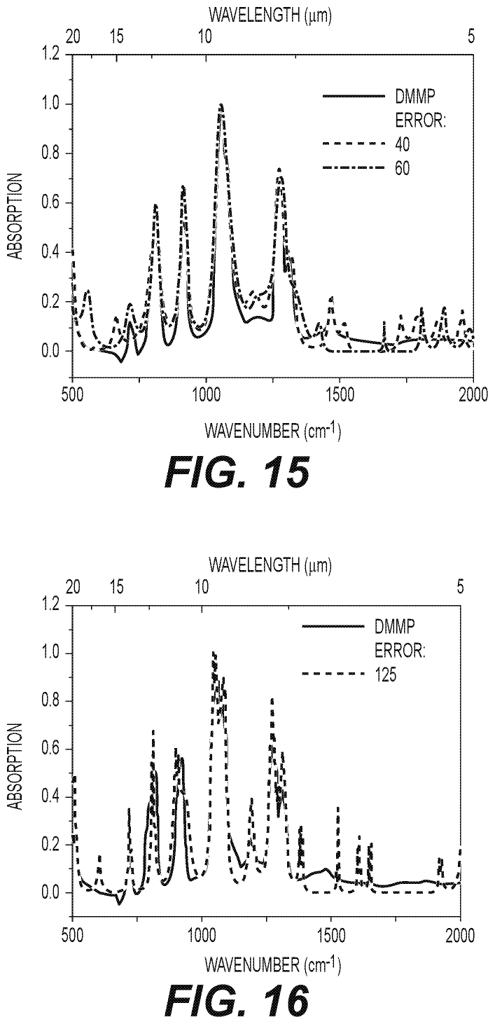

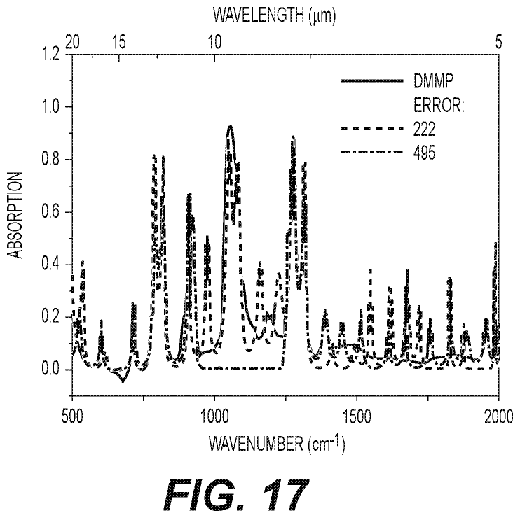

Here, to demonstrate that the stochastic gradient descent provides a better optimization than canonical gradient descent, a series of optimizations were performed on the same target: matching DMMP nerve agent and evaluating the performance based on mean-squared difference error (MSE). With stochastic gradient descent, the overall error is significantly lower than the optimization performed with canonical gradient descent. Within 20 optimization runs, the lowest error with stochastic gradient descent is ˜40, while this value is ˜70 for canonical gradient descent (FIG. 14). To visualize the arbitrary unit “error,” the designed spectra with different errors was plotted against the target spectra (FIG. 15-FIG. 17). While the main features are matched for errors below 100 (FIG. 15), designs with higher errors lose one or several of the main absorption peaks.

Section S3. Comparison among different design strategies. To design a Tamm plasmon polariton emitter, there are several strategies proposed and applied in the literature. Here, their advantages and limitations are summarized in Table 1. The algorithm disclosed herein provides a well-balanced optimization performance: high efficiency and high accuracy. The code is open-sourced and can be downloaded online (https://my.vanderbilt.edu/caldwellgroup/).

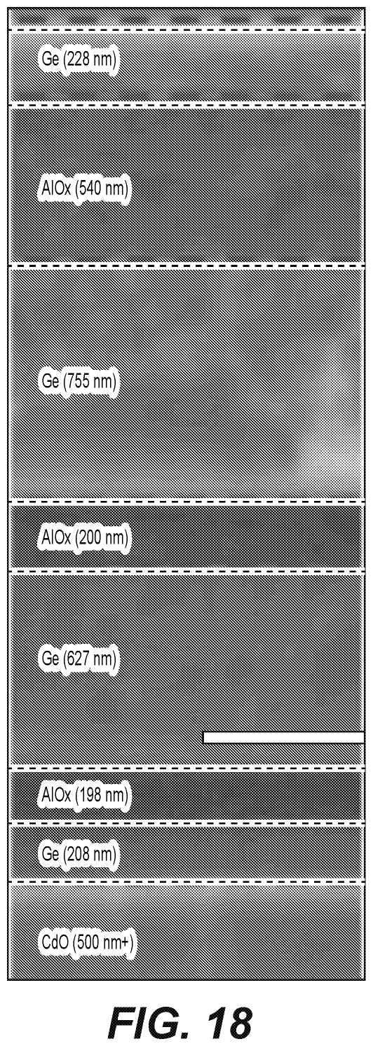

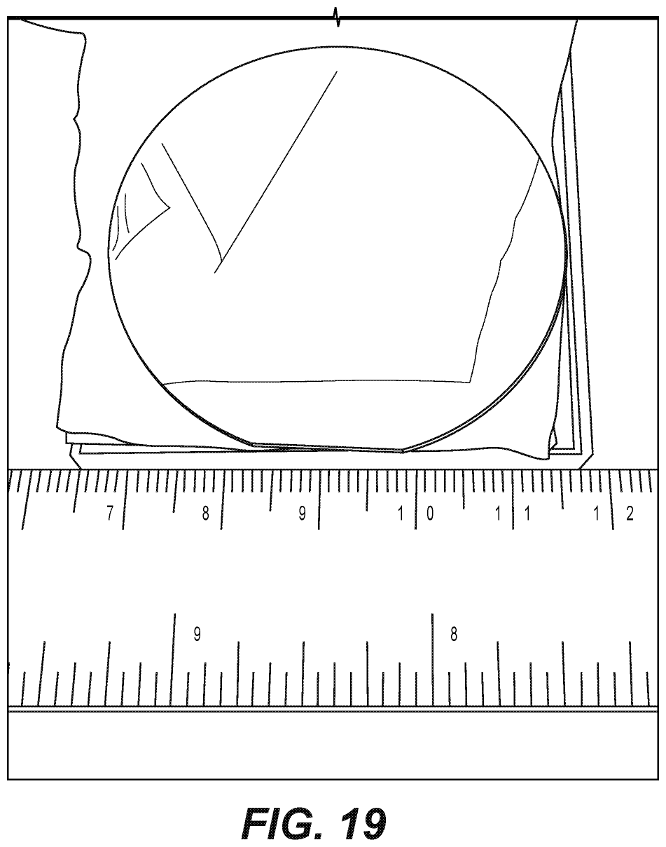

Section S4. Sample thickness and photo. The layer thicknesses of as-grown samples were characterized by cross-sectional SEM (XSEM). The designed and as-grown layer thickness are tabulated in Table 2, and the carrier densities (N_{d}) of CdO are also listed. One exemplary XSEM of the 7-layer sample designed to emit at three specific, disparate resonant frequencies (FIG. 6) is provided in FIG. 18. One wafer-scale Tamm plasmon polariton emitter device is shown in FIG. 19.

TABLE 1
Comparison among different design strategies.

| | Global or local | | | Demonstrated |
|---|---|---|---|---|
| Strategy | optimization? | Advantages | Disadvantages | designs |
| Particle Swarm^{a} | Global | Good global | Extremely slow | Single-peak |
| Bayesian | | optimization | (hours to months) | Single-peak |
| optimization^{b} | | | | |
| Genetic | | | | Single-peak |
| Algorithm^{c} | | | | |
| Forward design^{d} | Not applicable | Clear physics | Does not work for | Single-peak |
| (intuition and | | understanding | high-dimensional | |
| parameter sweep) | | | optimizations | |
| Deep learning | Depends on the | Extremely quick | Poor precision | Single-peak |
| (neuron | specific network | optimization | compared with | |
| network)^{e} | structure | (seconds or sub- | other strategies | |
| | | seconds) | | |
| Herein | Local | Efficient | Chances to be | Arbitrarily |
| | optimization | optimizations | stuck at local | required |
| | | (minutes) | minimums (see | spectrum |
| | | High precision | section S4) | |
| | | compared with | | |
| | | deep learning | | |
| | | approach | | |

^{a}Liang W et al. Optics Express 2020, 28, 31330-31344
^{b}Sakurai A et al. ACS Central Science 2019, 5, 319-326
^{c}Botros J et al. Journal of Applied Physics 2020, 127, 114502
^{d}Wang Z et al. ACS Photonics 2020, 7(6), 1569-1576; Wang Z et al. Advanced Functional Materials, 2021, 2102183
^{e}So S et al. Optical Materials Express, 2021, 11, 1863-1873

TABLE 2
Layer thickness of samples. Units of thickness are in nanometers.

| | 3 layer (FIG. 3) | | 3 layer (FIG. 4) | | 5 layer (FIG. 5) | | 7 layer (FIG. 6) | |
|---|---|---|---|---|---|---|---|---|
| | long-wave infrared | | CO₂ non-dispersive | | CO₂ + SO₂ non-dispersive | | Triple-peak | |
| | emitter | | infrared emitter | | infrared emitter | | design | |
| | Designed | As-grown | Designed | As-grown | Designed | As-grown | Designed | As-grown |
| Ge | Air | | Air | | Air | | 298 | 228 |
| AlOₓ | | | | | | | 520 | 540 |
| Ge | | | | | 389 | 468 | 766 | 755 |
| AlOₓ | | | | | 797 | 290 | 205 | 200 |
| Ge | 499 | 540 | 270 | 250 | 494 | 450 | 592 | 627 |
| AlOₓ | 829 | 440 | 430 | 590 | 310 | 268 | 152 | 198 |
| Ge | 315 | 400 | 656 | 641 | 494 | 644 | 215 | 208 |
| CdO N_{d} | 0.7e+20 | | 3.6e+20 | | 3.6e+20 | | 3.2e+20 | |
| (cm⁻³) | | | | | | | | |

Section S5. Dielectric function fitting of materials used: CdO, Ge, and AlOₓ. The fitting of the dielectric function of CdO has been studied in previously (Nolen J R et al. Physical Review Materials 2020, 4, 025202). The same process was followed to determine the dielectric function and carrier concentrations of CdO in this study. Both exemplary tabulated dielectric function and a MATLAB script to generate the dielectric function of CdO with user-defined carrier concentration from 1000 to 5000 cm⁻¹ are downloadable online (https://my.vanderbilt.edu/caldwellgroup/). This MATLAB script is also integrated into the inverse-design code (open-sourced and downloadable from https://my.vanderbilt.edu/caldwellgroup/).

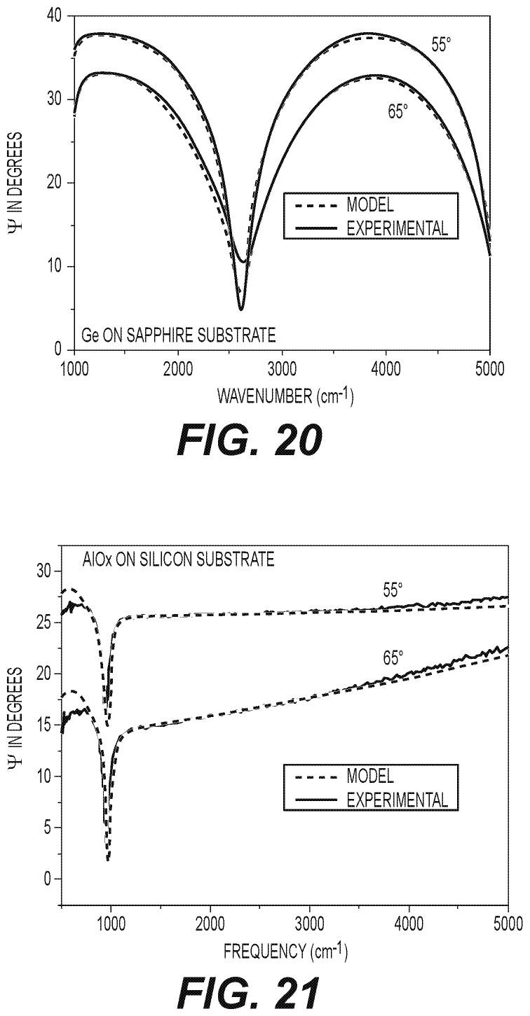

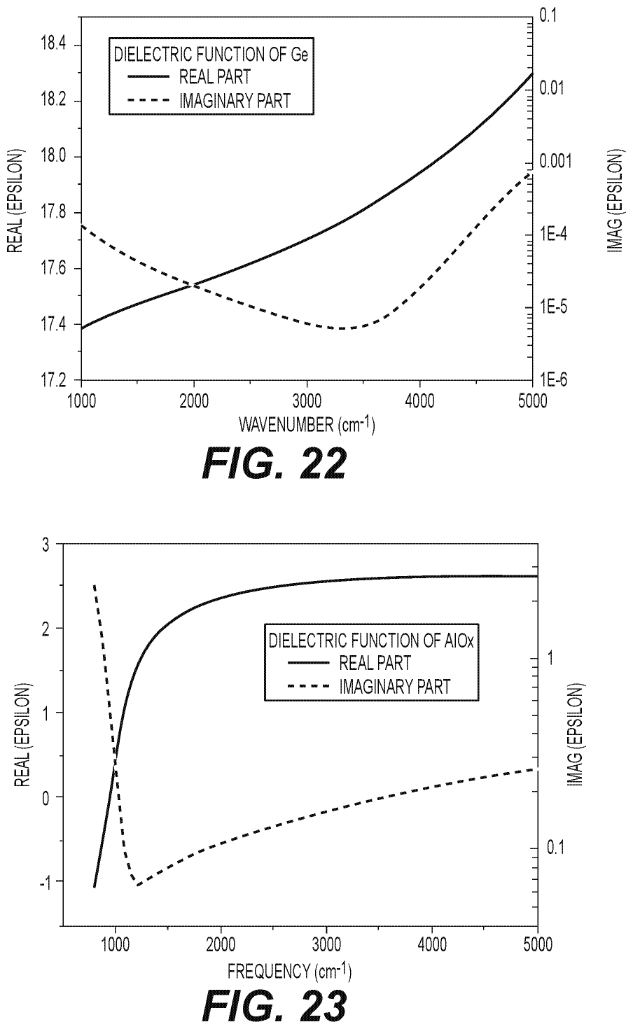

The dielectric functions of as-grown Ge and AlOₓ were extracted using IR-VASE ellipsometry measurements, as shown in FIG. 20-FIG. 23. The fitting was performed with WVase software from J. A. Woolam. Inc (Li H H. Journal of Physical and Chemical Reference Data, 1980, 9, 561-658).

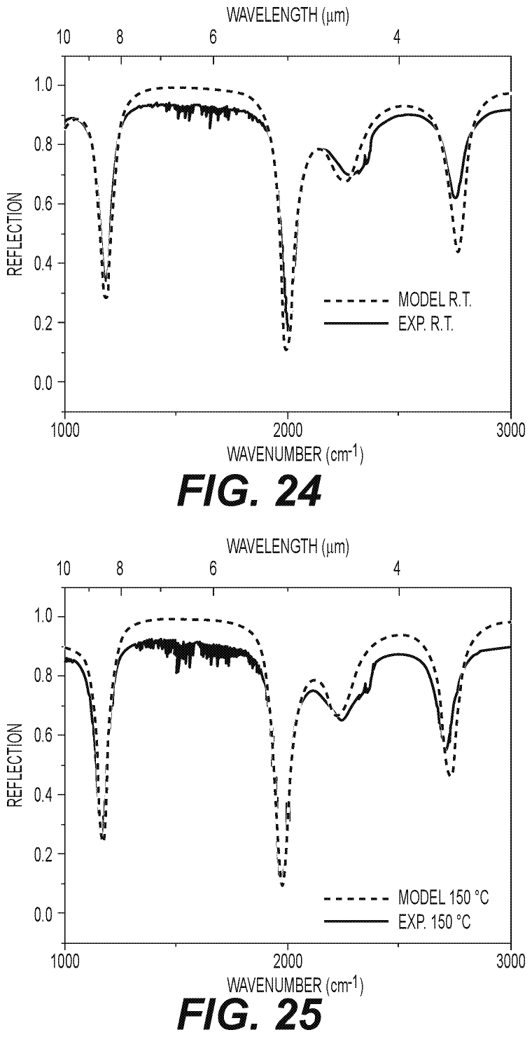

Based on the literature, it was assumed that the thermal expansion of each of the constituents can be ignored (below 0.1%) for operating temperatures below 300° C. (Kagaya H M et al. Physica Status Solidi (B), 1985, 129. K5-K8). Based on literature results (De Silans T P et al. Journal of Physics: Condensed Matter 2009, 21, 255902), it was assumed that the dielectric function of AlOₓ maintains a constant over temperature. The permittivity of Ge at 150° C. is modeled based on measurements at high temperature by varying the high-frequency permittivity. It was determined that at 150° C. the high-frequency permittivity is 0.5 higher than at room-temperature (FIG. 24-FIG. 25), in agreement with literature results (Li H H. Journal of Physical and Chemical Reference Data, 1980, 9, 561-658).

Section S6. Achievable complexity of the spectrum with different layer numbers. Herein, the achievable complexity for a Tamm plasmon polariton emitter with a defined number of dielectric layers is discussed. As the complexity of the spectrum is not something that can be fully quantified and is application-specific, three cases are employed: (1) determine the achievable Q-factor at a given frequency (2350 cm⁻¹ here) with 3, 5, 7, 9 and 11 layer dielectric stacks; (2) for the task presented in FIG. 6 (triple peak design), the best-matched spectrum achievable limiting to 3, 5, 7, 9 and 11 layer dielectric stacks is calculated; (3) to match a complicated spectrum, i.e. DMMP, this process is repeated, but using 7, 11, 19, and 29 dielectric layers. In this section, the dielectric materials used are Ge and ZnSe, with permittivity values of 16+0i and 5.25+0i.

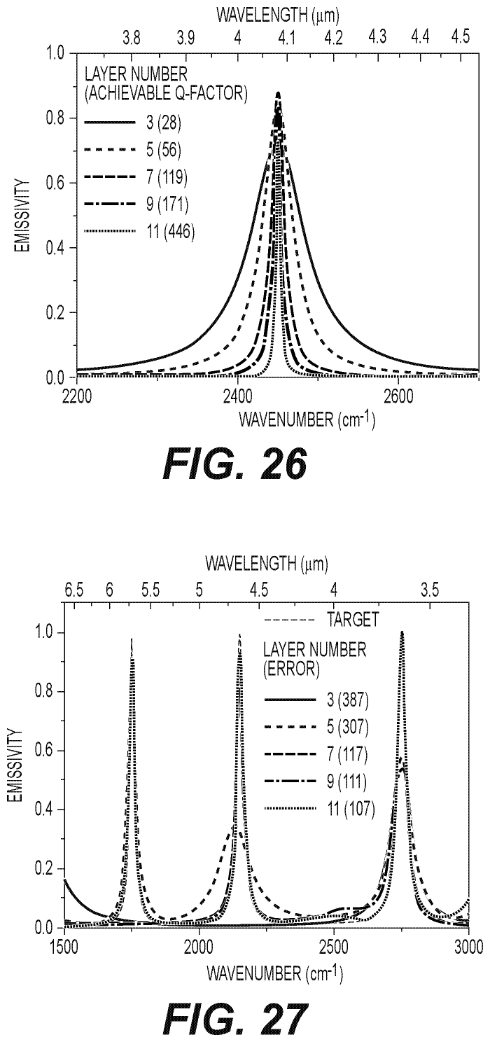

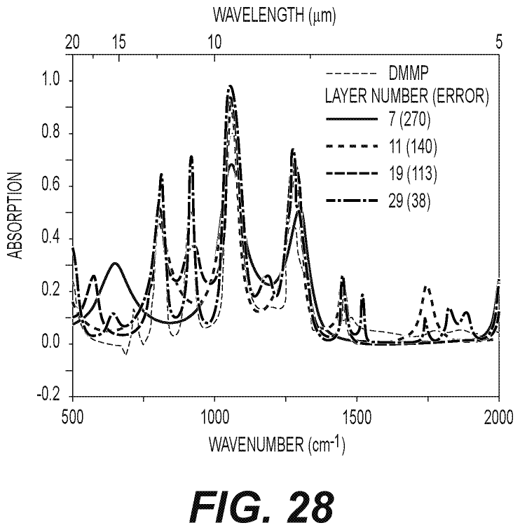

From this set of comparisons, it was concluded that more complicated spectra, i.e., referring to Q-factors and number of peaks, can be achieved with increasing numbers of dielectric layers in the stack (FIG. 26, FIG. 28). Note that for a given application, i.e., multi-peak design with requested Q-factors, more dielectric stacks do not guarantee better results. For the task in FIG. 27, using more than 9 dielectric layers does not provide significantly better results, even if the “error” is found to reduce, the difference in spectral match is negligible.

In summary, with more layers, more complicated spectra can be matched, and if a target spectrum can be achieved with a given number of dielectric stack layers, increasing this further does not provide significant additional advantages. For the experimentally demonstrated structures, the design was initiated by determining if the optimization is achievable with 3 dielectric layers, if yes, it was used to minimize the potential error on the layer thickness, which are the cases for FIG. 3 and FIG. 4. If the function is not achievable via three-dielectric-stacks, it was attempted with an increasing number of layers until a suitable match is found.

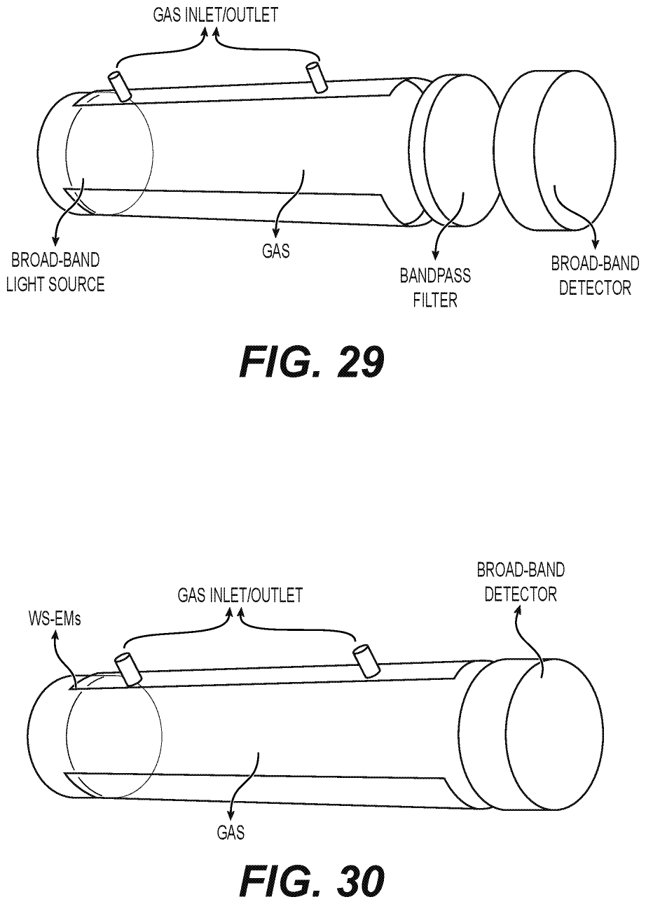

Section S7. Non-dispersive infrared working principles. Conventional non-dispersive infrared sensors comprise a gas cell containing a broadband emitter and broadband detector integrated with a narrow bandpass filter that is transmissive at the vibrational frequency of the analyte of interest (FIG. 29). The presence of the gas of interest within the cell results in a drop in the detected transmission, with the difference in amplitude being related to the molecular concentration in accordance with Beer's Law. Due to the simple design and small footprint, these sensors are commonly implemented in industrial settings, however, they suffer from inherent inefficiencies since off-resonant emission from the broadband emitter is not used and must be filtered. Therefore, there has been significant interest in improving the design and expanding the functionality of non-dispersive infrared sensors by combining the functionality of the emitter and bandpass filter into a single device. Approaches towards filterless non-dispersive infrared devices are in some iterations comprised of (1) wavelength-selective thermal emitter, (2) the gas cell, and (3) a broadband detector, such as a thermopile, as shown in FIG. 30. The emission frequency of the wavelength-selective thermal emitter is normally centered at the absorption frequency of the gas of interest with a sufficiently high Q-factor so as to eliminate false-negatives that would result from non-negligible absorption from other gases that may be present. There are normally two detectors, one is shown in FIG. 29-FIG. 30, and the other is to measure the power with reference gas, e.g., nitrogen, so that the power difference can be acquired.

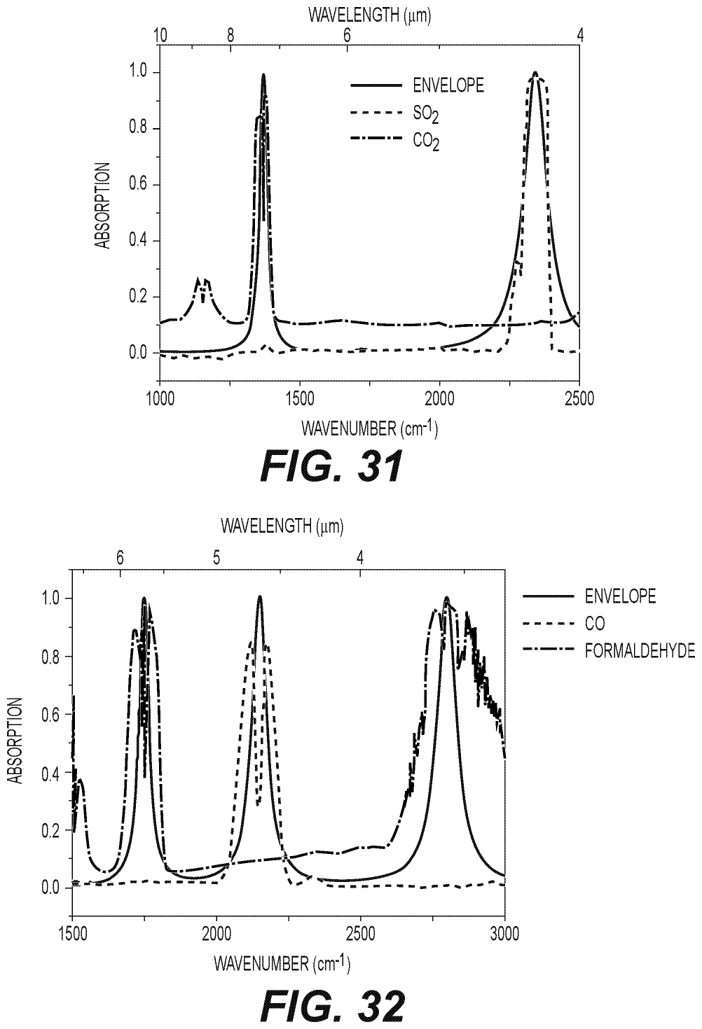

Section S8. Rationales of target spectrum in FIG. 5 and FIG. 6. In FIG. 5, a Tamm plasmon polariton emitter for dual-gas sensing was also demonstrated. The target is to match absorption features of SO₂ and CO₂ absorption simultaneously. In order to determine a target spectrum to design this device, the absorption spectra of SO₂ and CO₂ was taken from National Institute of Standards and Technology (NIST), then an envelope spectrum was used to cover the two main absorption peaks of SO₂ and CO₂ (FIG. 31). Because numerous gases possess absorption bands in the 1000-1500 cm⁻¹ spectral range, for instance CH₄, and the thermal emission leads to more energy in the lower frequency range, the target spectrum at 1380 cm⁻¹ is set to be sharper (20 cm⁻¹ FWHM) to reduce the energy emitted to compensate. The FWHM at 2360 cm⁻¹, which is the absorption peak of CO₂, is set to be larger (50 cm⁻¹) to compensate for the low emitted power dictated by Plancks' Law. The frequency range is set between 1000 cm⁻¹ and 2500 cm⁻¹. As the loss of AlOₓ is hard to predict, especially at elevated temperatures, the spectrum below 1000 cm⁻¹ was not tried to match; however, it is important to note that emission at lower energies can be very efficiently removed via a long-pass filter. The high frequency is set to be 2500 cm⁻¹ because the emitted power drops significantly above this value for the proposed operation temperatures, as dictated by Planck's Law, and thus emission at higher frequencies can be considered negligible.

The same rationale was also used to create the target spectrum for CO and formaldehyde dual gas sensing (FIG. 32). The target spectrum has increasing FWHM with increasing frequencies: 20, 30 and 40 cm⁻¹ for peaks at 1750, 2150 and 2800 cm⁻¹.

Section S9. Differentiating CO₂ and SO₂ with a single Tamm plasmon polariton emitter by linear regression. As the emitted power is influenced by the working temperature, such a difference can be used to find the concentration of CO₂ and SO₂ by linear regression. The absorbed power of one gas, can be described as follows:

$$\vec{Emitted power of EM} = \vec{Emitted power of black body} ⊗ \vec{Emissivity of EM} \qquad ( S 2 )$$

$$\vec{Absorbed power} = \vec{Emitted power of EM} ⊗ \vec{absorption spectrum of gas} \cdot absorption strength \qquad ( S 3 )$$

where ⊗ stands for element-wise multiplication. The actual gas concentration in ppm can be derived from scalar absorption strength with the Beer-Lambert law. Assuming all the spectra are discretized from 1000 cm⁻¹ to 2500 cm⁻¹ into N frequency points, then each spectrum can be written as a [N×1] vector. Assuming there are m different temperatures, then the emitted power of the Tamm plasmon polariton emitter at m temperatures can be written in a matrix of [N×m], i.e., [Emitted power], of which the rank of the matrix is m, because the \vec{Emitted power of black body} is linearly independent at different temperatures.

When there are multiple gas types (CO₂ and SO₂ here for example), the absorption spectra will be expanded into matrices, with different rows representing different gas types. As such, there are two unknown variables [1×2], i.e., \vec{absorption strength}, representing the concentrations of CO₂ and SO₂ respectively. Then the power change read by the detector is:

$$( S 4 )$$

$$( [ \vec{absorption strength} ] \times [ absorption spectra of {CO}_{2} and {SO}_{2} ] ) \times [ Emitted power of EM ] = \vec{power change at m temperatures concentration}$$

where └absorption spectra of CO₂ and SO₂┘ is a matrix of └2×N┘ representing the absorption of CO₂ and SO₂ respectively, and x stands for matrix multiplication. In Equation (S4), └absorption spectra of CO₂ and SO₂┘ is pre-calibrated. └Emitted power of EM┘ is the measured power of the wavelength-selective thermal emitter before it is assembled in the non-dispersive infrared, and \vec{power change at m temperatures concentration} is the reading from the detector. Thus, a simple non-negative linear regression solution can be used to find the vector of \vec{absorption strength} and thus extract the gas concentrations in ppm. Non-negative linear regression can be performed by many scientific programming interfaces, such as SciPy (https://www.scipy.org/).

Example of differentiating CO₂ and SO₂ with the Tamm plasmon polariton emitter in FIG. 5. In the case of differentiating CO₂ and SO₂ with the emitter in FIG. 5, the system can be simplified by only considering two isolated frequency points: 1380 and 2360 cm⁻¹, as they are the only two emission peaks of the Tamm plasmon polariton emitter. As such, the emissivity vector is: [0.6 1.0]. At 100, 150, 200, 250° C., the emitted powers (W/m²/sr/cm⁻¹) of black body are:

$$[ \begin{matrix}0.175 & 0.327 & 0.538 & 0.808 \\ 0.02 & 0.059 & 0.136 & 0.269\end{matrix} ]$$

As such, the emitted power (W/m²/sr/cm⁻¹) of the Tamm plasmon polariton emitter is:

$$[ \begin{matrix}0.105 & 0.198 & 0.323 & 0.485 \\ 0.02 & 0.059 & 0.136 & 0.269\end{matrix} ]$$

Assuming the concentration of SO₂ and CO₂ are leading to absorption values of a and b respectively, then the power change (W/m²/sr/cm⁻¹) matrix is:

$$[ \begin{matrix}0.105 a + 0.02 b + noise 1 & 0.196 a + 0.059 b + noise 2 & 0.323 a + 0.136 b + noise 3 & 0.485 + 0.269 b + noise 4\end{matrix} ]$$

which are the readings of the detector at four discrete Tamm plasmon polariton emitter operating temperatures. From there, both the absorption caused by SO₂ and CO₂ can be calculated and therefore the corresponding concentrations extracted dynamically.

Why Wavelength-selective thermal emitter instead of blackbody emitters? Within the previous discussions, it appears that one could do the aforementioned calculations with any emitter type, even a blackbody, which is true when there is no noise and only CO₂ and SO₂ are present. However, other gases, such as water vapor, will be present in the environment, and thus, with a blackbody emitter, changes in the humidity and/or other atmospheric gases will lead to corresponding power changes, resulting in false-positives. Yet, since the Tamm plasmon polariton emitter does not emit power in the water absorption band, the selectivity will be significantly improved.

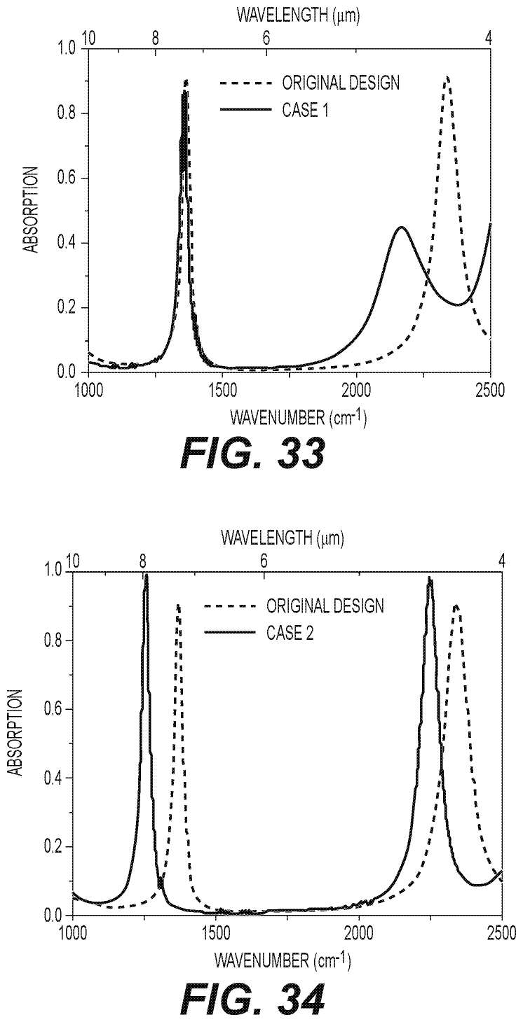

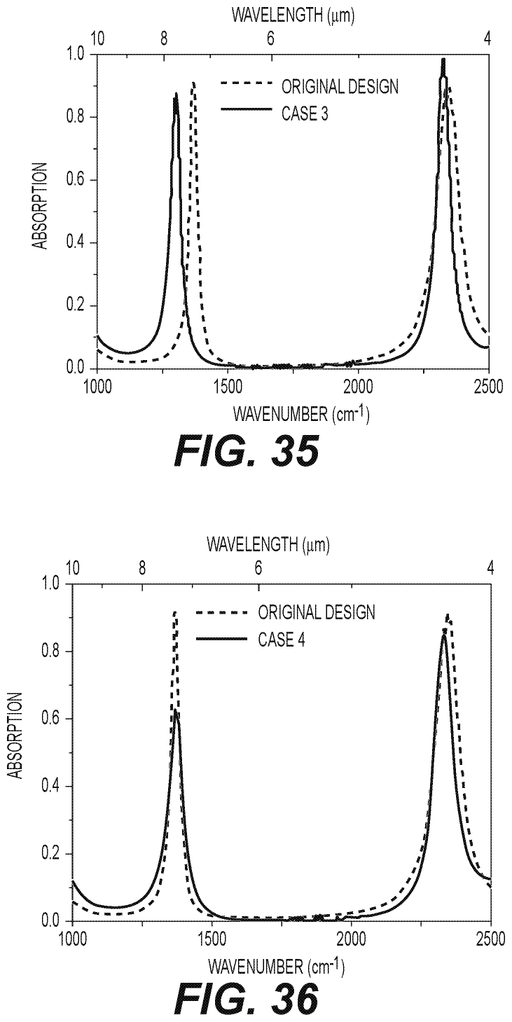

Section S10. Dielectric materials thickness error analysis. Herein, the influence of thickness error is discuss, i.e., how the results will be influenced when the thickness cannot be precisely controlled in experiments. In general, different combinations of layer thickness discrepancies can lead to different outcomes: (1) shifting the resonance frequency (case 2, 3); (2) broadening/sharpening the resonance linewidth (case 1, 4); (3) influencing the resonance amplitude(s) (case 1, 2, 3, 4); and (4) eliminating the resonance (case 1), as shown in FIG. 33-FIG. 36. Here, the designed layer thickness for the device presented in FIG. 5 was varied with several results provided.

The original design is [389 797 494 310 494](top to bottom layer thickness, starting with Ge ending with Ge), and CdO carrier concentration is 3.6e+20 cm⁻³. Below, bold and italic style numbers indicate that the corresponding layer thicknesses are different from the original design.

In case 1, the calculation is performed with: [509 797 494 310 494]

In case 2, the calculation is performed with: [389 797 494 310 604]

In case 3, the calculation is performed with: [389 507 494 310 604]

In case 4, the calculation is performed with: [468 290 450 268 644], which is our as-grown structure.

Section S11. Peak analysis of the device in FIG. 6. Table 3 provides the peak analysis of the target spectrum, designed spectrum, and experimental structures for the designed Tamm plasmon polariton emitter from FIG. 6.

TABLE 3
Peak analysis of FIG. 6

| | Center | FWHM | | Center | FWHM | | Center | FWHM | |
|---|---|---|---|---|---|---|---|---|---|
| | (cm⁻¹) | (cm⁻¹) | Q | (cm⁻¹) | (cm⁻¹) | Q | (cm⁻¹) | (cm⁻¹) | Q |
| target | 1750 | 20 | 87.5 | 2150 | 30 | 71.7 | 2800 | 40 | 70 |
| spectrum | | | | | | | | | |
| designed | 1750.3 | 37.5 | 46.7 | 2152.6 | 32.5 | 66.2 | 2802.0 | 35.8 | 78.3 |
| spectrum | | | | | | | | | |
| Exp. | 1761.9 | 41 | 42.7 | 2146.7 | 38 | 56.5 | 2721.6 | 21 | 129.6 |
| As-grown | 1745.6 | 41 | 42.8 | 2134.1 | 30 | 70.4 | 2703.4 | 23 | 119.6 |

Note that the Q-factors of those peaks are ˜100, which is on par with the best-reported values for isolated nanophotonic resonators using lower loss surface phonon polariton resonators (˜100-400) (Wang T et al. ACS Photonics, 2017, 4, 1753-1760; Caldwell J D et al. Nature Communications 2014, 3, 5221; Caldwell J D et al. Nano Letters, 2013, 13, 3690-3697; Tamagnone M et al. arXiv. 2019, arXiv:1905.02177; Autore M et al. Light: Science & Applications, 2018, 7, 17172) and plasmonic Fano structures (˜100-400) (Wang B et al. Advanced Optical Materials, 2021, 2001520). The allowed Q-factors of Tamm plasmon polariton emitters are related to the number of dielectric layers employed (section S6).

Section 512. Evaluating the theoretical detection limitation in non-dispersive infrared scheme. In a non-dispersive infrared device, the power emitted from the emitter (EM) will propagate through the gas cell and arrive at the detector. When the gas cell is filled with reference gas, e.g., nitrogen, the power reading on the detector is:

$$reference signal = emissivity of EM \times blackbody emission \times area of EM \times solid angle \qquad ( S5 )$$

Whilst in general the performance and power of the sensor is highly dependent on collection optics, some approximations can be made based on the geometry of a commercial sensor. Here, it was assumed that the emitter is a circle of 2-cm diameter, and the detector is also 2-cm diameter. The optical path length of gas cell is 10 cm, which is a typical design (https://www.edmundoptics.com/f/infrared-ir-bandpass-filters/14290/), leading to a solid angle of 2.2×10⁻⁴ sr. The gas absorption is determined by Beer-Lambert Law:

$$Transmission with {CO}_{2} = exp ( - kcL ) \qquad ( S6 )$$

where k is the absorption coefficient, c is gas concentration and L is the sample optical path length. The absorption spectra of CO₂, CO, SO₂ and formaldehyde at a given concentration and in a certain length of the gas cell were acquired or estimated from literature and NIST (Naganathappa M et al. Astrophysics and Space Science, 2011, 332, 249-256; Dong M et al. Infrared Physics & Technology 2017, 85, 450-456; Livingood A et al. ACS Photonics. 2021, 8(2), 472-480). Thus, the transmission (and equivalently, the absorption) for any concentration of CO₂ was able to be calculated. The reference power, e.g., power received by the detector when the gas cell is filled with nitrogen, can be calculated by Equation (S6). Knowing the reference power and the CO₂ transmission for a given concentration, the power collected at the detector when CO₂ is present is:

$$Detected power with chemical = reference signal \times Transmission with {CO}_{2} \qquad ( S7 )$$

In order to determine the detection limit of a hypothetical, filterless non-dispersive infrared device equipped with one of the Tamm plasmon polariton emitters, a commercial coin-sized pyroelectric detector was assumed (Asano T et al. Science Advances 2016, 2, e1600499) with a responsivity of 150,000 V/W, and estimated noise of 180 μV at 10 hz. For the device in FIG. 4, the working temperature was first set as 600° C., which is a typical design set up. At such a working temperature, when the difference between reference signal and Detected power with chemical is 3 σ (a signal to noise ratio of 3:1). i.e., the voltage difference is 540 μV, the CO₂ concentration is 0.5 ppm. Thus, the detection limit is determined to be 0.5 ppm. This calculation was then repeated for the device in FIG. 5, resulting in a CO₂ (SO₂) concentration detection limit of 0.5 (3.3) ppm. For comparison, this calculation was also performed for a conventional non-dispersive infrared design, i.e. assuming the same detector and gas cell, however, using a blackbody emitter at the same size coupled with a bandpass filter designed for CO₂ gas sensing (Granier C H et al. JOSA B 2014, 31, 1316-1321). Here, the resultant CO₂ concentration detection limit is also 0.5 ppm. For comparison, a commercial CO₂ non-dispersive infrared detector has a detection limit of 8 ppm (Howes A et al. Advanced Optical Materials 2020, 8, 1901470). Despite the imperfect distributed Bragg reflector growth technique, the Tamm plasmon polariton emitters enabled a filterless non-dispersive infrared sensor that still has identical performance for single gas sensing to a conventional blackbody/filter design, while permitting multi-gas sensing.

Building on the same assumptions, the performance of the triple-peak design was evaluated and the benefits of such a multi-peak emitter are discussed. One obvious point that has been discussed is the ability to sense multiple gases simultaneously. The other advantage is the improved sensitivity, i.e., reduced the detection limit. The detection limit of formaldehyde is 1.4 ppm with device in FIG. 6. However, for a black body emitter with a with a bandpass filter centered at 2750 cm⁻¹ with a Q-factor of 90, the detection limit is 3.1 ppm.

The power consumption of those light sources based on the emitted power was also estimated. The power consumption of non-dispersive infrared light source originates from heat conduction, heat convection and emitted power (emissivity multiplied by black body emission). While conduction and convection can be reduced by using thermally isolating materials and vacuumizing the emitter environment, the emitted power is fundamentally dictated by the emissivity and temperature. Thus, the lowest possible power consumption was estimated based on the emitted power, and the value of a blackbody at 600° C. is 1.03 W, however, the power consumption of the wavelength selective Tamm plasmon polariton emitter is only ˜0.1 W. The comparison is summarized in Table 4.

TABLE 4
Theoretical performance of non-dispersive IR
with different light sources and/or filters

| | Detection | Emitted | |
|---|---|---|---|
| | Limit | energy | |
| | (ppm) | (W) | Gas types |
| Exp. Device FIG. 4 | 0.5 | 0.18 | CO₂ |
| Exp. Device FIG. 5 | 0.5 | 0.22 | CO₂ |
| (Dual gas sensing) | 3.3 | | SO₂ |
| Commercial bandpass filter (Q = | 0.5 | 1.30 | CO₂ |
| 40) with blackbody emitter | | | |
| Commercial bandpass filter (Q = | 3.1 | 1.30 | formaldehyde |
| 90) with blackbody emitter | | | |
| Exp. Device FIG. 6 | 3.2 | 0.16 | CO |
| | 1.4 | | formaldehyde |
| Exp. Device FIG. 6 | 3.2 | 0.13 | CO |
| removing 1750 cm⁻¹ peak | 3.3 | | formaldehyde |

In summary, the multi-peak design provides several advantages over conventional non-dispersive infrared with single-band filters: (1) Permitted multi-gas sensing: (2) Improved sensitivity when multiple absorption bands of one chemical are matched; and (3) Reduced power consumption. While single-peak Tamm plasmon polariton emitter provides nearly identical sensitivity as conventional non-dispersive infrared, the power consumption and potentially design complexity would be reduced significantly. Notably, with the current commercial filters, dual- and multi-peak designs cannot be achieved with a single filter (Table 5).

TABLE 5
Comparison between our Tamm plasmon polariton
emitters and commercial bandpass filters. CO₂
bandpass filters are listed separately.

| | | | | Multi/ |
|---|---|---|---|---|
| | Center | Q- | Transmission or | single |
| Source | frequencies (cm⁻¹) | factors | Emissivity (%) | band |
| A^{a} | 1600-5000 | ~20-50 | 70-80 | Single |
| | 2340 (CO₂) | 40.6 | 75 | Single |
| B^{a} | 2000-3700 | ~25 | 65-80 | Single |
| | 2340 (CO₂) | 35.5 | 70 | Single |
| C^{b} | 1000-7000 | ~20-90 | 70-80 | Single |
| | 2340 (CO₂) | 47 | 85 | Single |
| D^{c} | 2000-4000 | ~20-40 | 70-80 | Single |
| | 2340 (CO₂) | 35.5 | 75 | Single |
| Experi- | 2340 (CO₂) | 20 | 100 | Single |
| mental | 2340 (CO₂) | 26 | 100 | Dual- |
| demon- | 1363 (SO₂) | 50 | 100 | band |
| strations | 1750 (formaldehyde) | 40 | 90 | Triple- |
| herein | 2150 (CO) | 60 | 90 | band |
| | 2750 (formaldehyde) | 90 | 65 | |

^{a}Granier C H et al. JOSA B 2014, 31, 1316-1321
^{b}Howes A et al. Advanced Optical Materials 2020, 8, 1901470
^{c}Asano T et al. Science Advances 2016, 2, e1600499

While the gas sensing measurements could not be experimentally perform using the multiband emitter because CO, SO₂ and formaldehyde are all highly toxic gases, it was validated that the single-peak Tamm plasmon polariton emitter provides nearly identical sensitivity as a conventional non-dispersive infrared approach using a traditional blackbody emitter. For this benchmark experiment, first the non-dispersive infrared response as a function of CO₂ concentration was experimentally measured using a blackbody emitter (here vertically aligned carbon nanotubes, e˜0.97) and a commercial CO₂ filter (4.26 um center wavelength, 105 nm bandpass), as shown in FIG. 37. A broadband pyroelectric detector with a chopper wheel at 10 Hz (RM9 with Chopper) was employed. The gas cell was first purged with dry nitrogen gas, and then it was purged with 5% and 1% CO₂, respectively. Before and after the gas cell is filled with a certain concentration of CO₂ it is purged with dry nitrogen. This measurement was repeated using the Tamm plasmon polariton emitter device presented in FIG. 4 and then again using the device in FIG. 5. The results are tabulated in Table 6. It was found that the Tamm plasmon polariton emitters lead to larger power variations than the combination of the CO₂ filter (Q=42) and blackbody emitter, which comes from the wider linewidth of the Tamm plasmon polariton emitter peaks (Q=20 and 36) and the near-unity emissivity at the resonance frequency. Thus, the proposed Tamm plasmon polariton emitter performs similarly to a blackbody emitter combined with narrow-bandpass filter when only one absorption peak of a type gas is matched. When more bands are integrated, the additional emitting frequencies can be used to either permit multi-gas sensing (device in FIG. 5) or enhanced sensitivity (device in FIG. 6) by matching the absorption of multiple vibrational or rotational modes of the molecule of interest. Unfortunately, this concept was not able to be demonstrate experimentally as the gases the multiple Tamm plasmon polariton emitter emission is designed for are extremely toxic.

TABLE 6
Tabulated power under different conditions, with background
power removed. Standard deviations (propagated uncertainties)
are included in the parentheses. The standard deviations
are calculated by analyzing the detector reading over 10
seconds. Sample temperatures are 250° C. for all cases.

| | | CO₂ | Power | CO₂ | Power |
|---|---|---|---|---|---|
| Power | N₂ | (5%) | change | (1%) | change |
| (background removed) | (μW) | (μW) | (μW) | (μW) | (μW) |
| Blackbody emitter + | 0.5 | 0.12 | 0.38 | 0.24 | 0.26 |
| filter | (0.12) | (0.11) | (0.16) | (0.11) | (0.16) |
| Tamm plasmon polariton | 5.3 | 4.2 | 1.1 | 4.9 | 0.4 |
| emitter (FIG. 4) | (0.13) | (0.13) | (0.18) | (0.15) | (0.20) |
| Tamm plasmon polariton | 5.4 | 4.18 | 1.22 | 4.76 | 0.64 |
| emitter (FIG. 5) | (0.12) | (0.18) | (0.21) | (0.12) | (0.17) |

Section S13. Thermal emission measurements at different angles. The angular spread of Tamm plasmon polariton emitter is limited to a small range, and TM (Transverse Magnetic) polarized light is typically slightly more dispersive than TE (Transverse Electric) polarized (Liu X et al. Nanoscale 2019, 11, 19742-19750; Kaliteevski M et al. Physical Review B 2007, 76, 165415). Here the emissivity of samples in FIG. 5 and FIG. 6 at different angles and polarizations are shown in FIG. 38-FIG. 41.

Section S14. Designed structures for inversely designed Tamm plasmon polariton emitters. Here, the parameters of the designed structures in FIG. 7-FIG. 10, FIG. 11, FIG. 48-FIG. 51, and FIG. 53 are provided. All of the designs comprised a 29-layer distributed Bragg reflector on top of a CdO bilayer with Ge as the first and last layers in the distributed Bragg reflector. The CdO carrier concentration is constrained between 0.2 and 12.0 e+20 cm⁻³, which is the range that has been demonstrated in literature (Nolen J R et al. Physical Review Materials 2020, 4, 025202; Liu C P et al. Physical Review Applied 2016, 6, 064018). A published model is used to calculate the dielectric function of CdO as a function of carrier density (Nolen J R et al. Physical Review Materials 2020, 4, 025202), and the corresponding MATLAB code is published online (https://my.vanderbilt.edu/caldwellgroup/). The dielectric function of Ge (Burnett J H et al. SPIE 2016, 9974, 99740X) and ZnSe (Gao W. SPIE 2009, 7283, 72832L) are considered as constants over the entire frequency range: 16+0i and 5.0625+0i, respectively. The substrate is fixed to CdO with the carrier concentration of 12.0×10²⁰ cm⁻³ (plasma frequency=7800 cm⁻¹), so that it was ensured there is no transmission. The units are all in nanometers.

Hyper-high-Q in FIG. 7:

| | | | | | | | | | | | | |
|---|---|---|---|---|---|---|---|---|---|---|---|---|
| [705 | 681 | 543 | 854 | 787 | 872 | 1073 | 1415 | 1491 | 1120 | 1133 | 1902 | 1702 |
| 2396 | 2563 | 2146 | 2051 | 2066 | 2447 | 2630 | 2141 | 1979 | 2351 | 2430 | 1945 | 2291 |

| | | | | |
|---|---|---|---|---|
| 2308 | 2460 | 1920 | 2500 | (N_{d} = 1.02 × 10²⁰ cm⁻³)] |

Multi-peak in FIG. 8:

| | | | | | | | | | | | | |
|---|---|---|---|---|---|---|---|---|---|---|---|---|
| [4 | 586 | 689 | 1 | 622 | 167 | 166 | 355 | 195 | 228 | 214 | 301 | 184 |
| 310 | 259 | 251 | 202 | 370 | 270 | 213 | 196 | 540 | 561 | 501 | 343 | 683 |

| | | | | |
|---|---|---|---|---|
| 698 | 697 | 177 | 1213 | (N_{d} = 1.86 × 10²⁰ cm⁻³)] |

Long-wave infrared to telecommunications in FIG. 9:

| | | | | | | | | | | | | |
|---|---|---|---|---|---|---|---|---|---|---|---|---|
| [476 | 345 | 258 | 261 | 455 | 399 | 297 | 176 | 458 | 447 | 355 | 407 | 286 |
| | 467 | 433 | 332 | 447 | 316 | 286 | 360 | 395 | 250 | 283 | 290 | 366 |

| | | | | | |
|---|---|---|---|---|---|
| 326 | 454 | 307 | 437 | 324 | (N_{d} = 6.3 × 10²⁰ cm⁻³)] |

Emissivity matching NO in FIG. 10:

| | | | | | | | | | | | | |
|---|---|---|---|---|---|---|---|---|---|---|---|---|
| [64 | 1401 | 588 | 169 | 278 | 1047 | 543 | 636 | 676 | 736 | 260 | 619 | 681 |
| | 448 | 1050 | 374 | 752 | 695 | 768 | 742 | 698 | 977 | 330 | 1286 | 922 |

| | | | | | | |
|---|---|---|---|---|---|---|
| 1116 | 831 | 557 | 93 | 565 | 564 | (N_{d} = 0.23 × 10²⁰ cm⁻³)] |

Matching DMMP nerve agent in FIG. 11 with CdO:

| | | | | | | | | | | | | |
|---|---|---|---|---|---|---|---|---|---|---|---|---|
| [19 | 1385 | 270 | 411 | 770 | 351 | 603 | 111 | 553 | 759 | 583 | 206 | 480 |
| | 213 | 876 | 457 | 1095 | 289 | 459 | 754 | 224 | 359 | 722 | 491 | 200 |

| | | | | | |
|---|---|---|---|---|---|
| 1009 | 898 | 1364 | 140 | 1713 | (N_{d} = 0.29 × 10²⁰ cm⁻³)] |

Matching DMMP nerve agent in FIG. 11 with gold (substrate is gold):

| | | | | | | | | | | | | |
|---|---|---|---|---|---|---|---|---|---|---|---|---|
| [244 | 394 | 402 | 314 | 300 | 421 | 359 | 404 | 324 | 284 | 434 | 591 | 495 |
| | 374 | 250 | 396 | 334 | 454 | 293 | 275 | 444 | 369 | 347 | 474 | 437 |
| | 491 | 106 | 442 | 574] | | | | | | | | |

Matching CO in FIG. 48:

| | | | | | | | | | | | | |
|---|---|---|---|---|---|---|---|---|---|---|---|---|
| [532 | 369 | 481 | 416 | 429 | 403 | 492 | 354 | 481 | 456 | 488 | 426 | 436 |
| | 343 | 464 | 365 | 509 | 342 | 451 | 399 | 516 | 453 | 461 | 362 | 301 |

| | | | | | |
|---|---|---|---|---|---|
| 502 | 710 | 540 | 150 | 631 | (N_{d} = 0.9 × 10²⁰ cm⁻³)] |

Matching O₃ envelope in FIG. 49:

| | | | | | | | | | | | | |
|---|---|---|---|---|---|---|---|---|---|---|---|---|
| [120 | 585 | 646 | 433 | 167 | 229 | 228 | 379 | 436 | 410 | 427 | 490 | 439 |
| | 441 | 362 | 445 | 465 | 528 | 245 | 343 | 371 | 174 | 267 | 676 | 582 |

| | | | | | |
|---|---|---|---|---|---|
| 511 | 365 | 147 | 213 | 1313 | (N_{d} = 1.4 × 20 cm⁻³)] |

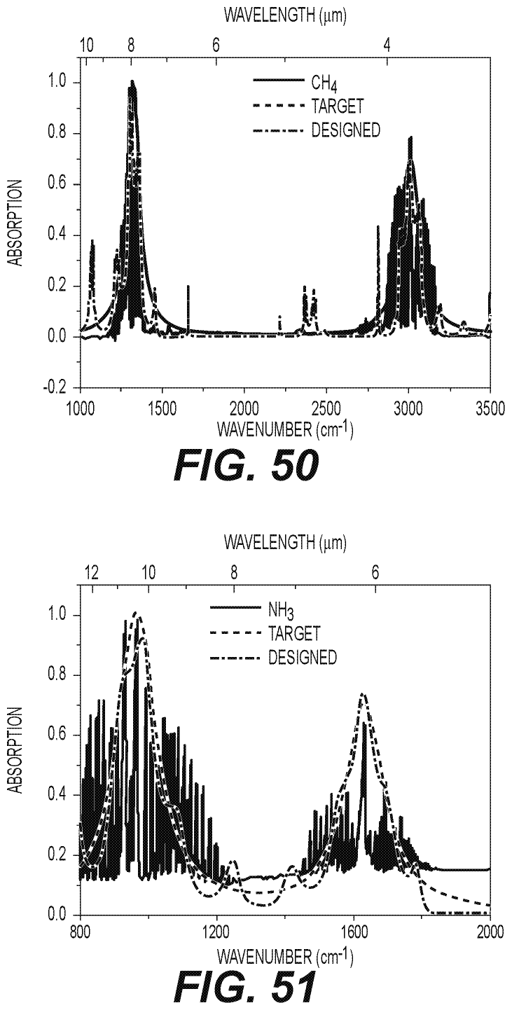

Matching CH₄ envelope in FIG. 50:

| | | | | | | | | | | | | |
|---|---|---|---|---|---|---|---|---|---|---|---|---|
| [379 | 287 | 418 | 720 | 310 | 514 | 611 | 312 | 375 | 443 | 522 | 443 | 372 |
| | 394 | 590 | 236 | 408 | 432 | 245 | 278 | 454 | 467 | 460 | 649 | 196 |

| | | | | | |
|---|---|---|---|---|---|
| 141 | 357 | 497 | 415 | 1116 | (N_{d} = 2.1 × 10²⁰ cm⁻³)] |

Matching NH₃ envelope in FIG. 51:

| | | | | | | | | | | | | |
|---|---|---|---|---|---|---|---|---|---|---|---|---|
| [47 | 698 | 472 | 96 | 440 | 640 | 235 | 301 | 482 | 301 | 349 | 400 | 380 |
| | 274 | 421 | 381 | 323 | 365 | 399 | 254 | 439 | 174 | 567 | 739 | 626 |

| | | | | | |
|---|---|---|---|---|---|
| 578 | 100 | 384 | 401 | 1582 | (N_{d} = 0.48 × 10²⁰ cm⁻³)] |

Emitted power matching N₂O in FIG. 53:

| | | | | | | | | | | | | |
|---|---|---|---|---|---|---|---|---|---|---|---|---|
| [92 | 460 | 759 | 414 | 98 | 275 | 726 | 355 | 174 | 416 | 305 | 209 | 191 |
| | 397 | 63 | 90 | 200 | 97 | 144 | 191 | 145 | 484 | 440 | 442 | 363 |

| | | | | | |
|---|---|---|---|---|---|
| 507 | 358 | 450 | 134 | 40 | (N_{d} = 3.19 × 10²⁰ cm⁻³)] |

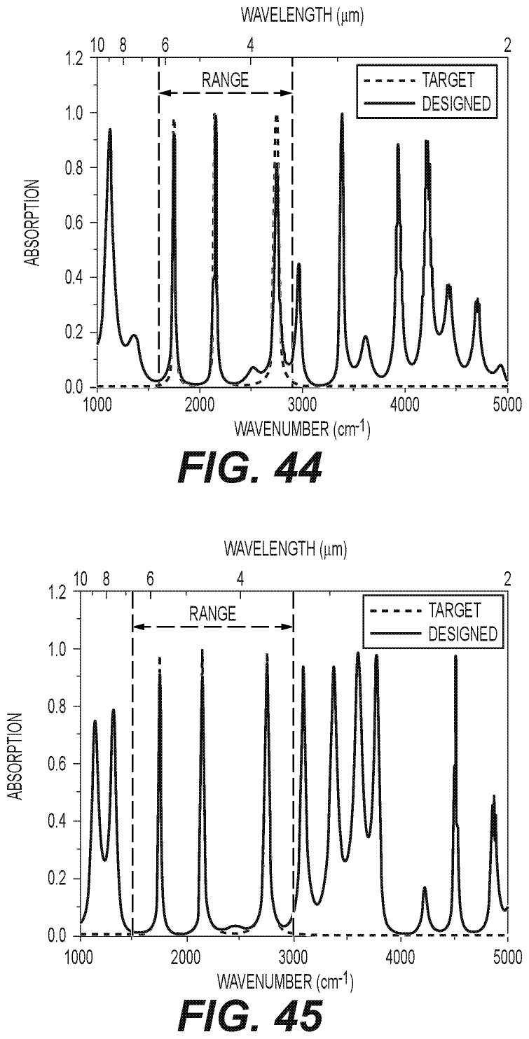

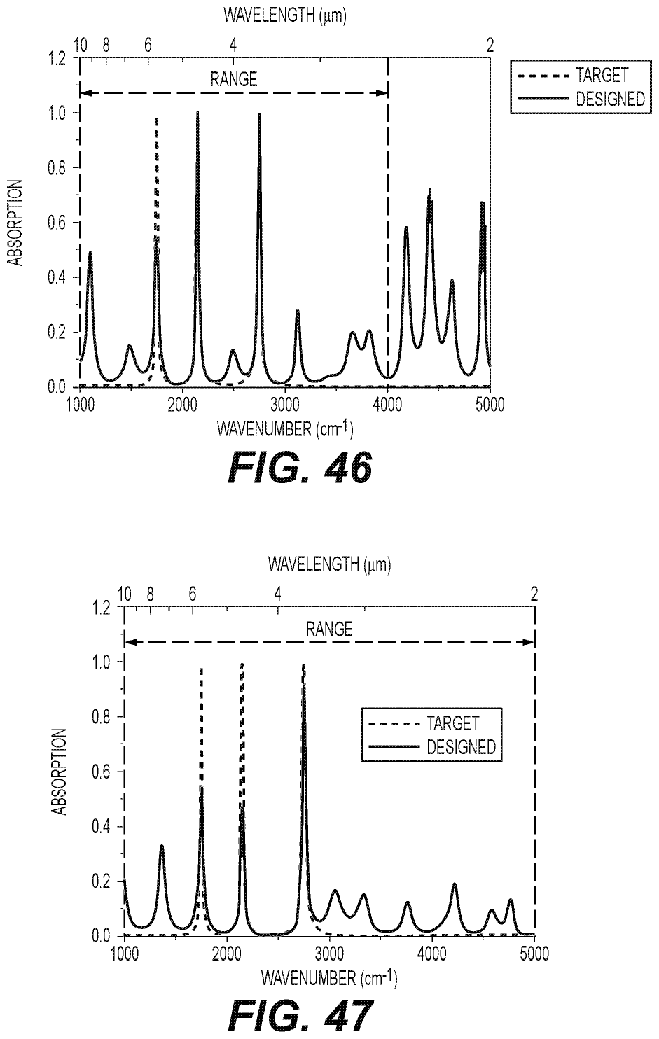

Section S15. Optimized Tamm plasmon polariton emitter within different frequency ranges. Here, how the “optimizing frequency range” will influence the outcomes is discussed. With a wider frequency range to optimize, the design will be more challenging due to the multi-mode nature of distributed Bragg reflector (FIG. 13). Here, one case is exemplified: a design for the same task presented in FIG. 6, with 11 dielectric layers, with different frequency ranges integrated for the optimization routine. The three peaks remain the same, and it is aimed to maintain the absorption (emissivity) as zero outside of those three main peaks. From FIG. 44-FIG. 47, the optimizing frequency range is progressively increased. Although the algorithm is able to suppress the side peaks well, it comes at the price of sacrificed performance for the main peaks. One can optimize the specific frequency range of interest depending on the application. For instance, in free-space communications, the performance of wavelength-selective thermal emitter in the water absorption band can be ignored since the energy will be attenuated through space propagation. One can also sample the frequency points more densely to force the algorithm to focus on that frequency of interest (section S1), and a similar balance can also be achieved via weighted error function.

Section S16. More demonstrations of inversely designed Tamm plasmon polariton emitters. A number of additional Tamm plasmon polariton emitter designs have been demonstrated, such as those matching the infrared-active vibrational spectra of nitric oxide (NO) and the nerve agent simulant dimethyl methyl phosphonate (DMMP). Here, additional examples are provided in FIG. 48-FIG. 51. Note that since the absorption spectra of O₃, CH₄ and NH₃ feature slopes or numerous sharp peaks, exact matching to the spectra cannot be realized. Instead, envelope spectra were used to cover those chemical spectra, and then these envelope spectra were employed as the target spectrum (TS). All the chemical absorption spectra are from the National Institute of Standards and Technology (NIST) website.

Section S17. Emitted power matching N₂O absorption spectrum. Since the emitted power is determined both by the emissivity and the temperature of the object, a Tamm plasmon polariton emitter working at 250° C. to be employed for N₂O non-dispersive infrared sensing was designed. First, the working temperature was determined to be 250° C., and this number can be adjusted according to the commercial product design based on signal strength and power consumption. Then the target emissivity spectrum becomes:

$$Target emissivity = normalize ( \frac{{N}_{2} O absorption spectra}{black body emission at 250 ° C .} ) \qquad ( S8 )$$

Here, the normalization is performed to make sure the highest emissivity is unity. The background absorption of N₂O was also removed. As such, the emissivity was adjusted to the specific working temperature, as shown in FIG. 52-FIG. 53.

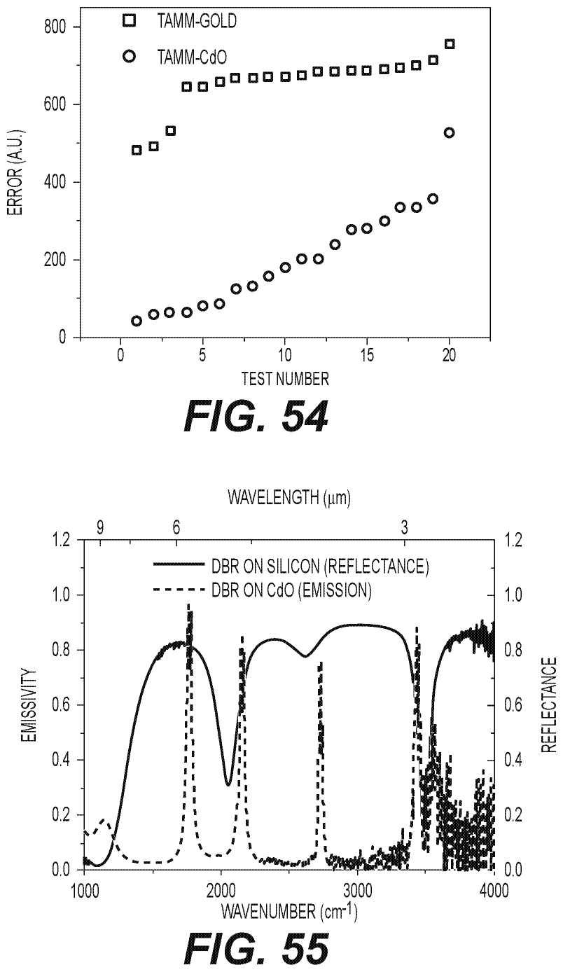

Section S18. Tamm plasmon polariton emitter optimizations with Gold and CdO. The stochastic gradient descent-based inverse design was also performed using the same constraints on the total number of dielectric layers (29 layers) for both CdO and gold as the bottom conductive layer. Both optimizations were performed 20 times to ensure that a local minimum is not reported. The errors are shown in FIG. 54, with the structures exhibiting the lowest error values reported in FIG. 11.

Section S19. Mechanism of Tamm plasmon polariton emitter. Generally speaking, the absorption resonances supported in the Tamm plasmon polariton emitter structures fall into two categories: a Tamm-mode (cavity mode between distributed Bragg reflector mirror and conductive substrate) and non-Tamm-mode (light transmitted from distributed Bragg reflector being absorbed by the conductor). For a Tamm plasmon polariton mode existing within the photonic bandgap of the distributed Bragg reflector, the reflection phase of the two mirrors (along opposing directions) must be equivalent but differ in sign (φ₁+φ₂=0). Herein, the metal-on-bottom distributed Bragg reflector-metal geometry where alternating layers of AlOₓ and Ge are grown on top of a doped CdO film was utilized. Since Tamm plasmon polariton modes are supported at the phase-matched condition between the conductor and the distributed Bragg reflector, one can determine whether a Tamm plasmon polariton mode will be supported at the conductor-distributed Bragg reflector interface by calculating the Fresnel reflection coefficients directed towards the distributed Bragg reflector and the conductor. There are several techniques for calculating the reflection coefficients of a multilayer structure, such as the transfer matrix method, which are used in the inverse-design calculations. However, for this simple model, an impedance model is used, as this method is conceptually intuitive due to its connection to circuit theory. Further, through the lumped-element model approach, this analysis can be extended to Tamm plasmon polariton-supporting films featuring a metasurface in place of the unstructured conductive film as well.

The characteristic p-polarized wave impedance in a material with a complex dielectric function εₙ is given as

$${Z}_{n} = \frac{{k}_{z , n}}{ω {ɛ}_{0} {ɛ}_{n}} \qquad ( S9 )$$

where

$${k}_{z , n} = \sqrt{{k}_{o}^{2} {ɛ}_{n} - {k}_{x}^{2}}$$

is the propagation constant along the z-direction, b is the frequency, and ε₀ is the permittivity of free space. From Equation (S9) it is evident that utilizing a doped semiconductor as opposed to noble metals for the conductor layer results in additional design flexibility due to the tunability of the optical impedance. Noble metals possess a large, defined carrier density and therefore the dielectric functions of these materials are also fixed. Alternatively, the plasma frequency of n-doped CdO is widely tunable throughout the IR granting additional flexibility to the design of Tamm plasmon polariton-supporting films by controlling the frequency at which the matching condition is realized for a fixed distributed Bragg reflector stack.

With the calculated characteristic impedances of each material, the total lumped impedances of the distributed Bragg reflector and conductive films can now be calculated. FIG. 57 shows the equivalent circuit model representation of a Tamm plasmon polariton film in the conductor-on-bottom geometry. To calculate the lumped impedance of the distributed Bragg reflector, starting at the dielectric layer furthest away from the CdO-distributed Bragg reflector interface, the impedance of each layer can be calculated using a recursive method. The impedance of an individual layer with a finite thickness is given as

$${Z}_{n , n + 1} = {Z}_{n} \frac{{Z}_{n + 1} + i {Z}_{n} tan ( {k}_{z , n} {d}_{n} )}{{Z}_{n} + i {Z}_{n + 1} tan ( {k}_{z , n} {d}_{n} )} \qquad ( S10 )$$

where dₙ is the layer thickness and n is an index denoting the layer number in the stack. Zₙ₊₁ is the total impedance behind the layer, so when calculating the impedance of the first layer of the distributed Bragg reflector in the CdO-on-bottom geometry Zₙ₊₁=Zₐᵢᵣ. The total impedance of the distributed Bragg reflector (Z_{DBR}) is then solved by progressing through the remaining layers in the stack. The impedance of the CdO layer (Z_{CdO}) is calculated using the same method, however, this is thus only limited to a single layer.

With the calculated lumped impedances Z_{DBR} and Z_{CdO} seen from the distributed Bragg reflector-CdO interface looking in opposing directions (See arrows in FIG. 57), the TP films can now be modeled as a simple AC equivalent circuit (FIG. 57) with source and load impedances. From circuit theory, the maximum active power is dissipated by the load at the conjugate impedance-matched condition Z_{DBR}+Z_{CdO}*=0. In Tamm plasmon polariton films, this translates to a Tamm plasmon polariton mode being supported when Im[Z_{DBR}]=−Im[Z_{CdO}], and the absorption maximized when Re[Z_{DBR}]=Re[Z_{CdO}] as well.

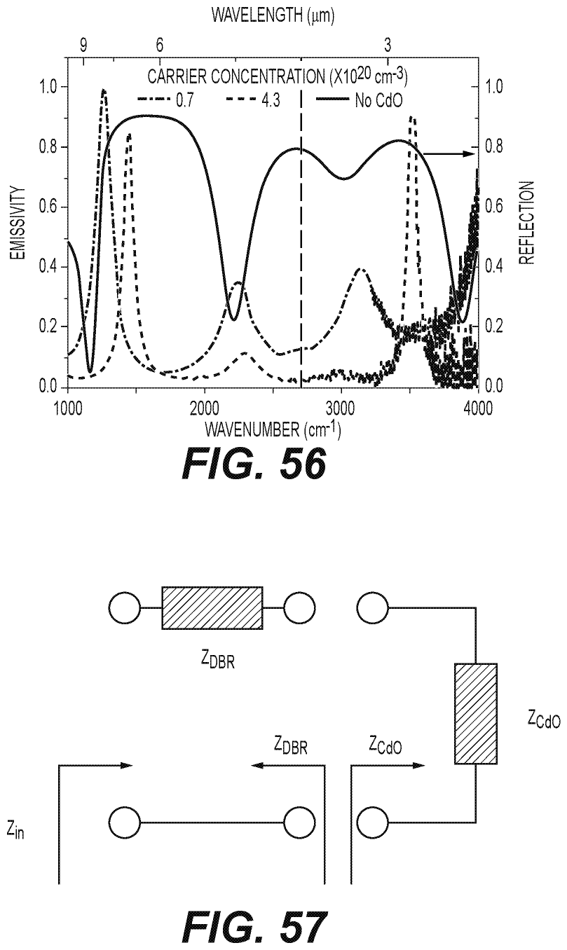

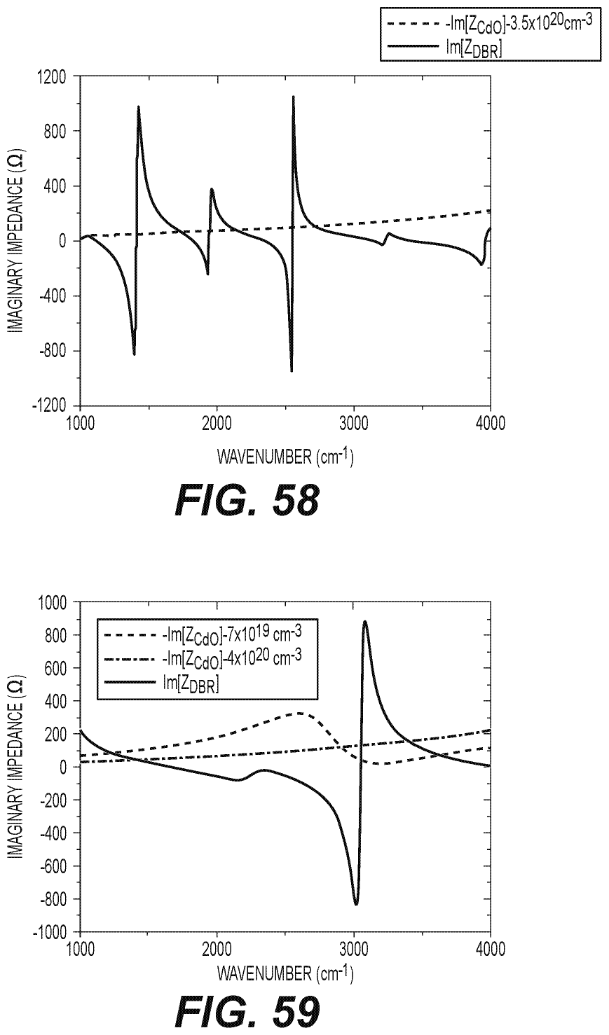

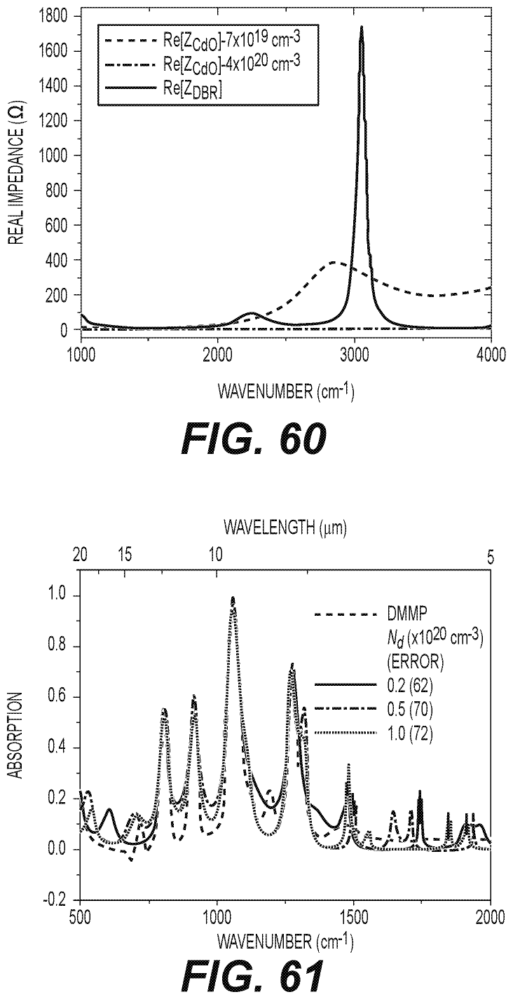

To illustrate this further, the reflectance (black line) of an aperiodic distributed Bragg reflector (on Si) and the emission (red line) from a Tamm plasmon polariton emitter (on CdO, N_{d}=3.5×10²⁰ cm⁻³) with an identical distributed Bragg reflector are provided in FIG. 55. In FIG. 58, the imaginary part of the distributed Bragg reflector (Im[Z_{DBR}]) and the CdO layer (−Im[Z_{CdO}]) impedances are provided for this Tamm plasmon polariton emitter. From FIG. 55 and FIG. 58, the peaks in emissivity from the Tamm plasmon polariton emitter correspond with the intersection of Im[Z_{DBR}] and −Im[Z_{CdO}]. The dips in reflectivity of the distributed Bragg reflector correspond with resonant features in Im[Z_{DBR}]. The large peaks in emissivity are a result of the high carrier density of the CdO film, and therefore the low Re[Z_{CdO}] of the CdO within this spectral range. Above the plasma frequency of the CdO, Re[Z_{CdO}] increases substantially, thus, resulting in poor impedance matching between the distributed Bragg reflector and the CdO. FIG. 56 displays the emissivity of two Tamm plasmon polariton emitters with identical distributed Bragg reflectors, but with one deposited on low-doped (N_{d}=7×10¹⁹ cm⁻³) and the other on high-doped (N_{d}=4.3×10²⁰ cm⁻³) CdO films. Although for both carrier densities of CdO, Im[Z_{DBR}] and −Im[Z_{CdO}] intersect at similar frequencies (see FIG. 59), the elevated Re[Z_{CdO}] of the low carrier density Tamm plasmon polariton emitter film (see FIG. 60) results in Tamm plasmon polariton modes not being supported above the plasma frequency of the CdO (dashed, vertical black line in FIG. 56).

Section S20. The role of CdO in the inversely designed Tamm plasmon polariton emitters: carrier concentration (real part of dielectric function) and mobility (imaginary part of dielectric function). Here, the discussion of how the tunable dielectric function of CdO (both real part and imaginary part) leads to the enhanced spectral control is extended. The dielectric function of CdO is mainly dictated by two components: carrier concentration (N_{d}) and mobility. N_{d} mainly determines the real part while the mobility mainly decides the ratio of imaginary part over real part. Herein, except for this section, the mobility is treated as a constant of 200 cm⁻²/V/s because the fabrication process does not change it dramatically. The N_{d} is designable as shown in experimental data.

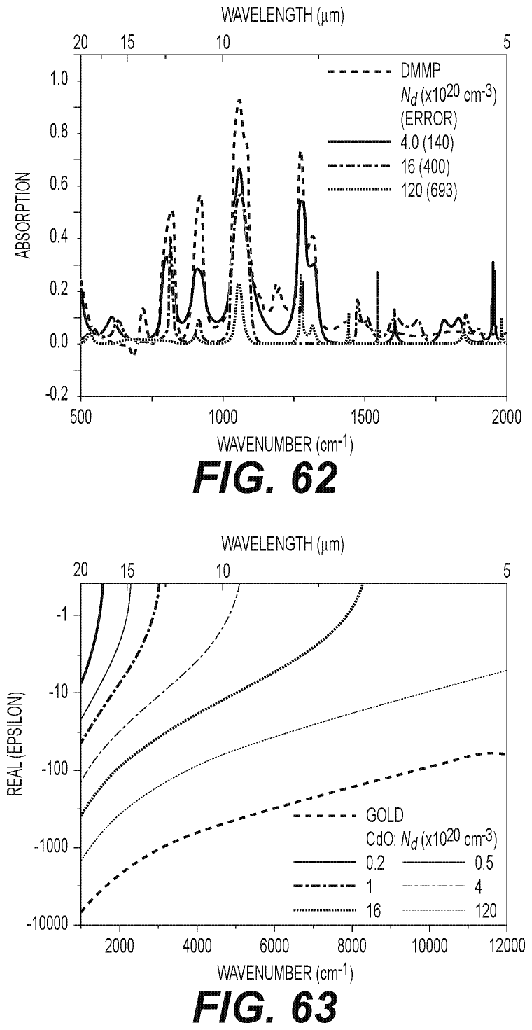

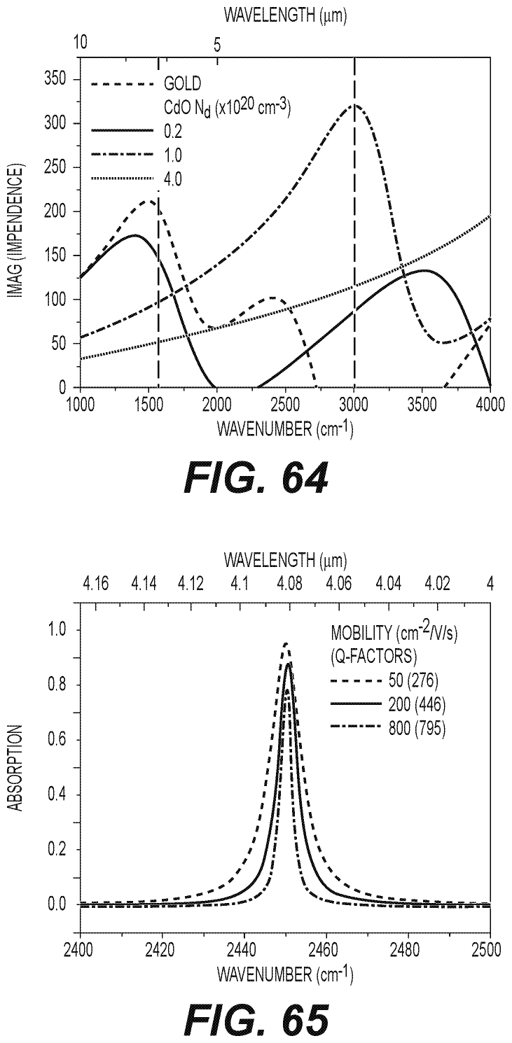

The influence of carrier concentrations. As discussed above regarding FIG. 11, it was observed that the CdO-based Tamm plasmon polariton emitter offers better performance, i.e., more close matching to the target spectrum, yet the inverse design algorithm provides no physical intuition. Here, revelation of the origin of how the tunable carrier concentration provides such substantial improvements to the performance of Tamm plasmon polariton emitters was attempted. To this aim, the same optimization was run to match the absorption spectrum of DMMP with different, fixed N_{dS}, ranging from 0.2 to 120.0×10²⁰ cm⁻³, spaced exponentially, as shown in FIG. 61-FIG. 62. Note that the highest possible carrier concentration of CdO is 12.0×10²⁰ cm⁻³, according to literature (Nolen J R et al. Physical Review Materials 2020, 4, 025202; Liu C P et al. Physical Review Applied 2016, 6, 064018), and herein this was extended to 120.0×10²⁰ cm⁻³ purely to explore the mechanism. The number of dielectric layers in the distributed Bragg reflector stack is fixed to 29 so that they are consistent with FIG. 11. It was found that the performance of CdO-based Tamm plasmon polariton emitter is strongly defined by the carrier concentration: when the carrier concentration is below 1.0×10²⁰ cm⁻³, the optimized structures have similar performances. However, when the carrier concentration is fixed at a value above 4.0×10²⁰ cm⁻³, the performance degrades. Thus, the dielectric function of CdO (equivalently, the carrier concentration in our case) can be considered as a parameter, and the algorithm can optimize this value for a given task. From a physics perspective, the dielectric function of CdO (FIG. 63) can be tuned via doping to adjust the impedance model (FIG. 64) so that the spectra of Tamm plasmon polariton emitters, which are determined by the impedance of the conducting layer and distributed Bragg reflector together (section S19), can be matched to arbitrary spectra.

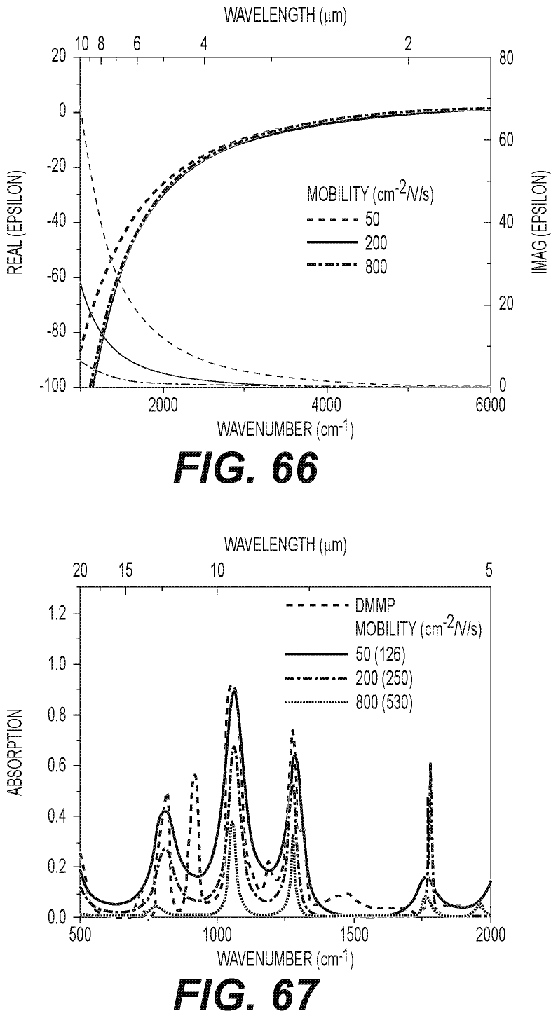

The influence mobilities. The CdO mobility determines the imaginary part of the dielectric function with a given carrier concentration (FIG. 66), which should influence the performance of Tamm plasmon polariton emitter according to references (Brand S et al. Physical Review B 2009, 79, 085416; Morozov K M et al. Scientific Reports 2019, 9, 1-9: Kaliteevski M A et al. Plasmonics 2015, 10, 281-284). Here, what will happen if the mobility is increased (decreased) for improved fabrication techniques (restricted fabrication process for cost, compatibility issue, etc.) is discussed. The mobility of 200 cm⁻²/V/s was used for the calculations reported herein, which is roughly in line with the lower end of the observed values measured experimentally for this material (Nolen J R et al. Physical Review Materials 2020, 4, 025202). However, for this thought experiment, here equivalent designs are performed with artificially reduced and increased values of 50 and 800 cm⁻²/V/s.

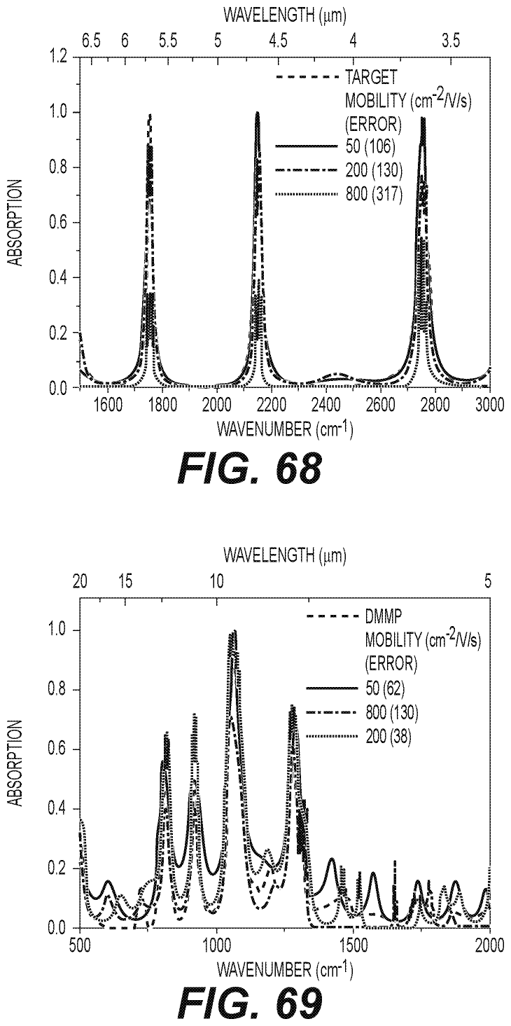

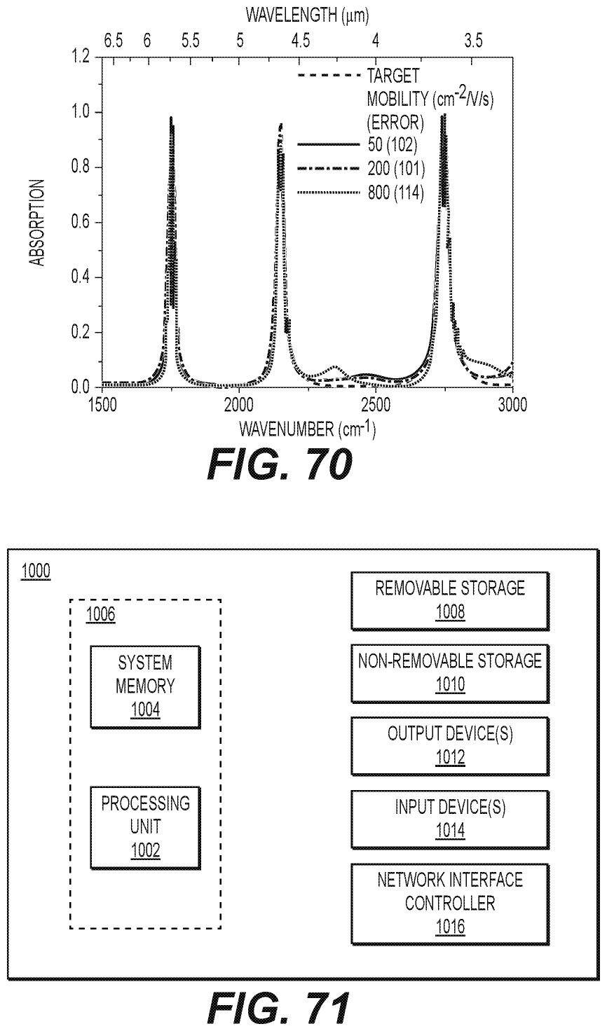

First, the highest accessible Q-factor with a given number of dielectric stacks (11 here) were compared and it was found that higher Q-factors can be achieved with higher mobility films, i.e., lower imaginary part of CdO dielectric function, as expected (FIG. 65, FIG. 66). Then, the carrier concentration (N_{d}) of CdO was fixed and the performance of inversely designed Tamm plasmon polariton emitters with different mobilities were compared for the same tasks with 11 and 29 dielectric layers, respectively. It was found that the two tasks can be realized with the best performance at specific mobility values, which are both 50 cm⁻²/V/s for the task in FIG. 67 and FIG. 68, respectively. Note that, for the comparison, the carrier concentration was fixed to 4.0×10²⁰ cm⁻³, however, at a different fixed carrier concentration the optimal mobility might become 200 or 800 cm⁻²/V/s, as the mobility and carrier concentration together determine the complex dielectric function of CdO (thus optical properties). Finally, the mobility of CdO was fixed to 50, 200 and 800 cm-2/V/s and the N_{d} was allowed to change freely. When the carrier density is allowed to vary to account for different mobility values, comparable performances were observed from all three even with dramatically different mobilities, as shown in FIG. 69-FIG. 70. Thus, the use of the CdO in which the carrier density can be controlled over a broad range implies that the increased/decreased mobility (loss of CdO) does not influence the performance of inversely designed Tamm plasmon polariton emitter for many tasks, providing such CdO-based designs unprecedented spectral control.

### Example 2—Designer Tamn Plasmon Thermal Emitters Using Gradient Descent Regression Optimization

The mid-infrared (MIR) spectral range is often referred to as the molecular fingerprint region due to the multitude of molecular vibrational signatures it contains. As such, research focused on developing mid-infrared optical sources of sufficiently narrow bandwidth, minimal power demands and small form factors are of great interest for potential spectroscopic and sensing applications such as bio- and chemical sensing, as well as the detection of harmful gases. One approach for such applications that has garnered significant attention recently has been frequency-selective thermal emitters. Here, by judiciously selecting and/or structuring semiconductor materials, the thermal photonic density of states can be tailored such that frequency-dependent far-field impedance matching, and therefore absorptivity, is achieved. Reciprocally, through Kirchhoff s law, this results in an emissivity of equivalent direction and magnitude. Herein is a report on a powerful approach towards realizing narrowband thermal emitters with a high degree of frequency selectivity, without sacrificing narrow emission linewidths that is typically an issue with plasmonic-based emitters, through the inverse design of aperiodic Tamm plasmon (TP) devices.

Tamm plasmons are optical interface states that form between a distributed Bragg reflector (DBR) and a metal or between two dissimilar distributed Bragg reflectors. These excitations exhibit a parabolic dispersion that falls within the photonic bandgap of the distributed Bragg reflector and the air light cone and are therefore accessible from free space without the need for expensive and time-consuming lithographic and etching fabrication steps. Herein, a gradient descent regression (GDR) algorithm is employed to design Tamm plasmon-supporting films in the metal-distributed Bragg reflector geometry and grow films that reproduce the predicted spectral features of the designs with great success. n-CdO deposited through high-power impulse magnetron sputtering is utilize as the metal layer. This highly-promising transparent conducting oxide (TCO) has been demonstrated to exhibit broad spectral tunability of the plasma frequency, while maintaining exceptionally low optical losses. This is due to CdO possessing both a low effective mass (ranging from 0.12-0.26 in epitaxially-grown films with carrier densities ranging from 10¹⁹-10²⁰ cm⁻³) as well as electron mobilities extending upwards to 500 cm⁻²/V-s. As Tamm plasmon modes correspond with the impedance-matched condition of the distributed Bragg reflector and the metal film, having such control over the impedance of both the distributed Bragg reflector (through changes to individual layer thicknesses and dielectric index), and the CdO layer (through changes to the carrier density and layer thickness), grants significant flexibility to the design.

Inverse design has been used to design Tamm plasmon-supporting films in the past, however, these efforts have relied on computationally-expensive techniques, such as genetic algorithms, Bayesian optimization, or deep learning, often requiring several hours or days to reach a final solution for a single-peak emission spectrum. In contrast, the gradient descent regression approach is capable of arriving at a solution on the timescale of seconds or minutes, all while running on a consumer-grade CPU. As demonstrated herein, this opens the door to realizing thermal emitters with varying levels of spectral complexity. For example, realizing arbitrarily positioned single- and multi-peak thermal emission spectra, which can accurately match to the IR absorption spectra of greenhouse gases such as CO₂ and N₂O. The methods herein were also able to achieve quality-factors that far-exceed conventional plasmonic devices (Q>300 for designed films), and control the full Tamm plasmon-dispersion and therefore spatial coherence of the thermal emission, all while maintaining a simple, planar structure. Therefore, the design principles used here outline a highly-tunable and potentially scalable platform for realizing applications such as filter-less non-dispersive infrared gas sensing and free-space communications

### Example 3—Designer Emission Spectra from Infrared Thermal Emitters as Optical Sources

The use of thin films of a polaritonic material (material or medium that exhibits a negative real part of the permittivity tensor along one or more Cartesian or crystal axes) on/below/in between one or more dielectric Bragg reflectors (multilayer dielectric photonic crystals), resulting in a structure suitable to support one or more Tamm plasmon polaritons (TPPs) resonance(s) has previously been described. Tamm plasmon polaritons can lead to single and/or multiple resonances, thus enabling single/multiple wavelength thermal emission lines.

Herein, new wavelength-selective emitters are described that can be employed within a non-dispersive infrared (NDIR) or other chemical sensor. This can be employed to sense chemicals in gas, liquid, or solid phases in reflection, transmission, absorption, or emission modalities. In an non-dispersive infrared sensor, the use of the wavelength-selective emitter removes the need for the traditional bandpass filters within the non-dispersive infrared device, while the emitter itself also serves to replace the traditional broadband blackbody emitter employed. The emission frequency (frequencies) of the device can be designed by physical intuition and/or algorithms. Once the emission frequency of the device is aligned to the absorption frequency of one or more vibrational or rotational modes for the chemical of interest, the chemical concentration can be sensed in a non-dispersive infrared setup. As the Tamm plasmon polaritons naturally support multiple emission frequencies, those frequencies could be used to either enhance the sensitivity of one gas/chemical or to enable the sensing of multiple chemicals of interest. For instance, if the multiple emission wavelengths are aligned to several absorption wavelengths of one particular chemical, the sensitivity to the sensing of that chemical would be improved. Alternatively, if absorption frequencies of several gases are matched from the emitter, each of those gases can be sensed simultaneously. More details and demonstrations can be found in the examples above. The two functions are not mutually-exclusive, and they can be realized simultaneously as demonstrated above. Furthermore, the Tamm approach can also be modified to create frequency specific absorption bands of an otherwise broadband detector (e.g. a mercury-cadmium-telluride, deuterated lanthanum α-alanine-doped triglycine sulphate detectors). As such, this technology offers opportunities to use wavelength-selective thermal emitters or detectors for advanced chemical, environmental, or remote sensing applications (high sensitivity, high signal to noise, and multi-chemical sensing).

The implementation of an unpatterned, multilayer planar film as the means of achieving narrowband thermal emission is newly described herein. The multiple emission frequencies from this structure can also be designed and/or dynamically modulated, which allows high sensitivity and/or multiple chemical sensing. In the case of the latter, active modulation could be achieved through several means, for instance carrier injection into one or more of the Tamm structure layers, incorporating ferroelectric or piezoelectric materials into the Tamm structure or incorporation of phase change materials.

Practical applications include gas, liquid, or solid material/chemical sensing via non-dispersive infrared sensors, or alternative approaches in the infrared. This overcomes the additional costs of incorporating a bandpass filter or in multifrequency chemical sensors the need for a bulky and expensive rotating bandpass filter wheel. The multiple emission frequencies can be used to enhance sensitivity and/or enable more chemicals of interest to be sensed within the same device, for instance by including multiple Tamm-based detectors and/or emitters within the same design that could be operated simultaneously or in series.

Compared to current non-dispersive infrared or similar IR gas or liquid sensors, the approach herein enables multiple frequency and multiple chemical detection within a compact single package without the need for bandpass filters. Further, variable temperature and computational algorithms can be included for multi-gas concentration differentiation.

### Example 4

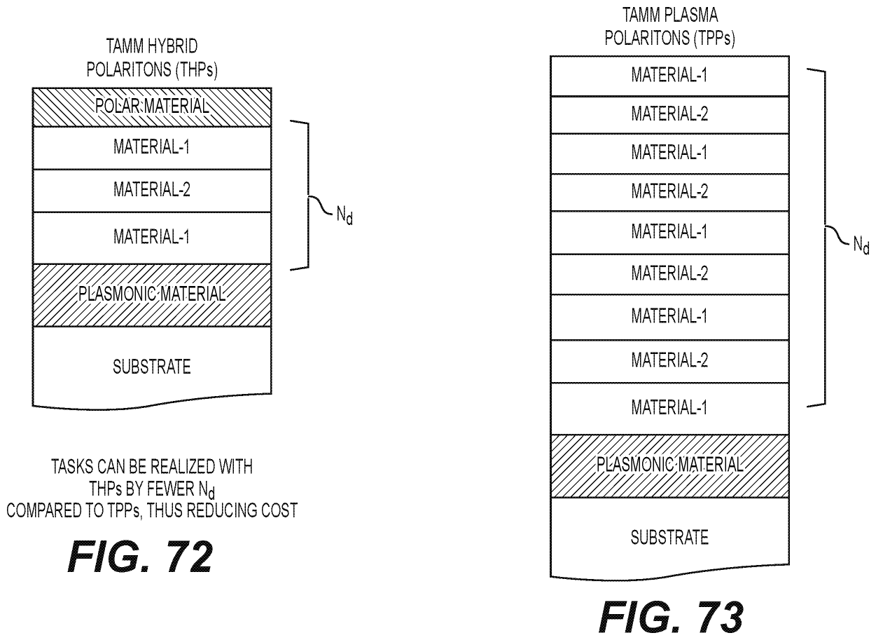

Although DBR growth is already cheaper than nanopatterning, the cost can still linearly increase with the number of DBR layers required. To further reduce the cost, it has been demonstrated that Tamm hybrid polaritons (THPs) can be used to realize multi-emissions with a lower number of DBR layers than TPPs (three times as exemplified below). One representative schematic of THP supporting structures is shown in FIG. 72: polar material, e.g., hexagonal boron nitride, and plasmonic material, e.g., metal or doped semiconductor, and one or multiple DBRs. The positions of the three components are not restricted to the schematic, and they can be in any order. The TPP supporting structure is a DBR-plasmonic material heterostructure (FIG. 73), as thoroughly discussed in Example 1.

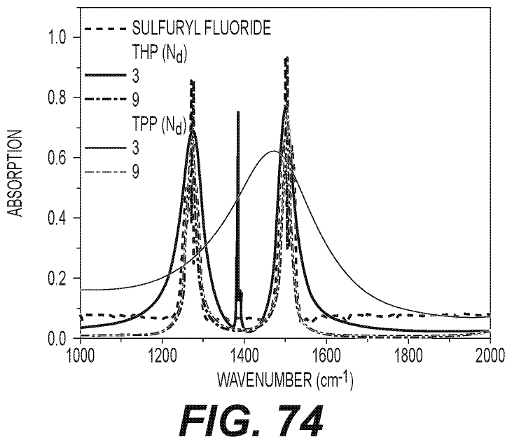

Here, it is exemplified how THP supporting structure fabrication is cheaper than the TPP supporting structure. To realize high sensitivity sulfuryl fluoride gas sensing, two emission peaks (equivalently, absorption peaks) are required. When TPP supporting structures are used, the number of DBR layer (N_{d}) is determined to be nine. However, Na of three is sufficient for THPs to realize this function, as shown in FIG. 74 Such a difference implies the fabrication cost can be reduced by at least two-fold when THP supporting structures are used. Since THP supporting structures do not require any nanopatterning either, they can still be mass fabricated at wafer scale by thin-film deposition, with even lower cost than TPPs, and they can be used for applications such as chemical sensing and infrared beacons.

### Example 5—Coupled Tamm Phonon and Plasmon Polaritons for Designer Planar Multi-Resonance Absorbers

Abstract. Wavelength-selective absorbers (WS-absorbers) are of interest for various applications, including chemical sensing and light sources. Lithography-free fabrication of wavelength-selective absorbers can be realized via Tamm plasmon polaritons (TPPs) supported by distributed Bragg reflectors (DBR) on plasmonic materials. While multi-frequency and nearly arbitrary spectra can be realized with Tamm plasmon polaritons via inverse design algorithms, demanding and thick distributed Bragg reflectors are required for high quality-factors (Q-factors) and/or multi-band Tamm plasmon polariton-absorbers, increasing the cost and reducing fabrication error tolerance. Herein, high Q-factor multi-band absorption is experimentally demonstrated with limited distributed Bragg reflector layers (3 layers) by Tamm hybrid polaritons (THPs) formed by coupling Tamm plasmon polaritons and Tamm phonon polaritons (TPhPs) when modal frequencies are overlapped. Compared to the Tamm plasmon polariton component, the Q-factors of Tamm hybrid polaritons are improved two-fold, and the angular broadening is also reduced two-fold, facilitating applications where narrow-band and non-dispersive wavelength-selective absorbers are needed. Moreover, an open-source algorithm to inversely design Tamm hybrid polariton-absorbers consisting of anisotropic media is develop and it is exemplified that the modal frequencies can be assigned to desirable positions. Furthermore, it is demonstrated that inversely designed Tamm hybrid polariton-absorbers can realize same spectral resonances with fewer distributed Bragg reflector layers than a Tamm plasmon polariton-absorber, thus reducing the fabrication complexity and enabling more cost-effective, lithography-free, wafer-scale wavelength selective-emitters for applications such as free-space communications and gas sensing.

Results and Discussion. Developing wavelength-selective absorbers (WS-absorbers) in the infrared is highly desirable for many applications ranging from optical sensing, imaging, photovoltaic/photothermovoltaic devices, to narrow-band and/or multi-frequency thermal emitters, and their expeditious design and fabrication is a long-standing scientific and technological goal. However, most wavelength-selective absorbers employ patterned nanostructures, requiring lithography and other high-cost fabrication steps, especially for low-volume manufacturing per design, making such approaches potentially inaccessible for many applications. Recently, it has been demonstrated that Tamm plasmon polaritons (TPPs) can be supported by planar films consisting of a distributed Bragg reflector (DBR) and a plasmonic material (Kaliteevski M et al. Physical Review B 2007, 76, 165415). The distributed Bragg reflector provides optical phase-matching to the plasmonic surface, leading to an absorptive resonance with high quality (Q)-factors accessible in free-space (Kaliteevski M et al. Physical Review B 2007, 76, 165415; Sasin M E et al. Applied physics letters 2008, 92, 251112; Sakurai A et al. ACS central science 2019, 5, 319-326; Wang Z et al. ACS Photonics 2020, 7(6), 1569-1576; Wang Z et al. ACS photonics 2018, 5, 2446-2452). As only thin-film deposition is required to fabricate these structures, Tamm plasmon polariton-absorbers offer a promising and simplified platform that can be grown at wafer-scale and therefore serve as a strong candidate for wavelength-selective absorbers for a variety of applications (Sakurai A et al. ACS central science 2019, 5, 319-326; Wang Z et al. ACS Photonics 2020, 7(6), 1569-1576; Wang Z et al. ACS photonics 2018, 5, 2446-2452).

Despite the high promise of Tamm plasmon polariton-absorbers, the distributed Bragg reflectors required for wavelength-selective absorbers can be sophisticated and difficult to fabricate. As discussed previously in literature, high Q-factors (Wang Z et al. ACS Photonics 2020, 7(6), 1569-1576; He M et al. Nature Materials 2021, 20, 1663-1669; Wang Z et al. Advanced Functional Materials 2021, 31(26), 2102183: Yang Z Y et al. ACS Photonics 2017, 4, 2212-2219) and multi-resonance (He M et al. Nature Materials 2021, 20, 1663-1669) wavelength-selective absorbers are only possible with sufficient number of distributed Bragg reflector layers, and the specific requirements vary from 5 to tens of dielectric layers. Therefore, for some applications of wavelength-selective absorbers, such as high sensitivity non-dispersive infrared sensing (NDIR), it is desirable to further optimize the structure, i.e., decrease the required number of distributed Bragg reflector layers and the total thickness to reduce the cost. One solution is introducing polaritonic strong coupling (Yoo D et al. Nature Photonics 2021, 15, 125-130; Runnerstrom E L et al. Nano letters 2018, 19, 948-957; Passler N C et al. Nano letters 2018, 18, 4285-4292) and/or hybridizing, here by coupling them with Tamm plasmon polaritons, thereby inducing additional resonances without modifying the distributed Bragg reflectors. Previous work has demonstrated the engineering of the spectral (Hu J et al. Optics express 2019, 27, 18642-18652; Hu J et al. Optics letters 2019, 44, 5642-5645) and spatial (Balevičius Z. Coatings 2020, 10, 1187; Buzavaite-Verteliene E et al. Optics express 2020, 28, 10308-10319; Kaliteevski M et al. Applied Physics Letters 2009, 95, 251108) properties in hybrid Tamm plasmon polariton-polariton systems (similar to other coupled systems). However, the coupling of low-loss phonon polaritons has not yet been explored. In addition, the altered resonances resulting from such hybridization make the design more challenging than pure Tamm plasmon polariton resonances, and the anisotropic phonon materials (He M et al. ACS Photoncs 2022, 9(4), 1078-1095) further complicate the system in the angular domain.

Herein, an approach to realizing high Q-factor, multi-resonant wavelength-selective absorbers by inducing Tamm hybrid polaritons (THPs) is demonstrated and an open-source inverse design algorithm for structure optimization is provided that is compatible even with the inclusion of anisotropic materials. The Tamm hybrid polariton-absorbers are realized by coupling Tamm plasmon polaritons and Tamm phonon polaritons (TPhPs), which are supported by distributed Bragg reflector with a doped semiconductor (cadmium oxide, CdO) and phonon polariton material, here hexagonal boron nitride (hBN). Experimentally, it is shown that Tamm phonon polariton-absorbers (hBN on distributed Bragg reflector) possess ˜10× narrower linewidths than their Tamm plasmon polariton counterparts (distributed Bragg reflector on CdO), resulting from the lower optical loss of the phonon polariton modes. In hBN-distributed Bragg reflector-CdO structures, Tamm hybrid polaritons are formed by spectrally overlapping the two modes, with the Tamm hybrid polaritons exhibiting two-fold narrower linewidth than the uncoupled Tamm plasmon polariton component. In addition to modified spectral behaviors, it is also shown that through Tamm plasmon polariton-Tamm phonon polariton coupling, the spatial dispersion of planar Tamm polaritons within the light cone can be engineered. In particular, the spectral detuning due to the angular dispersion of the Tamm hybrid polariton modes is reduced by half in comparison to uncoupled Tamm plasmon polariton modes, a consequence of the non-dispersive Tamm phonon polaritons. Further, an inverse design algorithm based on stochastic gradient descent (SGD) to design Tamm hybrid polaritons supported by anisotropic materials is developed. The design of Tamm hybrid polaritons by matching frequencies and lineshapes is illustrated and it is shown that those tasks can be achieved with Tamm hybrid polaritons with significantly fewer and thinner (˜2-5 times) distributed Bragg reflector layers compared to Tamm plasmon polaritons. Although herein exfoliated hBN was used for this proof-of-concept demonstration, high-quality polar materials that support Tamm hybrid polaritons (e.g., hBN (Wang G et al. Fundamental Research 2021, 1(6), 677-683), SiO₂ (Chen D Z A et al. Applied Physics Letters 2007, 91, 121906)) can be grown at wafer-scale (Lattemann M et al. Surface and Coatings Technology 2003, 174, 365-369; Ma K Y et al. Nature 2022, 606, 88-93; Li Q et al. Advanced Functional Materials 2022, 32(38), 2206094). Thus, the combination of efficient inverse-design algorithm and modal engineering facilitates the realization of cost-effective, wafer-scale, and lithography-free Tamm hybrid polariton-absorbers for numerous applications, including non-dispersive infrared, environmental, atmospheric, and chemical sensing, free-space communications, and infrared beacons.

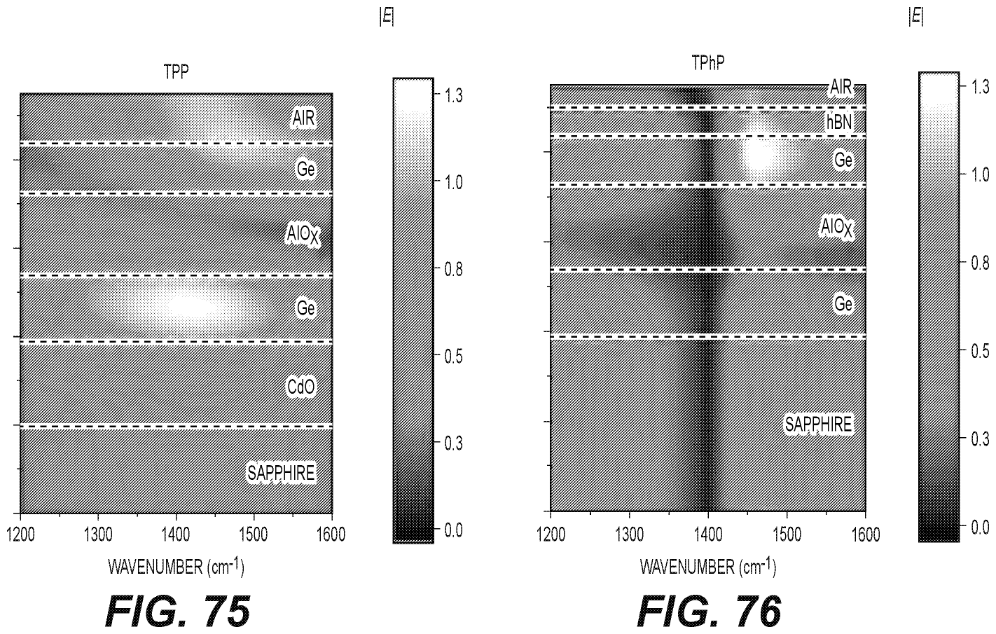

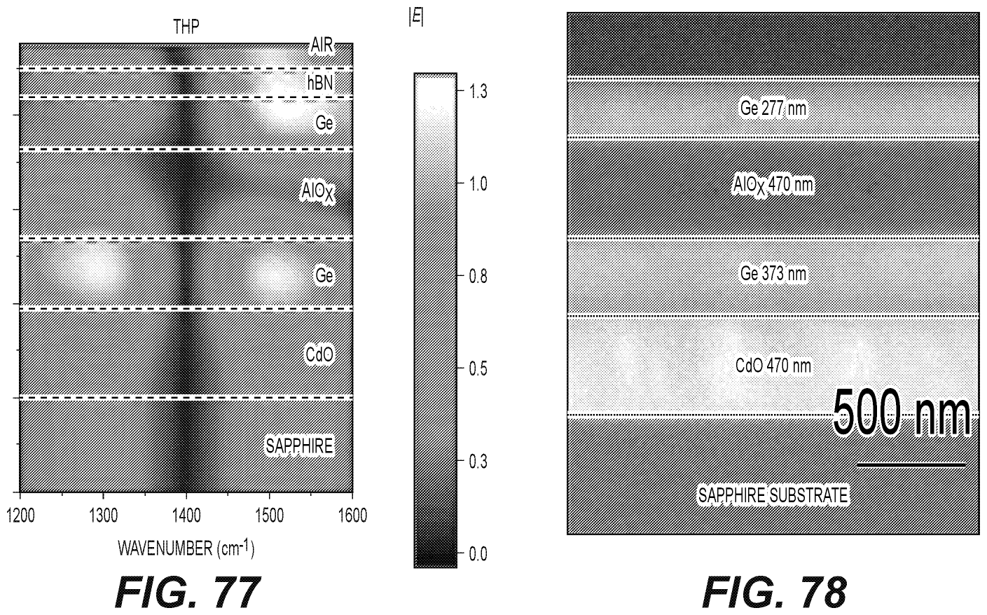

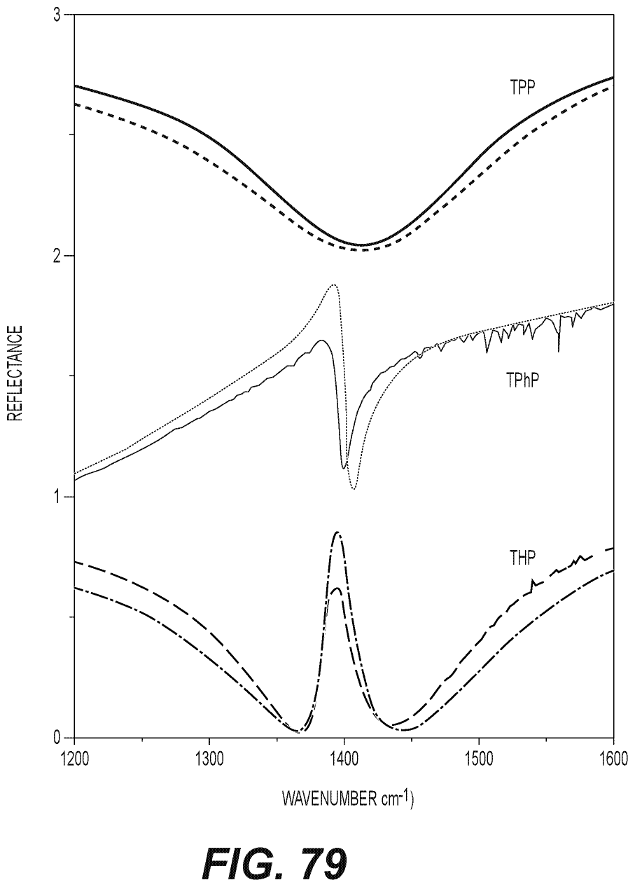

The Tamm polariton absorbers discussed are comprised of an aperiodic distributed Bragg reflector comprising Ge and AlOₓ alternating layers above/below the polariton supporting materials. To support a Tamm plasmon polariton resonance, a geometry of distributed Bragg reflector on a doped semiconductor (here, n-type CdO (Nolen J R et al. Physical Review Materials 2020, 4, 025202)) is employed that allows arbitrary resonant spectra to be matched by an inverse design algorithm (He M et al. Nature Materials 2021, 20, 1663-1669), with the resultant Tamm plasmon polariton field profile is shown in FIG. 75. To support Tamm phonon polaritons, a van der Waals material supporting phonon polaritons (¹⁰B enriched hBN (Giles A J et al. Nature Materials 2018, 17, 134; Liu S et al. Chemistry of Materials 2018, 30, 6222-6225)) was used and was transferred on top of the distributed Bragg reflector, as shown in FIG. 76. As such, the two modes can be supported simultaneously in an hBN-distributed Bragg reflector-CdO structure, resulting in modal coupling when the frequencies are overlapped. While Tamm phonon polariton frequencies are inherently limited to a small frequency range (within the Reststrahlen band (RB)), Tamm plasmon polariton modes can be designed to occur at any frequency below the plasma frequency of the material. Therefore, in order to achieve the requisite spectral overlap of the Tamm plasmon polariton and Tamm phonon polariton modes, an inverse design algorithm (He M et al. Nature Materials 2021, 20, 1663-1669) was used to design a Tamm plasmon polariton-absorber with the resonance aligned within the Reststrahlen band of hBN (at 1400 cm⁻¹). The three stacks simulated in FIG. 75-FIG. 77 were fabricated by a combination of sputtering, evaporation, and layer transfer, with the corresponding IR spectra shown in FIG. 79.

With the inversely designed and fabricated Tamm plasmon polariton-absorber, a resonance at around 1400 cm⁻¹ with a FWHM of 204 cm⁻¹ was observed. The relatively low Q-factor is caused by the intrinsic losses associated with the AlOₓ layer. During the fabrication process, the same distributed Bragg reflector stack was also deposited on a sapphire substrate so that hBN could be transferred onto the same distributed Bragg reflector to study the corresponding Tamm phonon polariton mode. In contrast to Tamm plasmon polariton modes, the linewidth of the Tamm phonon polariton supported by the same distributed Bragg reflector is significantly narrower: the FWHM is only 16 cm⁻¹ with a center frequency of 1400 cm⁻¹, as shown in FIG. 79. The improved Q-factor comes from the lower loss of polar dielectric materials in comparison to plasmonic materials, similar to the outcomes reported in the literature (He M et al. ACS Photonics 2022, 9(4), 1078-1095; Lee I H et al. Nature communications 2020, 11, 1-8; He M et al. Nano Letters 2021, 21, 7921-7928; Caldwell J D et al. Nano letters 2013, 13, 3690-3697). As stated above, different stacking orders (hBN-distributed Bragg reflector versus distributed Bragg reflector-CdO) were intentionally used so that the two modes can be simultaneously supported in a hBN-distributed Bragg reflector-CdO geometry. Indeed, Tamm plasmon polariton and Tamm phonon polariton modes are coupled to form two hybridized modes (Tamm hybrid polaritons), with one below and one above the transverse optical (TO) phonon frequency of hBN (FIG. 79). The Tamm hybrid polariton resonances are notated as the upper and lower polariton branches (UPB and LPB) based on resonance frequencies.

Importantly, Tamm hybrid polaritons result in nearly doubled Q-factors in contrast to the Tamm plasmon polariton component due to the inherently high-Q Tamm phonon polaritons contribution; therefore, this hybridization could be used to engineer spectral properties of Tamm polaritons. Evidence of modal coupling can also be inferred from the Tamm hybrid polariton field profile. For the uncoupled resonances, the field is confined in the Ge layer adjacent to the polariton supporting material: bottom and top Ge layer for Tamm plasmon polariton-absorber and Tamm phonon polariton-absorber, respectively. In the Tamm hybrid polariton-absorber, the fields are confined in both top and bottom Ge layers, exhibiting the profiles of Tamm plasmon polaritons and Tamm phonon polaritons simultaneously, which again validates the modal hybridization.

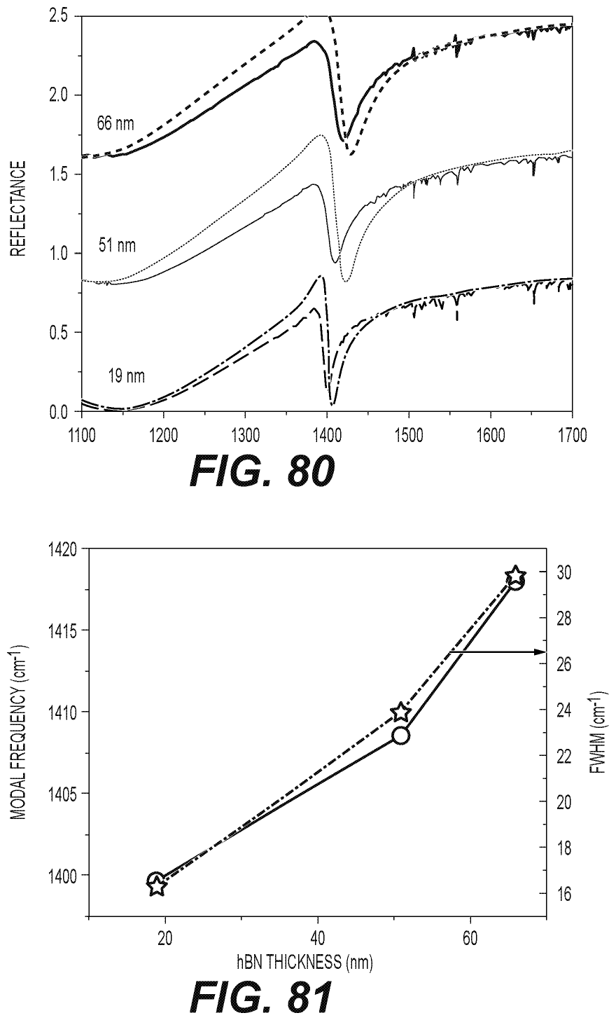

Before further discussing the modal coupling giving rise to the Tamm hybrid polaritons modes, the uncoupled Tamm phonon polariton modes will first be investigated, which have been underexplored compared to their Tamm plasmon polariton counterparts. For this purpose, a conceptually intuitive model (circuit impedance model) was employed to understand how Tamm phonon polaritons arise at the distributed Bragg reflector-hBN interface and how these modes can be engineered. Through the circuit impedance model, an effective impedance for the distributed Bragg reflector can be derived for any multilayer dielectric stack Z_{DBR}. Likewise, the optical impedance of the hBN layer (Z_{hBN}) can be defined from the dielectric function and thickness. The Tamm phonon polariton mode is then supported at the impedance matching condition between the hBN and distributed Bragg reflector: Z_{hBN}=ZD_{BR}, i.e., when Imag(Z_{hBN})=−Imag(Z_{DBR}). Further, IReal(Z_{hBN})−Real(Z_{DBR})| is negatively correlated with the resonance amplitude (Tsurimaki Y et al. ACS Photonics 2018, 5, 929-938). This model has been employed extensively in past work (He M et al. Nature Materials 2021, 20, 1663-1669; Tsurimaki Y et al. ACS Photonics 2018, 5, 929-938) and is described in further detail in the SI, section 1. Since thicker hBN blue shifts Imag(Z_{hBN}), the Tamm phonon polariton modal frequency moves to a higher frequency with thicker hBN. Experimentally, hBN with varying thicknesses was transferred onto the same distributed Bragg reflector and FTIR reflectance measurements were performed, and the results agree well with transfer matrix method (TMM) calculations (FIG. 80). Notably, the FWHMs of Tamm phonon polaritons also increase with hBN thickness (FIG. 81), since the impedance of thicker hBN is less dispersive in the frequency domain and the impedance matching condition can be satisfied over a wider frequency range, i.e., larger FWHM. It should be noted that the blue shifting is independent of the hyperbolic nature of hBN, and similar responses have been reported in metal-distributed Bragg reflector structures (Yang Z Y et al. ACS Photonics 2017, 4, 2212-2219).

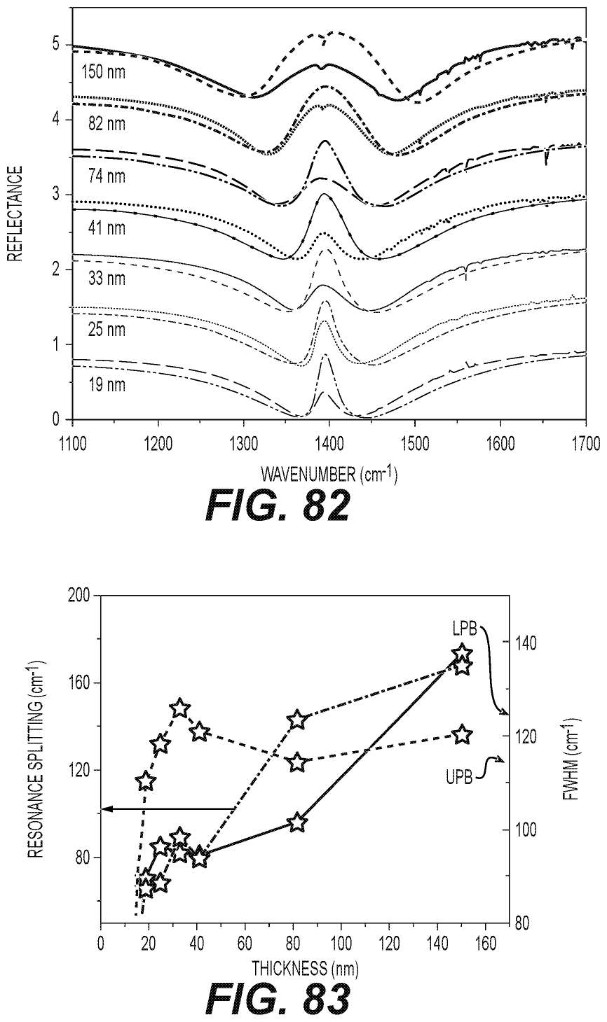

As Tamm phonon polariton modes are dependent on the hBN thickness, it inherently affects the properties of the Tamm hybrid polaritons. To study the thickness dependence of hBN upon the Tamm hybrid polaritons, a series of hBN flakes were transferred onto the Tamm plasmon polariton-absorber. With thicker hBN, the splitting between the two hybridized modes increases (FIG. 82, FIG. 83), a result of the larger spatial overlap with the electric field distribution of Tamm plasmon polariton and Tamm phonon polariton mode (FIG. 75 and SI, section 7). To further understand the hybridization phenomenon, a harmonic oscillator model was employed. The Hamiltonian matrix ( [symbol] ) for this coupled system can be written as:

$$ℋ = [ \begin{matrix}{ω}_{TPP} & g \\ g & {ω}_{TPhP}\end{matrix} ] \qquad Eq . ( 1 )$$

where ω_{TPP} and ω_{TPhP} are complex-valued resonance frequencies, and g is the coupling strength between the two modes. Eigenmodes of the systems governed by the Hamiltonian Eq. 1 satisfy the eigenequation

$$ℋ ψ = ω ψ \qquad Eq . ( 2 )$$

where ω is the modal frequency and ψ is the vector of modal amplitudes whose squared elements correspond to the Hopfield coefficients. Unknown parameters (g) are calculated by performing a least-squares fit to peak positions extracted from experimental data. With the coupling strength g extracted, the coupling criteria can calculated

$$C = = \frac{2 g}{{FWHM}_{SPhP} + {FWHM}_{SPP}} .$$

Experimentally, the coupling criteria (C, defined as

$$\frac{2 g}{{FWHM}_{TPhP} + {FWHM}_{TPP}} )$$

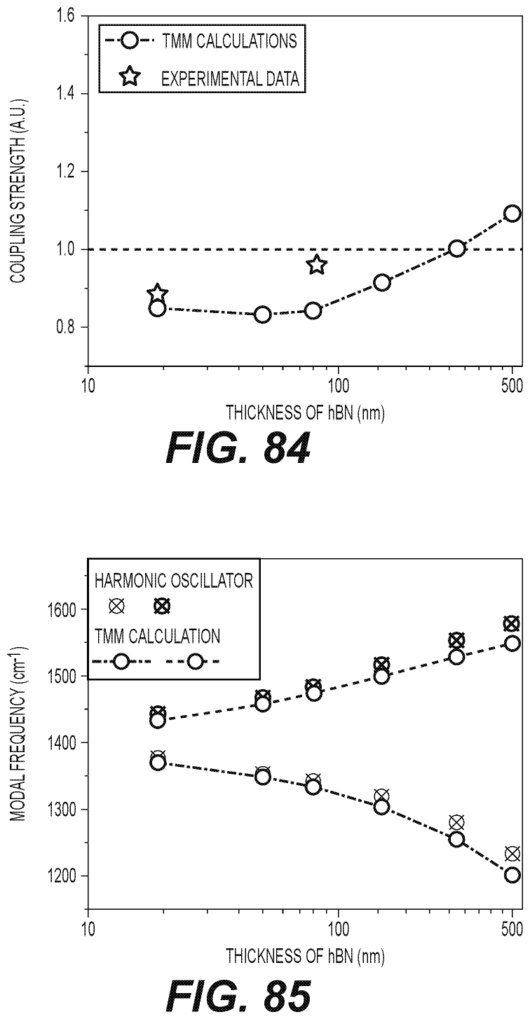

is 0.7-0.9 when the hBN thickness is below 100 nm. Although a clear spectral splitting is observed in the Tamm hybrid polariton dispersion, the system is within the weak coupling regime because of the large FWHM of the Tamm plasmon polariton mode (thus, small C≤1). However, when the hBN is thicker than 200 nm, the numerical simulations predict that the two modes will become strongly coupled (i.e., C≥1), as shown in FIG. 84. In addition, the accuracy of the model was validated by comparing the extracted modal frequency with that of the coupled harmonic oscillators, as shown in FIG. 85.

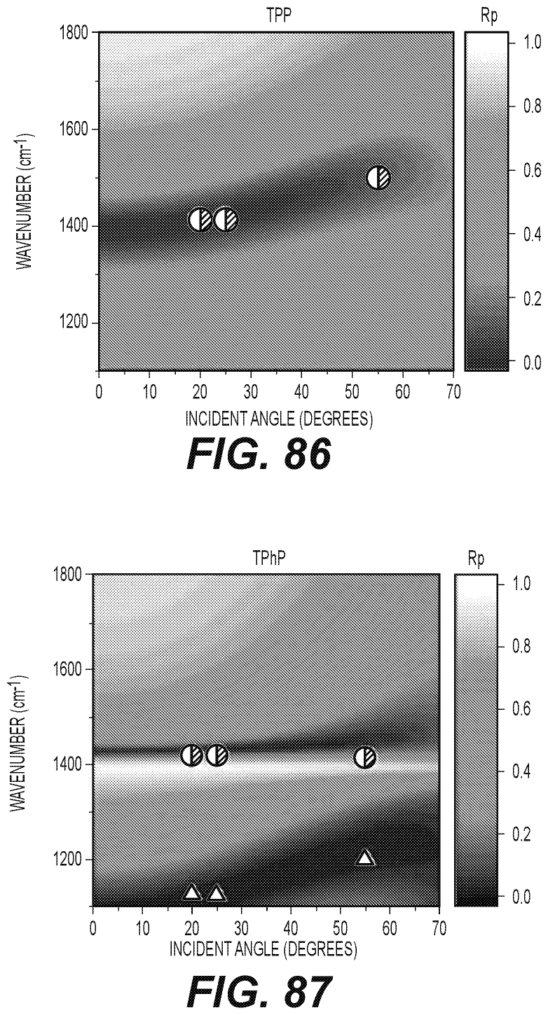

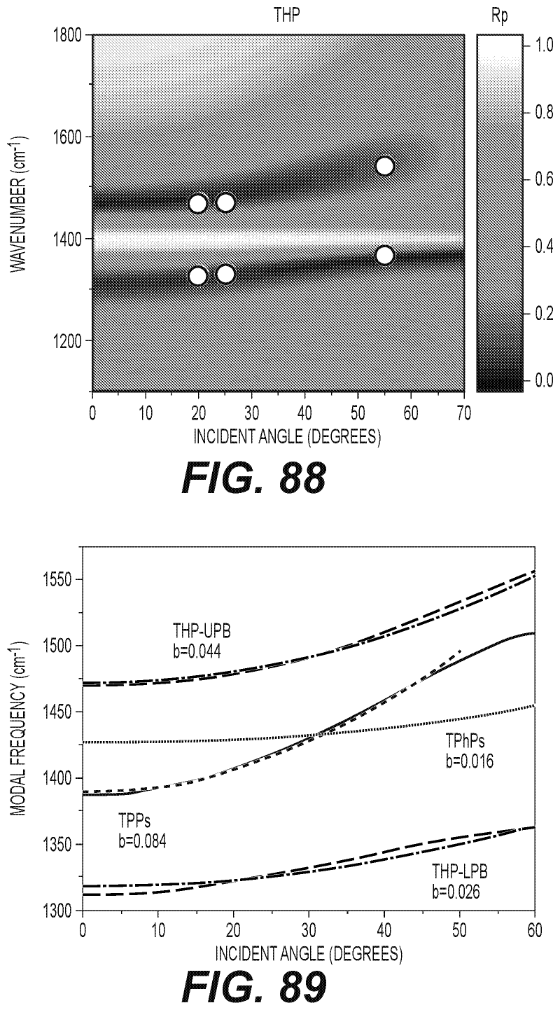

In addition to the spectral properties, the modal dispersion is engineered in momentum-space through modal coupling. First, the reflectance of the Tamm plasmon polariton-absorber at different incident angles was calculated, and then it was measured with three different objectives, allowing the spectral response at different incident angles to be acquired (measurement details are given in the Methods section). The accuracy of the numerical calculation was then validated by overlapping with the experimentally extracted resonance frequency, with the fitting details included in SI, section 2. The dispersion of the Tamm plasmon polariton mode is approximated through a second-order Taylor expansion (Kaliteevski M et al. Physical Review B 2007, 76, 165415; Overvig A C et al. Physical Review X2021, 11, 021050):

$${ω}_{resonαnce} ( θ ) = {ω}_{resonance} ( θ = 0 ) + \frac{b}{2} {θ}^{2} \qquad Eq . ( 3 )$$

where b is the phenomenologically determined band curvature, and θ is the incident angle in degrees. While the band curvature is 0.08 cm⁻¹/degree² for the Tamm plasmon polariton-absorber, the value is much smaller for the Tamm phonon polariton mode (0.016 cm⁻¹/degree²), as shown in FIG. 86, FIG. 87, and FIG. 89. A Rabi splitting is observed in the Tamm hybrid polariton dispersion at the intersection between the Tamm plasmon polariton and the ‘slower’ Tamm phonon polariton dispersion (FIG. 88), an indicator of modal coupling (Lu G et al. Nano Letters 2021, 21, 1831-1838; Dovzhenko D S et al. Nanoscale 2018, 10, 3589-3605). Quantitatively, the band curvatures of the upper polariton branch and lower polariton branch of Tamm hybrid polaritons are 0.04 cm⁻¹/degree² and 0.02 cm⁻¹/degree², respectively, both falling between the Tamm plasmon polariton and Tamm phonon polariton mode curvatures, as shown in FIG. 89. Therefore. Tamm plasmon polariton-Tamm phonon polariton hybridization also provides a means to engineer modes in momentum space: hybridizing with more (less) dispersive modes could increase (decrease) the spatial coherence of thermal emission (Lu G et al. Nano Letters 2021, 21, 1831-1838).

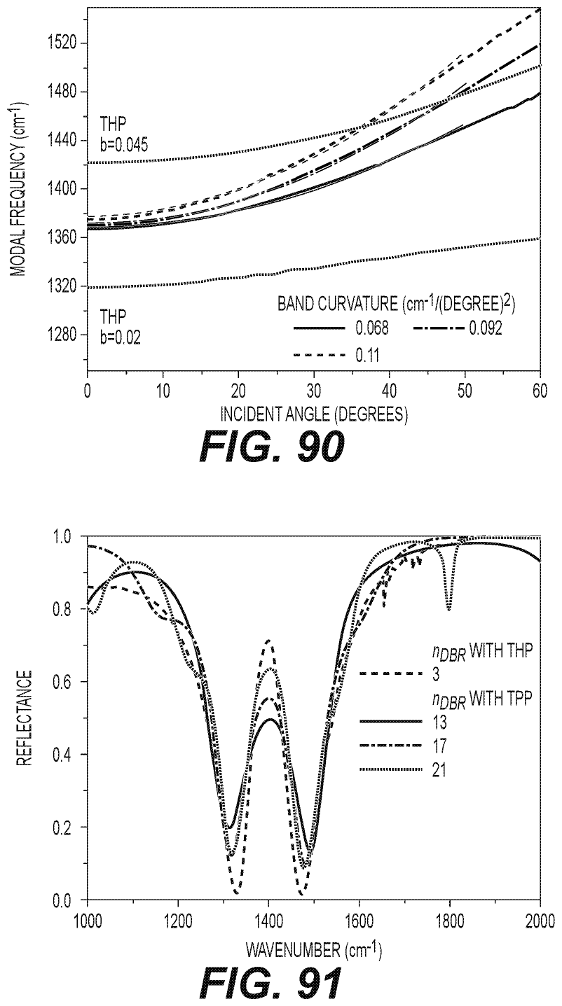

Benefitting from the modal coupling, Tamm hybrid polariton-absorbers exhibit modest dispersion and multiple resonances that could be advantageous over pure Tamm plasmon polariton-absorbers in many applications. First, the implication of the dispersion properties of Tamm hybrid polariton-absorbers is discussed. Small modal dispersion throughout momentum space is desired for applications where spectral properties should be angle independent. For instance, wavelength-selective absorbers can be used as wavelength selective thermal emitters for filterless chemical sensing and infrared beacons, where the emitted light at a range of incident or exit angles can be collected with parabolic mirrors to increase the signal intensity. As such, the device response will be a convolution among different angles, leading to spectral broadening. However, by trying to match different band curvatures with an inverse design protocol, it was found that the Tamm plasmon polariton dispersion is inherently limited within a certain range. For instance, for a Tamm plasmon polariton-absorber composed of Ge, AlOₓ and CdO, the band curvature is restricted between −0.06 and 0.1 cm⁻¹/degree², as shown in FIG. 90 (raw data provided in SI, section 3). Thus, for typical Tamm plasmon polariton-absorbers, the smallest resultant spectral broadening is ˜60 cm⁻¹ when incoming light (collected by a parabolic mirror with NA+0.7) spans ±45°. In contrast, by adding a 100 nm thick hBN over the same design, the spectral broadening is reduced, as shown in FIG. 86. Quantitatively, the FWHM of the Tamm plasmon polariton-absorbers is broadened from 38 cm⁻¹ to 100 cm⁻¹, while the FWHM of the corresponding Tamm hybrid polaritons only increases from 24 cm⁻¹ to 44 cm⁻¹. For high-Q Tamm plasmon polariton-absorbers (FWHM of 5.8 cm⁻¹), the angular spread (60 cm⁻¹) is significantly larger than the resonance FWHM, and numerically it was found that the resonance is suppressed when a range of incident angles are simultaneously considered. In contrast, the Tamm hybrid polariton-absorber response persists with the angular convolution. The detailed calculations and discussions can be found in the SI, section 4. In summary, the angular dispersion of Tamm plasmon polariton-absorbers fundamentally limits the spectral coherence when certain angular ranges are considered, with a key finding of this report being the observation that Tamm hybrid polariton-absorbers largely overcome this limitation.

In addition to the finer control of the dispersion, the Tamm hybrid polariton-absorber design potentially reduces the fabrication costs. As discussed in previous work (He M et al. Nature Materials 2021, 20, 1663-1669), the multi-resonance features can be deterministically achieved through inversely designed Tamm plasmon polariton-absorbers (He M et al. Nature Materials 2021, 20, 1663-1669), yet those advanced designs are only feasible with many-layer distributed Bragg reflector stacks. Herein, it is shown that spectral features realized with a 3-layer distributed Bragg reflector Tamm hybrid polariton-absorber can be quite sophisticated and would require a more complicated Tamm plasmon polariton-absorber stack. The normalized experimental Tamm hybrid polariton reflectance (FIG. 82) was used as the target spectrum and it was attempted to optimize a Tamm plasmon polariton-absorber to mimic it. FIG. 91 shows the measured Tamm hybrid polariton reflectance spectrum and simulated Tamm plasmon polariton spectra when the distributed Bragg reflector stack includes 13, 17, and 21 layers, with more than 17 layers being necessary to sufficiently replicate the infrared response. This comparison demonstrates that while the Tamm hybrid polariton spectral properties can be matched with Tamm plasmon polariton-absorbers, the associated distributed Bragg reflector must also be more complex, and therefore prone to inhomogeneities, defects, and thickness errors that can erode performance.

Since hBN exhibits strong anisotropy, i.e., the permittivity in the x-y plane is negative while it is positive along the z-axis between ˜1390 cm⁻¹ and 1650 cm⁻¹, it is important to discuss how this anisotropy affects the hybridized system. For that purpose, hBN was artificially modeled as an isotropic medium with ε_{z} assigned as equal to ε_{xy} (negative permittivity along all axis), similar to cubic boron nitride (Chatzakis I et al. Optics Letters 2018, 43, 2177-2180; He M et al. Journal of Materials Research 2021, 36, 4394-4403). Notably, the Berreman modes near the longitudinal optical (LO) phonon of hBN (1650 cm⁻¹) are excited in this artificially isotropic hBN, but they are absent in the real material because they can only be excited along the out-of-plane axis (Zhu H et al. Advanced Optical Materials 2021, 9(21), 2100645). As such, using hyperbolic media allows for selectively turning off those undesignable modes, which in many applications may be desirable (SI, section 5 and 8). Additionally, the response of the isotropic and anisotropic hBNs differ at high incident angles, e.g., 60°, while they are nearly identical at low angles. Therefore, the Tamm hybrid polaritons highlighted here can be supported by other isotropic polar materials, while the anisotropy further alters the Tamm hybrid polariton behaviors by restricting which modes can participate in the coupled system. Similar coupling phenomena is exemplified with other phonon polariton supporting materials (SiO₂ and SiC) with feasible designs in SI, section 8.

Despite the advantages, it is challenging to design Tamm hybrid polariton-absorbers where multiple resonances emerge at arbitrary frequencies. The challenge originates in part because all the resonances in the stack are interdependent, the distributed Bragg reflector is aperiodic, and the polar dielectric is potentially anisotropic. Therefore, it is impractical to design Tamm hybrid polaritons with conventional and intuitive models. To address this challenge, a previous stochastic gradient-descent-based inverse design algorithm was modified to enable the integration of anisotropic of materials such as hBN. The operating principle of the algorithm has been discussed in detail in a previous publication (He M et al. Nature Materials 2021, 20, 1663-1669), and this version is freely available online. In the following discussions that demonstrate this latest version, all the parameters, e.g., thickness of individual distributed Bragg reflector layers, polaritonic material (hBN and CdO) thicknesses, and carrier concentrations of CdO, are designable parameters, so that the design freedom of Tamm hybrid polariton-absorbers can be exploited.

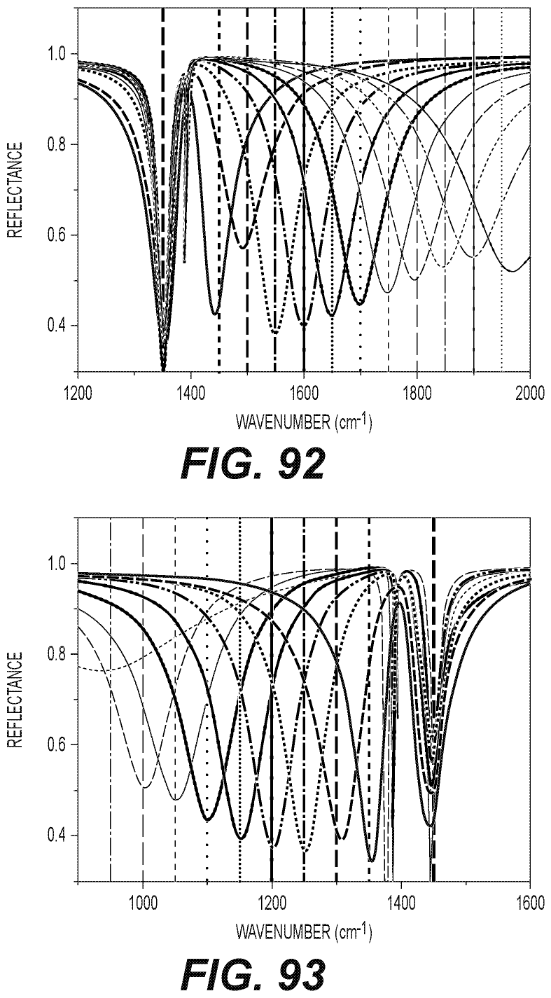

It is first shown that two resonance frequencies of Tamm hybrid polariton-absorbers can be independently assigned, which is extremely challenging with physical intuition as mentioned above. In the first case, the frequency of the lower polariton branch was fixed and it was attempted to change the frequency of upper polariton branch with a 50 cm⁻¹ steps. The inverse design algorithm accomplishes this task, with all lower polariton branch frequencies locked at 1350 cm⁻¹ while the upper polariton branch varied from 1450 to 1950 cm⁻¹, as shown in FIG. 92. Then, the algorithm was tested on the symmetrical task: moving the lower polariton branch frequency while the upper polariton branch frequency is fixed at 1450 cm⁻¹, and the targets are still achieved with the inverse design algorithm (FIG. 93).

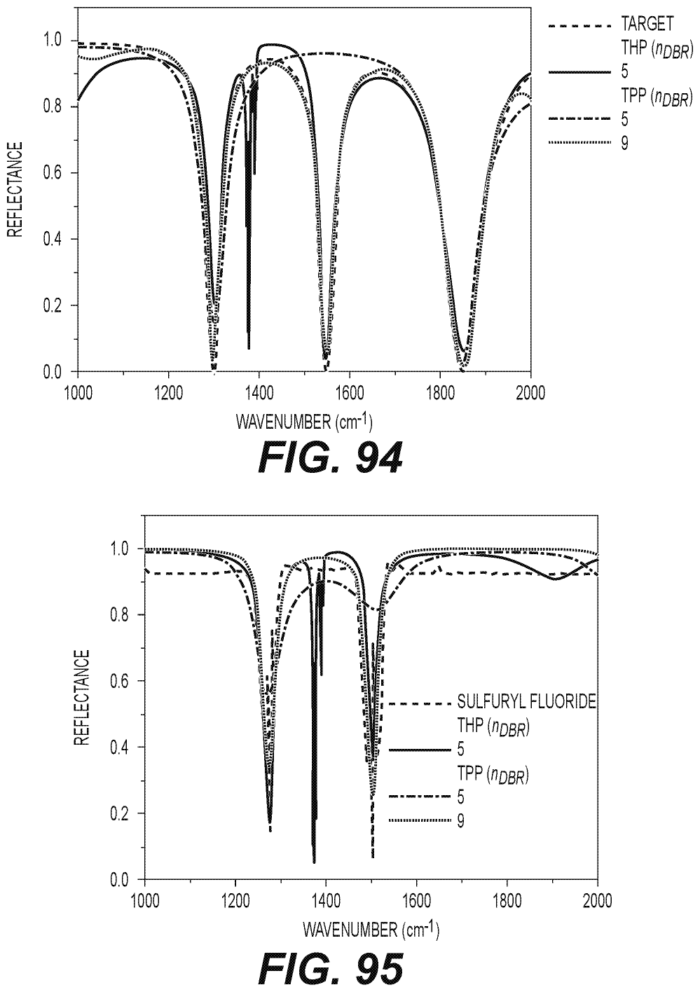

Since the hybridized modes naturally exhibit multiple resonances in a narrow frequency range, this property can be utilized to design multi-frequency wavelength-selective absorbers. Although it has been demonstrated that Tamm plasmon polariton resonances by themselves can be matched to arbitrary spectra with the inverse design algorithm (He M et al. Nature Materials 2021, 20, 1663-1669), it can only be achieved with a sufficient number of distributed Bragg reflector layers (notated as n_{DBR}), and n_{DBR} depends on the specific design requirement. For a spectral barcoding application shown in FIG. 94, where three resonance peaks are desired, the task can be accomplished with n_{DBR} of 5 for Tamm hybrid polariton-absorbers. In contrast, the optimized Tamm plasmon polariton with n_{DBR} of 5 can only offer two peaks, with the peak at 1500 cm⁻¹ not able to be matched. With more dielectric layers, the inversely designed Tamm plasmon polariton resonances can ultimately match these arbitrary shapes, but the n_{DBR} required for this barcoding task is 9, as shown in FIG. 94 yellow curve. Note that the resonance at ˜1400 cm⁻¹ for the Tamm hybrid polariton-absorbers cannot be avoided, as they originate from the transverse optical phonon absorption and the high positive permittivity of hBN near the transverse optical phonon (Howes A et al. Advanced Optical Materials 2020, 8, 1901470: Zhu H et al. Advanced Optical Materials 2021, 9(21), 2100645). However, considering the extremely narrow linewidth (˜5 cm⁻¹), the influence of that mode can be safely neglected in most cases. For instance, for thermal emitter applications, assuming 600° C. working temperature, the emitted power at ˜1400 cm⁻¹ only counts for 4% of the total emitted power in the 1000-2000 cm⁻¹ range (SI, section 6) for these designs.

The advantage of Tamm hybrid polariton-absorbers over Tamm plasmon polariton-absorbers in filterless non-dispersive infrared applications is further illustrated. As elaborated above, wavelength-selective absorbers could be used as wavelength-selective thermal emitters for filterless non-dispersive infrared applications. Additionally, high sensitivity chemical sensing can be realized when multiple absorption (equivalently, emission) frequencies of wavelength-selective absorbers are aligned to the chemical absorption spectrum, thus optimizing the signal intensity. Here, sulfuryl fluoride non-dispersive infrared gas sensing is used as an example; sulfuryl fluoride is a widely used pest control chemical, and the target spectrum is an envelope to cover the irregular-shaped absorption spectrum. Similar to the spectral barcoding application, the Tamm hybrid polariton-absorbers again show that the same task can be accomplished with fewer dielectric layers (5 layers versus 9 layers) than Tamm plasmon polariton-absorbers (FIG. 95). Therefore, the reduced requirements of the distributed Bragg reflector for the Tamm hybrid polaritons permit low-cost, wafer-scale and lithography-free fabrication for numerous applications.

Conclusion. In summary, the combination of the coupling phenomenon and the efficient inverse design algorithm enables designer multi-band wavelength-selective absorbers with limited distributed Bragg reflector layers, which were numerically and experimentally validated. By aligning the modal frequencies of Tamm plasmon polaritons and Tamm phonon polaritons, the two modes are coupled, and both spectral and spatial properties can be engineered. The hybridized Tamm hybrid polaritons modes exhibit improved Q-factors and slower spatial dispersion compared to their Tamm plasmon polariton components. Further, an algorithm was developed to inversely design Tamm hybrid polaritons comprising anisotropic materials, as an increasing list of phonon polariton supporting materials are being discovered and/or exploited (Ma W et al. Nature 2018, 562, 557: Taboada-Gutiérrez J et al. Nature materials 2020, 19, 964-968; Passler N C et al. Nature 2022, 602, 595-600; Caldwell J D et al. Nanophotonics 2015, 4, 44-68). With this algorithm, it was demonstrated that the two branches of Tamm hybrid polaritons can be individually determined. It was then demonstrated that Tamm hybrid polariton-absorbers can be used as multi-band wavelength-selective absorbers with significantly fewer distributed Bragg reflector layers (2-5 times) than Tamm plasmon polariton-absorbers, a significant reduction in fabrication complexity. It is stressed that other polar materials can be used to induce similar coupling, and material choice plays a critical role in the resultant Tamm hybrid polariton response. Empowered by the stochastic gradient descent algorithm and this tunability, the demonstrated spectral control of Tamm plasmon polariton-absorbers promises cost-effective, wafer-scale and lithography-free solutions for numerous applications throughout the infrared.

### Methods

Device fabrication. In-doped CdO (n-type) was deposited on 2-inch r-plane (012) sapphire single crystal substates at 400° C. by a reactive co-sputtering process employing high-power impulse magnetron sputtering (HiPIMS) and radio frequency (RF) sputtering from 2-inch diameter metal cadmium and indium targets, respectively. HiPIMS drive conditions were 800-Hz frequency and 80-ρs pulse time, yielding a 1250-ρs period and 6.4% duty cycle. Film growth occurs in a mixed argon (20 sccm) and oxygen (14.4 sccm) environment at a total pressure of 10 mTorr. Post-deposition, samples were annealed in a static oxygen atmosphere at 635° C. for 30 minutes.

Dielectric stacks (Ge and AlOx) were deposited at ambient temperature using electron beam evaporation from Ge (99.999%) and sapphire sources in vacuum. Thickness was monitored throughout the deposition using a quartz crystal microbalance (QCM). Post deposition, samples were cleaved and the layer thicknesses were measured using cross-sectional SEM.

¹⁰B enriched hBN (˜99% enriched (Giles A J et al. Nature Materials 2018, 17, 134; Vuong T et al. Nature materials 2018, 17, 152)) flakes were exfoliated and transferred onto the Tamm plasmon polariton-absorbers and distributed Bragg reflector samples using low contamination transfer techniques. The hBN crystals were grown with a boron source that was nearly 100% ¹⁰B isotope, as previously described (Liu S et al. Chemistry of Materials 2018, 30, 6222-6225).

Infrared reflection measurements. All infrared reflection measurements were performed with a Bruker Vertex 70v FTIR with a Hyperion II microscope, and the detector is a liquid nitrogen cooled mercury-cadmium-telluride (MCT) detector. In order to acquire the spectra at different incident angles, 15×. 36× and grazing angle objectives are used, and the incident angles are estimated to be 20, 25 and 55 degrees. While the measurement with grazing angle objective was p-polarized, other measurements are unpolarized. The spectral resolution was 2 cm⁻¹, and the spectra were referenced to a gold mirror.

Computation resources used for the algorithm. All the optimizations are performed on a consumer-grade desktop equipped with Intel I7-8700K CPU (˜$400 when first launched in 2017) and 16 Gb memory, and no GPU units are used. The algorithm is written in Python 3.6 with TensorFlow 2.3.0. The specific stochastic gradient descent version used is adaptive momentum estimation (Adam), provided by TensorFlow, and the optimization step is 0.005. All optimizations performed in this paper cost ˜1-10 minutes.

### Supporting Information (SI)

Section 1. Mechanism of Tamm polaritons explained by impedance model. The mechanisms of Tamm phonon or plasma polaritons have been discussed in series of papers (Tsurimaki Y et al. Acs Photonics 2018, 5, 929-938; Wang Z et al. Acs Photonics 2018, 5, 2446-2452; He M et al. Nature Materials 2021, 20, 1663-1669; Kaliteevski M et al. Physical Review B 2007, 76, 165415; Brand S et al. Physical Review B 2009, 79, 085416). Herein, the Tamm plasmon and phonon polaritons (TPPs and TPhPs) are explained with the impedance model (Tsurimaki Y et al. Acs Photonics 2018, 5, 929-938). For a Tamm mode existing within the photonic bandgap of the distributed Bragg reflector, the reflection phase of the two mirrors (along opposing directions) must be equivalent in amplitude but must differ in sign (φ₁+φ₂=0). Here, an impedance model is relied on as this method is conceptually intuitive due to its connection to circuit theory. Further, through the lumped-element model approach, this analysis can be extended to Tamm plasmon polariton-supporting films featuring a metasurface in place of the unstructured conductive film as well.

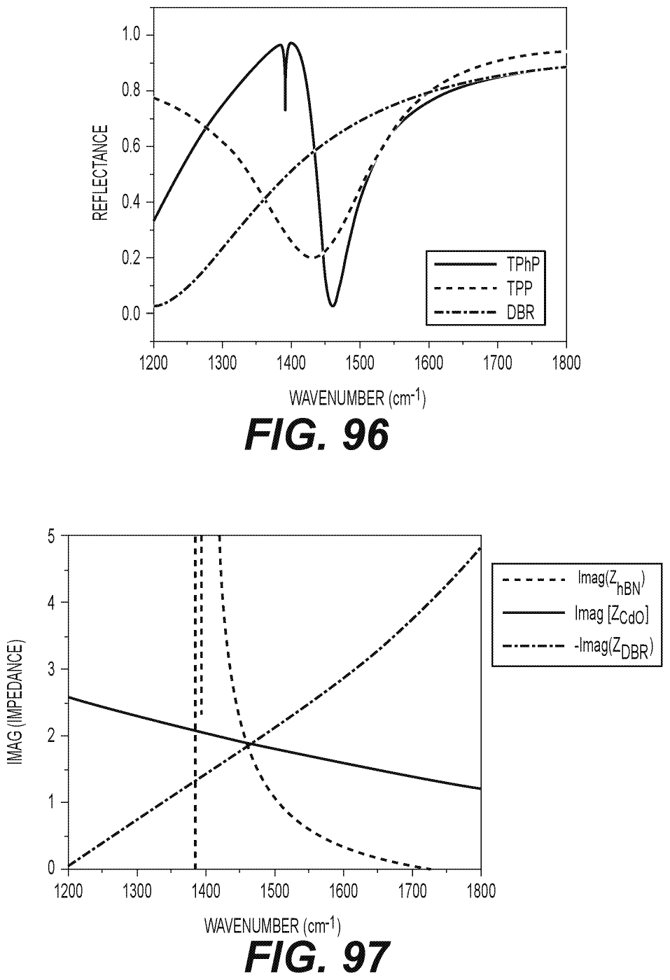

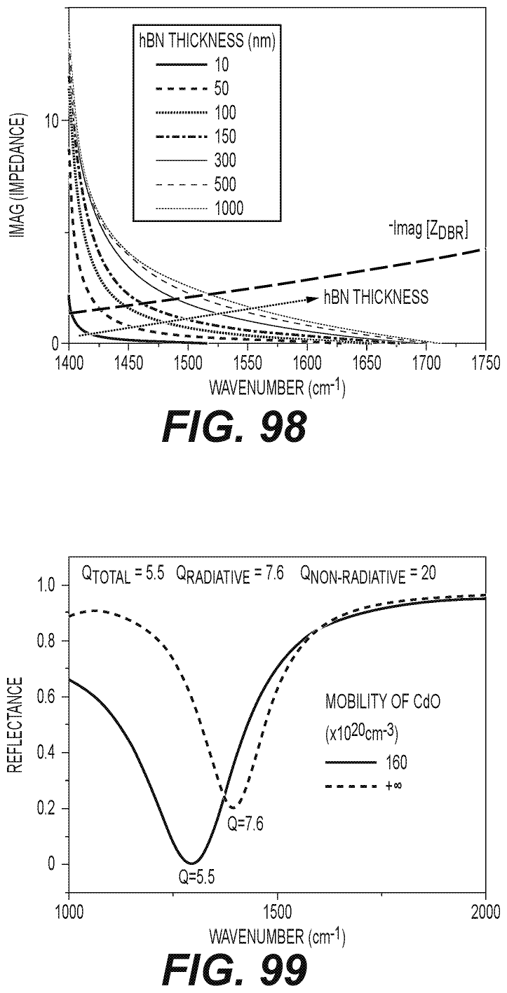

The normalized complex optical impedance of a surface is directly related to the complex surface reflection coefficient r=|r|e^{iδ} as Z/Z₀=(1+r)/(1−r) (Tsurimaki Y et al. Acs Photonics 2018, 5, 929-938), and can be calculated from a transfer matrix model (Passler N C et al. Physical Review B 2020, 101, 165425; Passler N C et al. JOSA B 2017, 34, 2128-2139) (FIG. 96). When the imaginary part of the impedance of the two components (distributed Bragg reflector and the polariton supporting material) are matched (equal in amplitude yet opposite in sign), the Tamm resonance can be supported. The intersection between −Imag (Z_{DBR}) and Imag (Z_{polariton supporting material}) determines the Tamm resonance, as shown in FIG. 97. While the thickness of CdO is around 500 nm, which can be considered as optically bulk, the thickness of hBN is relatively thin (10-200 nm). The impedance of hBN varies quickly with thicknesses when the thickness is below 100 nm, as shown in FIG. 98.

As the Tamm resonance is only present when Imag(Z_{hBN})−Imag(Z_{DBR})=0, the quicker the two components diverge from each other, the narrower the Tamm resonance would be as the condition no longer satisfies. Indeed, the dispersion of Imag(Z_{hBN}) is significantly faster than Imag(Z_{CdO}), and the dispersion is slower with thicker hBN, consistent with the observation that: Q-factor of Tamm phonon polariton is larger than Tamm plasmon polariton, and it decreases with thicker hBN.

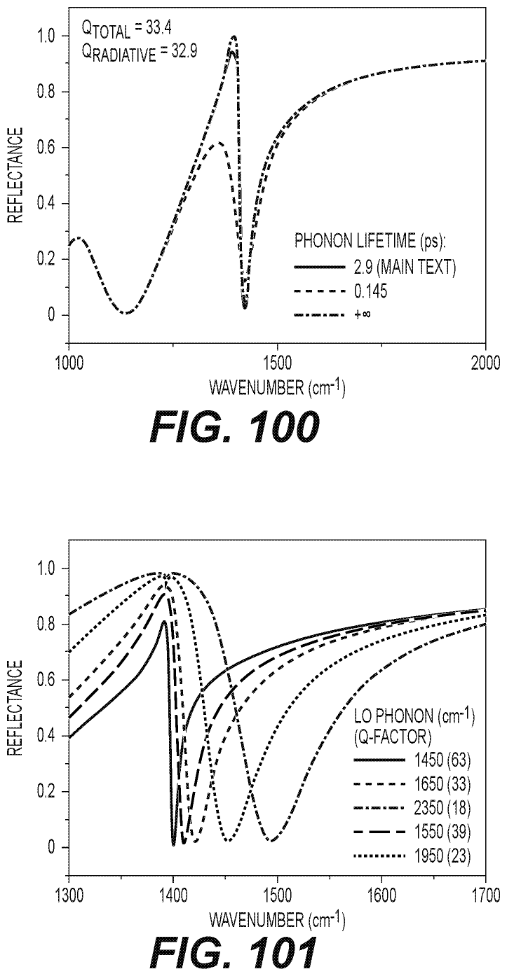

To further understand the improved Q-factor of Tamm phonon polaritons compared to Tamm plasmon polaritons, the quality factors of the two systems induced by impedance dispersion (radiative loss) and material loss (non-radiative loss) was analyzed. In order to find the radiative loss of the Tamm mode(s), both CdO and hBN were modeled in a loss-free manner by artificially setting the mobility and phonon lifetime as infinite (FIG. 99-FIG. 100), respectively, following the methodology of Yoon et al. (Yoon J et al. Optics Express 2008, 16, 1269-1279). The radiative loss of Tamm phonon polaritons is significantly lower than Tamm plasmon polaritons (Q factor of ˜33 versus 7.6), which is caused by the fast dispersion of hBN impedance mirror, and as discussed further in the following paragraph. With the radiative loss and overall loss of two systems, the non-radiative loss can be derived (Yoon J et al. Optics Express 2008, 16, 1269-1279) and the non-radiative loss of Tamm phonon polaritons is negligible while it is still playing an essential role in Tamm plasmon polaritons. Assuming a phonon polariton material with the same dispersion of hBN yet a material quality of plasmonic material (phonon lifetime of 0.145 ρs), the resulting Q-factor of Tamm phonon polaritons was found to be reduced from ˜33 to ˜25, indicating that the low loss of phonon polariton material is still important.

Note that the Q-factor of Tamm plasmon polaritons is still lower than Tamm phonon polaritons even if they are both lossless, with this caused by different impedance dispersions. The radiative loss is determined by the relative dispersion of the two mirrors in the system: the distributed Bragg reflector and polaritonic mirror. As mentioned elsewhere (Tsurimaki Y et al. Acs Photonics 2018, 5, 929-938; Wang Z et al. Acs Photonics 2018, 5, 2446-2452; He M et al. Nature Materials 2021, 20, 1663-1669; Kaliteevski M et al. Physical Review B 2007, 76, 165415; Brand S et al. Physical Review B 2009, 79, 085416), the Tamm mode is supported when the imaginary part of the impedance for the two components are matched. In other words, for a system where the two impedances deviate from each other faster in the spectral domain, the mode will be supported over a smaller frequency range, and thus, a narrower linewidth and therefore a higher Q-factor. Since the impedance of the hBN is much more dispersive than CdO (FIG. 96-FIG. 98), the corresponding Tamm mode is only supported within a narrower frequency range, therefore causing the modal linewidth to be reduced even if the scattering lifetimes of the phonon and plasmon polariton materials were equivalent. To further confirm this, a system featuring hBN with different artificial longitudinal optical phonon frequencies to modify the spectral dispersion with a fixed scattering lifetime was also modeled, and it was found that the quality factor increases with faster material dispersion (FIG. 101). Therefore, the improved Q-factors of Tamm phonon polaritons can be attributed to both the material dispersion (radiative loss) and material quality (non-radiative loss).

Section 2. Peak fittings. Tamm phonon polariton, Tamm plasmon polariton and Tamm-hybrid samples were measured with three different objectives, leading to varying incident angles. Asymmetric peak fitting functions provided by Origin Lab were used to find the FWHM and center max of those peaks.

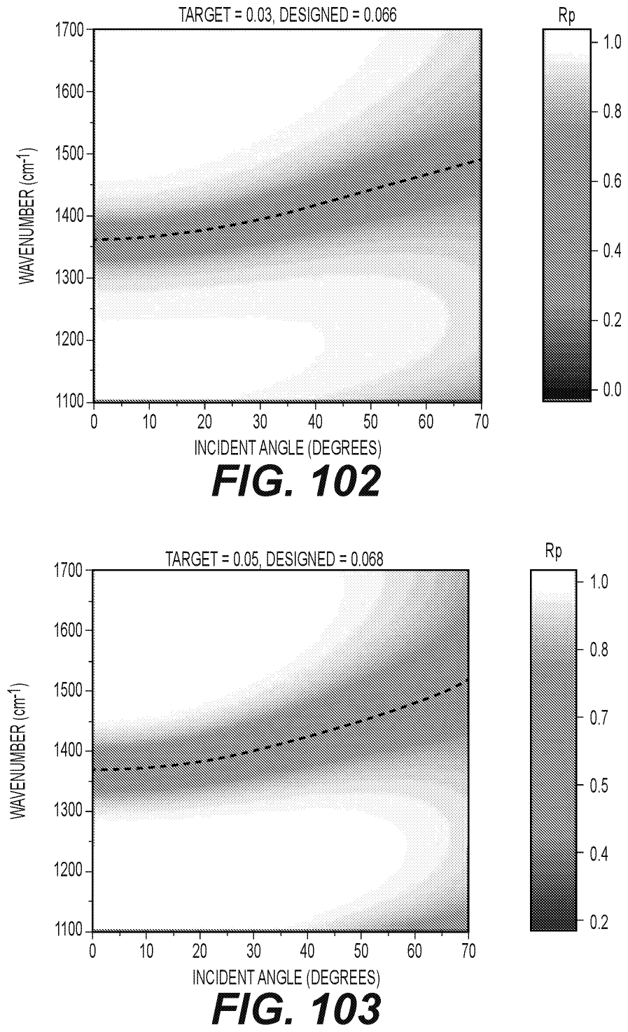

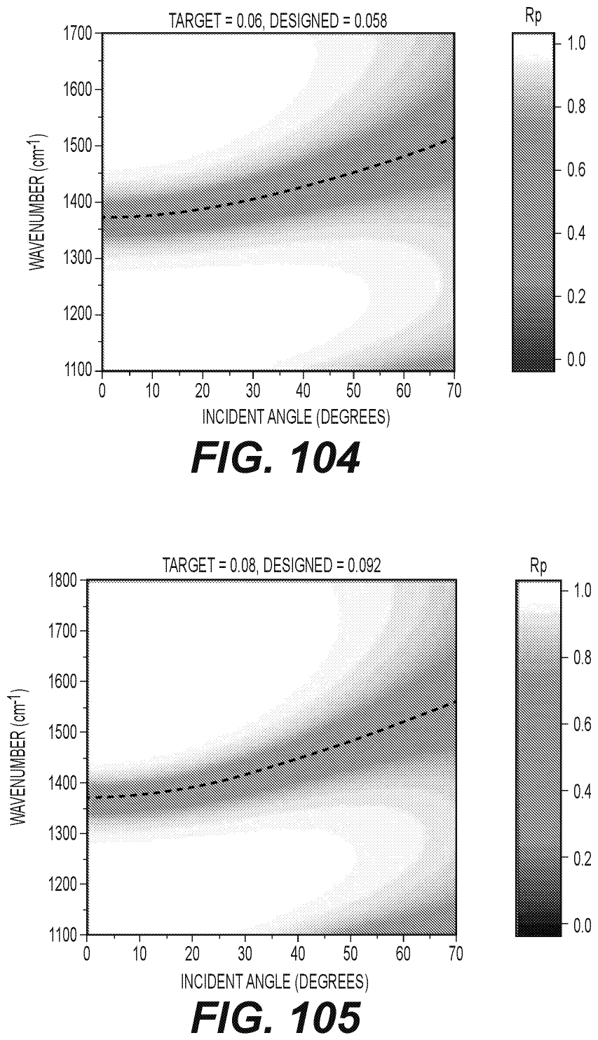

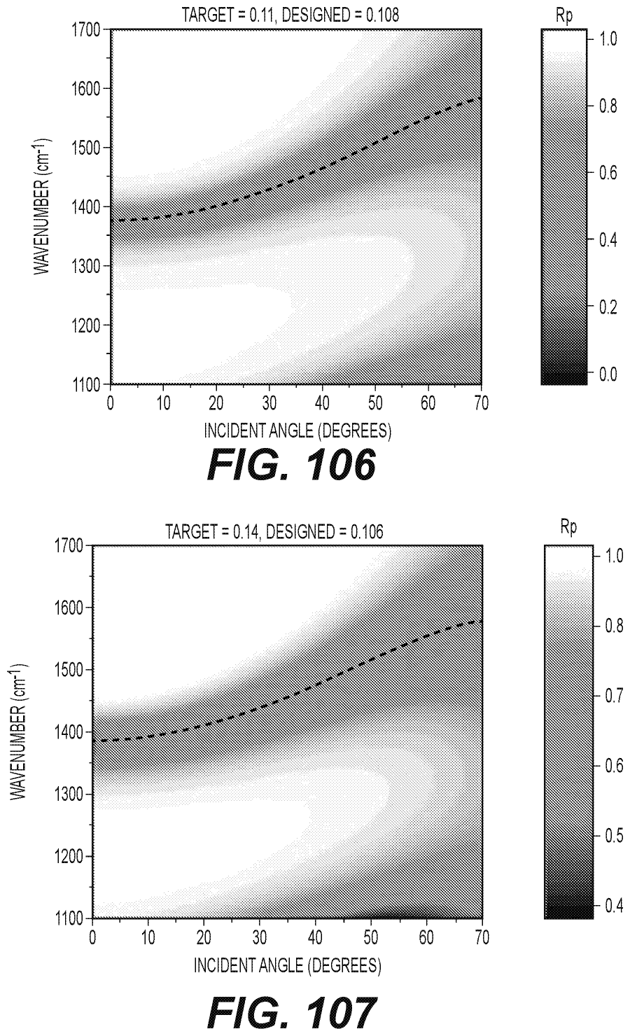

Section 3. Band curvature of Tamm plasmon polariton-absorbers and Tamm hybrid polariton-absorbers. While the spectral properties can be matched by having more distributed Bragg reflector layers in Tamm plasmon polariton-absorbers, the angular dispersions of Tamm plasmon polaritons are fundamentally limited to a narrow range with distributed Bragg reflector composed of Ge and AlOx. Here, it is shows that different band curvatures are targeted and the resultant band curvatures are always between 0.058 and 0.094 cm⁻¹/degree², as shown in FIG. 102-FIG. 107. Thus, hybridization provides a unique way to flatten the dispersion for applications where non-dispersive properties are ideal.

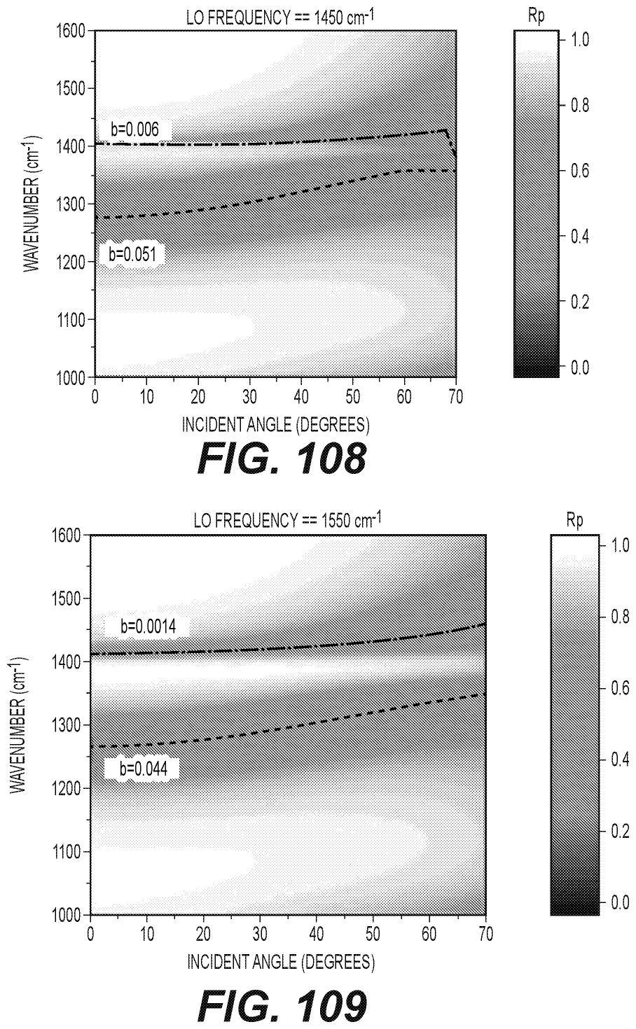

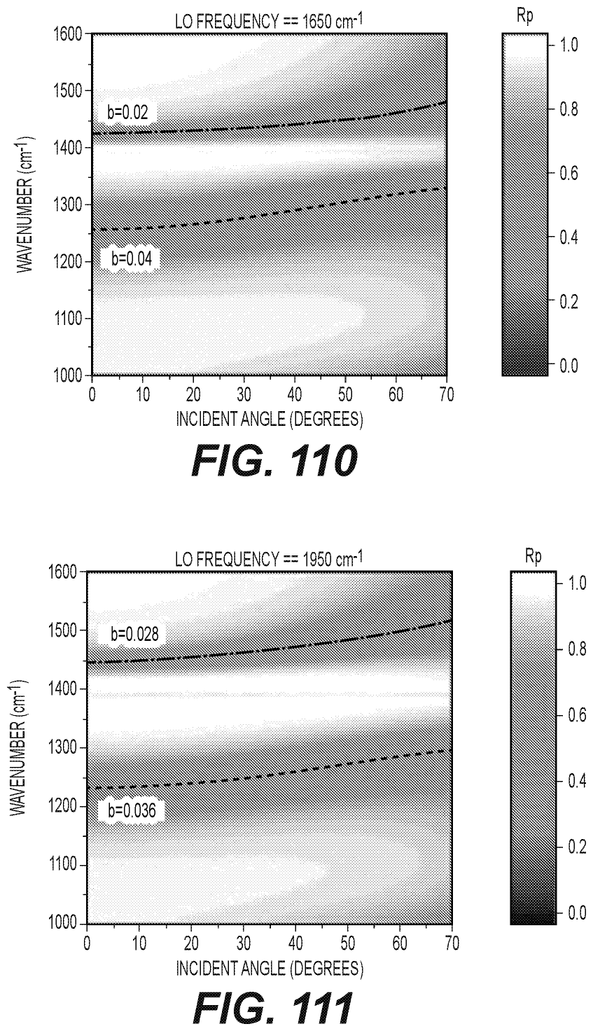

The band curvature was then analyzed from a material dispersion perspective. For that purpose, the structure of 100 nm thick hBN over the Tamm plasmon polariton-absorber design was used, and the longitudinal optical phonon frequencies of hBN were artificially modified to study how the Tamm hybrid polariton-absorber band curvature changes. It is found that fast dispersing materials, i.e., closely spaced transverse optical (TO) and longitudinal optical (LO) phonon frequencies, further decrease the band curvature of Tamm hybrid polariton-absorbers, as shown in FIG. 108-FIG. 111. Notably, the dispersion of the system is overall dominated by the Tamm plasmon polariton component (band curvature of 0.058 cm⁻¹/degree²), which is much more dispersive than the Tamm phonon polariton component (˜0.01 cm⁻¹/degree²).

Section 4. Band curvature of Tamm plasmon polariton-absorbers and Tamm hybrid polariton-absorbers. Herein, the implication of the band curvature upon applications where a range of incident angles will be considered simultaneously is discussed. For any metamaterial with angular dispersion, e.g., quasi bound states in the continuum (Yang S et al. Nano Letters, 2022, 22(20), 8060-8067; Leitis A et al. Science Advances 2019, 5, eaaw2871), directional thermal emitters, the spectrum collected is a combination of different incident angles. For instance, wavelength-selective absorbers can be used as wavelength-selective thermal emitters for filterless chemical sensing and infrared beacons, and the emitted light at different incident angles can be collected with parabolic mirrors to increase the signal intensity. Typical parabolic mirrors have Numerical apertures of 0.5-0.7, indicating a collecting angle of ±30° and ±45°.

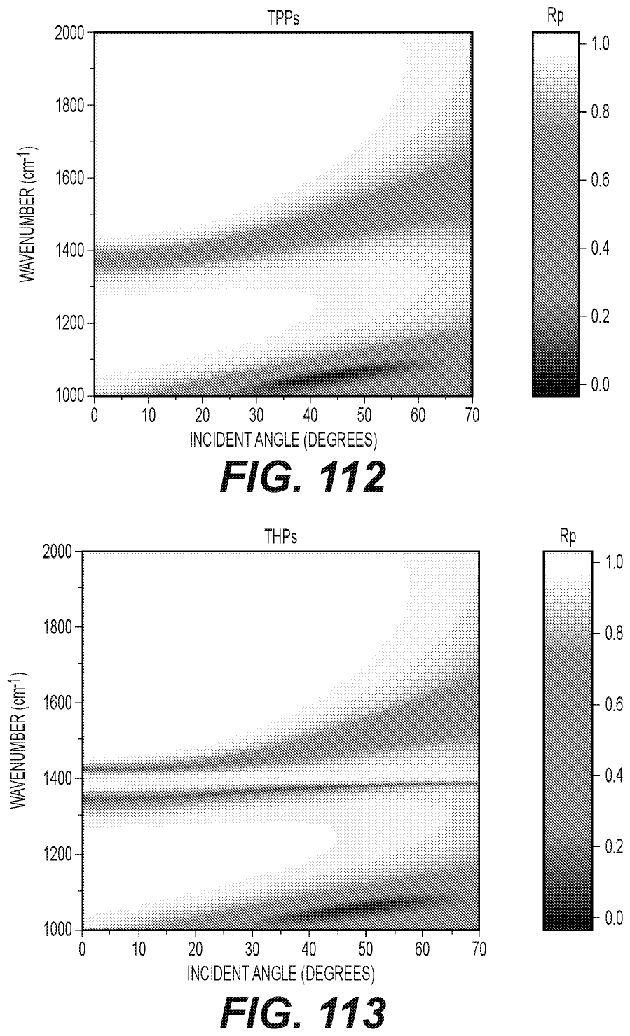

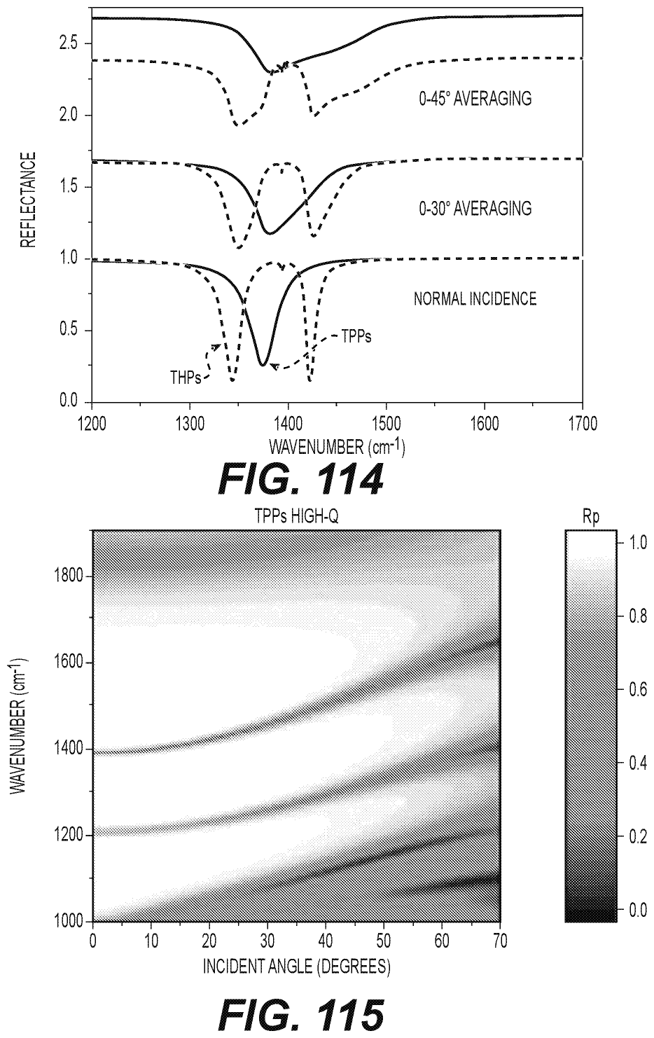

Firstly, Tamm plasmon polariton-absorbers with FWHM of 38 cm⁻¹ at the normal incident angle, as shown in FIG. 112, are considered. The convoluted spectral of collecting angle of ±30° and ±45° become significantly broadened, and the FWHMs are increased to 61 cm⁻¹ and 100 cm⁻¹, respectively (FIG. 114). However, for the same structure, when a 100 nm thick hBN is added to form Tamm hybrid polaritons, the band curvature is reduced significantly (FIG. 113). Quantitively, the FWHMs of lower polariton branch (upper polariton branch) at the normal incident angle, 300° and +45° collecting angles are: 24, 31, 43 cm⁻¹ (12, 29, 54 cm⁻¹).

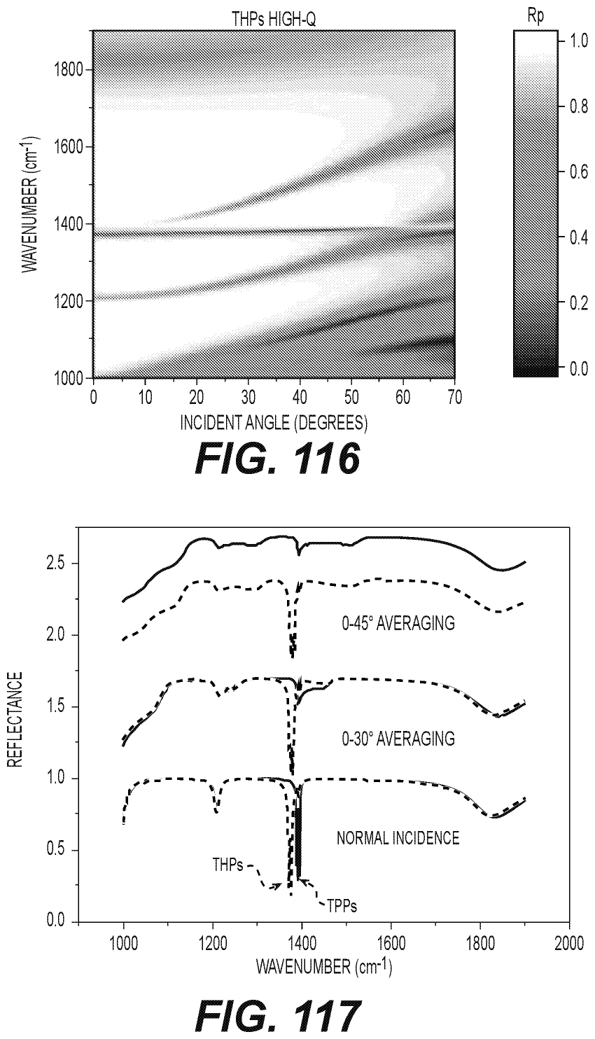

Next, a Tamm plasmon polariton-absorber featuring high Q-factor, with a FWHM of only 5.8 cm⁻¹ (FIG. 115) was considered. The spectral become suppressed and the resonance is nearly indistinguishable for collecting angle of ±30° and ±45°, as shown in FIG. 117. However, for the corresponding Tamm hybrid polaritons (FIG. 116), the lower polariton branch, which is the less dispersive one, remains clear even for ±45° collecting angle.

Section 5. The influence of anisotropy of hBN on the system. Hexagonal boron nitride (hBN) is a hyperbolic material in the upper and lower Reststrahlen band, and volume-confined hyperbolic modes can be supported by hBN. However, all the properties discussed herein are not related to the hyperbolicity of hBN. To discuss the role of anisotropy in the system, the Tamm phonon polariton and Tamm-hybrid were modeled with two kinds of hBN: the actual hBN with dielectric function from reference (Giles A J et al. Nature materials 2018, 17, 134), and artificially isotropic hBN by assigning ε_{z}=ε_{xy}, and the distributed Bragg reflector structure used here is from FIG. 75-FIG. 85.

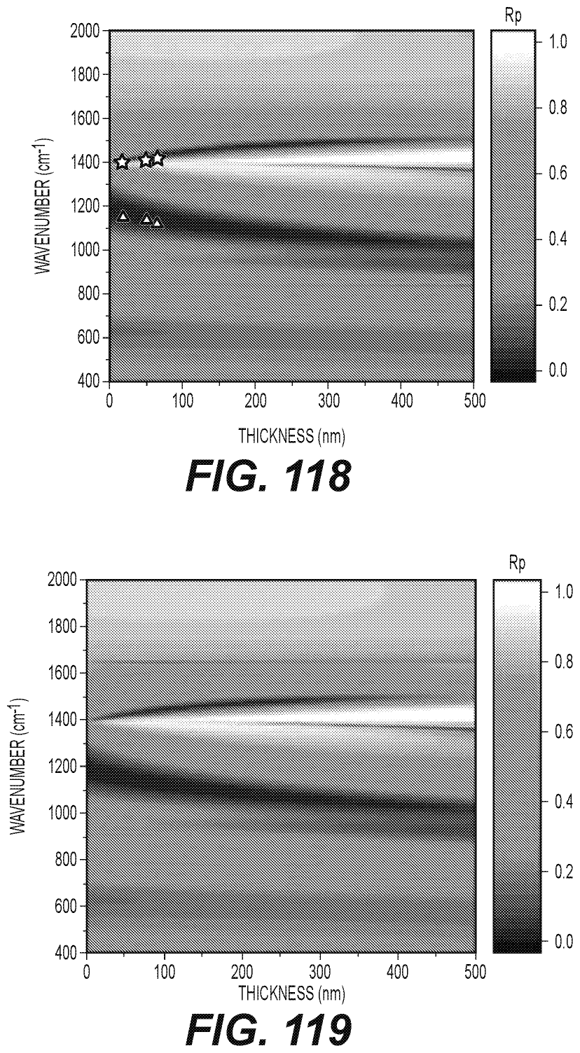

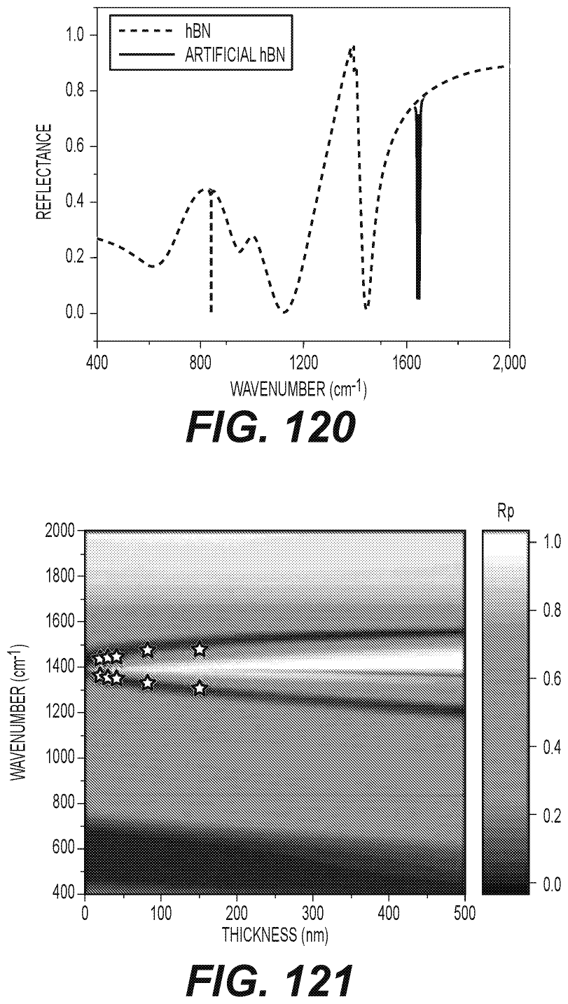

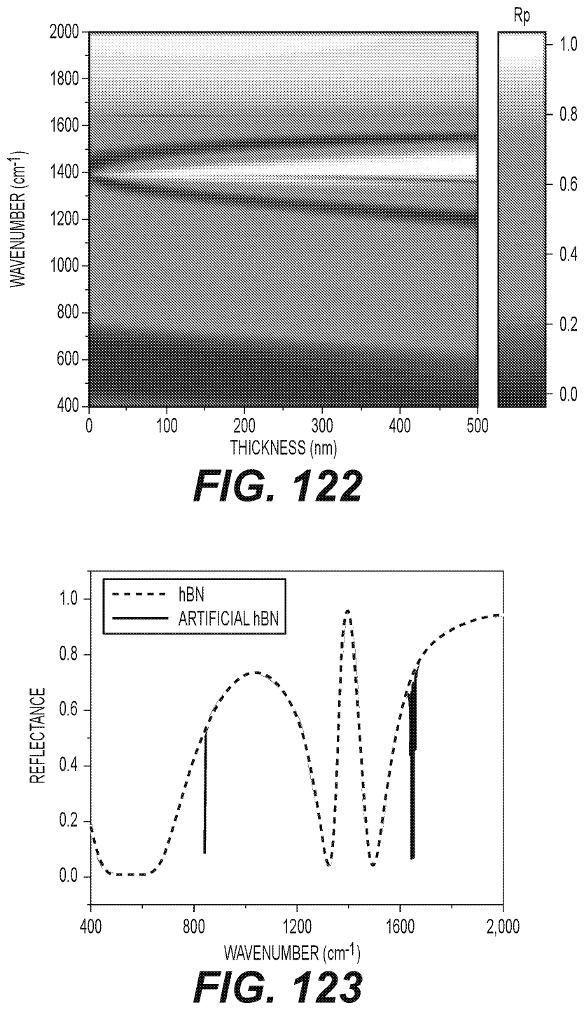

First, the influence at an incident angle of 300 of p-polarized light is discussed. For Tamm phonon polariton resonances, the responses of hBN and artificial hBN are nearly identical, as shown in FIG. 118, FIG. 119, and FIG. 120. Since the Berreman mode can only be excited when the permittivity along the z-axis is approaching zero (near longitudinal optical phonon) (Zhu H et al. Advanced Optical Materials, 2021, 9(21). 2100645), the isotropic model cannot predict the true response. For Tamm hybrid polaritons, the differences between isotropic and anisotropic models are similar to the Tamm phonon polariton case, as shown in FIG. 121-FIG. 123.

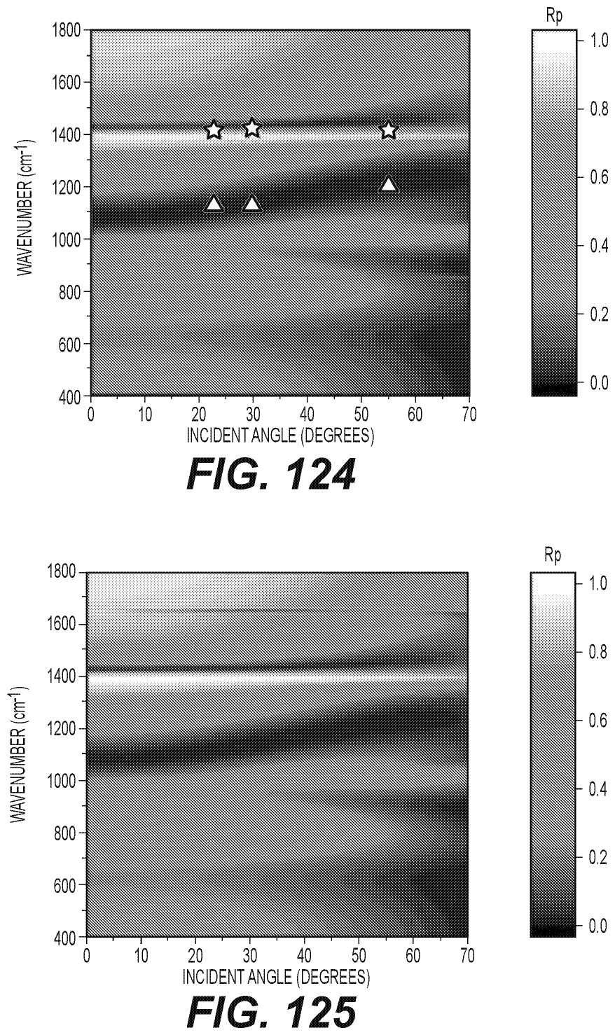

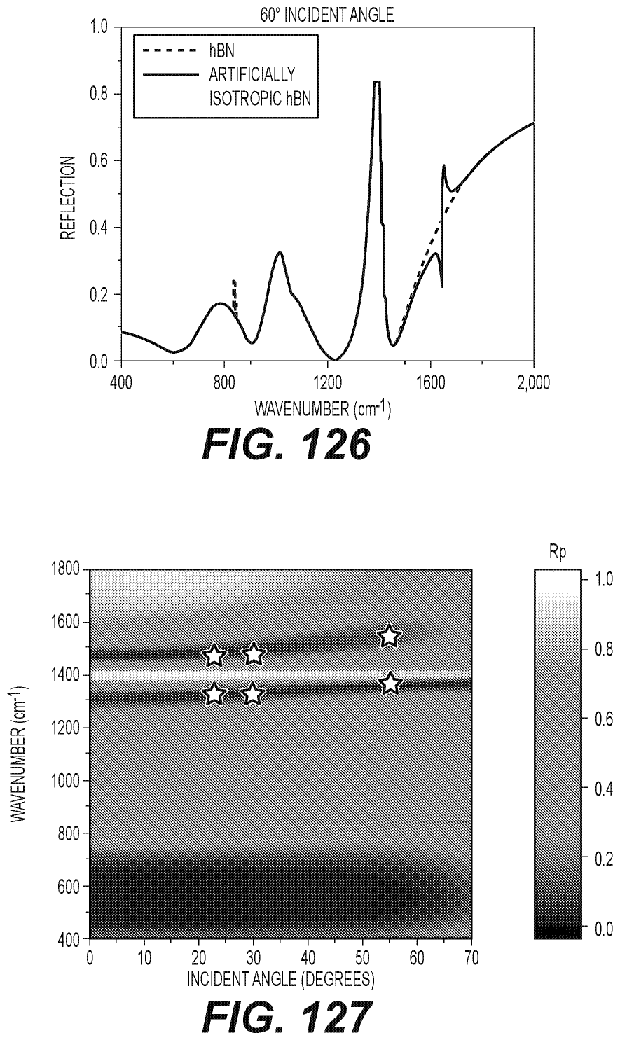

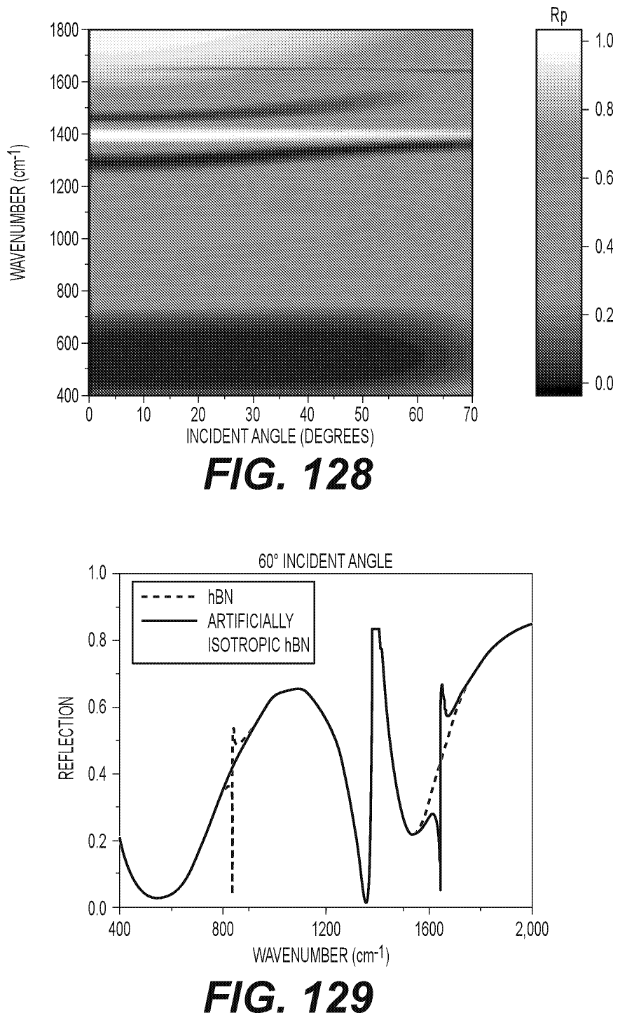

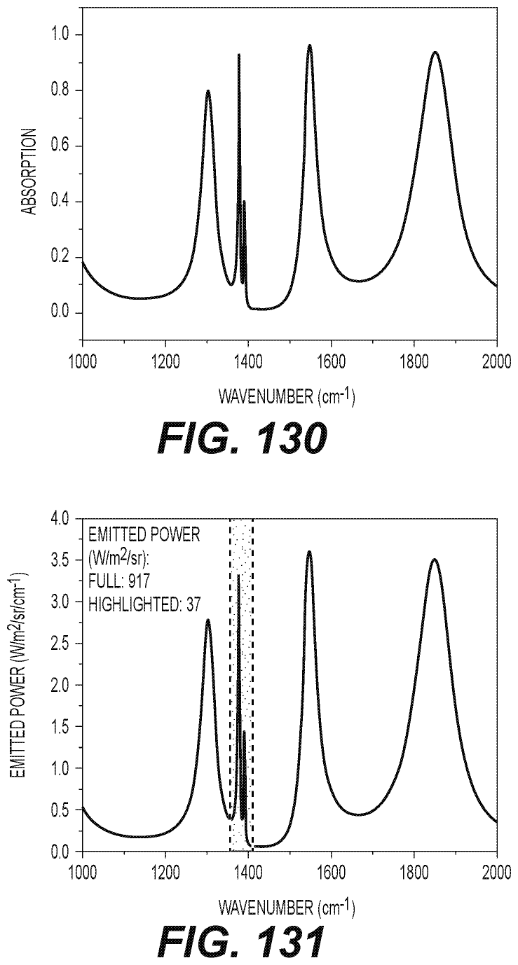

While the responses of hBN and artificially isotropic hBN in Tamm polariton structures are nearly identical at low incident angle (30°), it is no longer the same case at high incident angles (600 here). Here, the Tamm hybrid polaritons and Tamm phonon polaritons with differently modeled hBN were calculated at different incident angles (FIG. 124-FIG. 129). Besides Berreman modes that are axis-selective, the spectra of artificially isotropic hBN also deviate from the true model when approaching the longitudinal optical phonon frequencies, and the deviation appears in both Tamm phonon polaritons and Tamm hybrid polaritons. Thus, the fact that hBN is an anisotropic material cannot be ignored and therefore the response cannot be simply approximated with simple isotropic material, and the complicated anisotropic response further poses challenges to the structure design.

Section 6. Unavoidable transverse optical phonon of Tamm phonon polariton structure and the influence. Since the transverse optical phonon of hBN at around 1400 cm⁻¹ is along the x-y plane, such a phonon absorption mode will be present as long as the hBN is included in the structure. Thus, the influence of such an unavoidable mode on applications is evaluated. It was assumed that the multi-band absorber is used as a thermal emitter light source with the spectral bar-coding application (FIG. 88), and the working temperature is assumed to be 600° C. As such, the spectral emitted power can be calculated by multiplying the absorption by the emitted power of a blackbody, resulting in FIG. 131. By integrating the whole frequency range, it was found that the emitted power between 1000 cm⁻¹ and 2000 cm⁻¹ is 917 W/m²/sr. Then, only the range between 1380 and 1410 cm⁻¹ was integrated, where the Fabry Parot and transverse optical phonon absorption (emission) lines are present, leading to an emitted power of 37 W/m²/sr, which only accounts for ˜4% of the full emitted power. As such, those additional yet unavoidable absorption lines can be neglected in most applications.

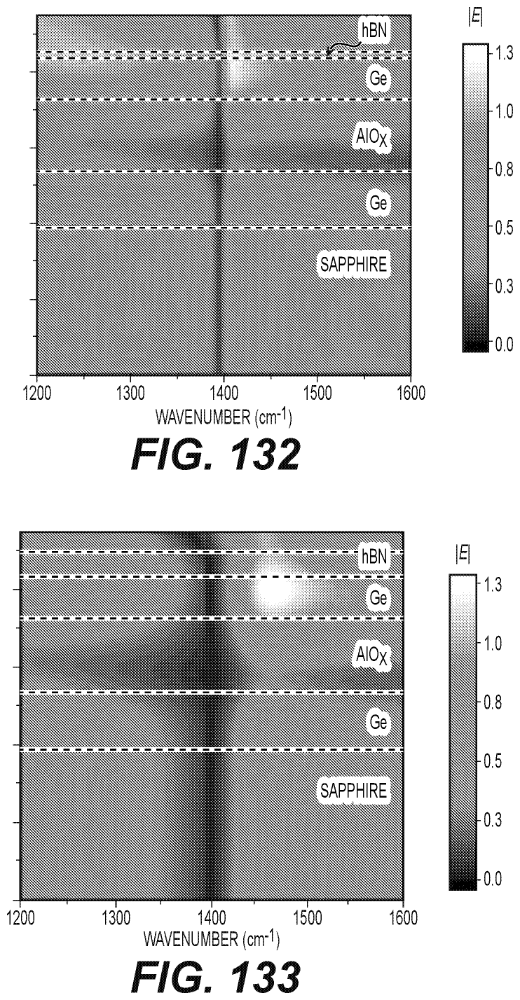

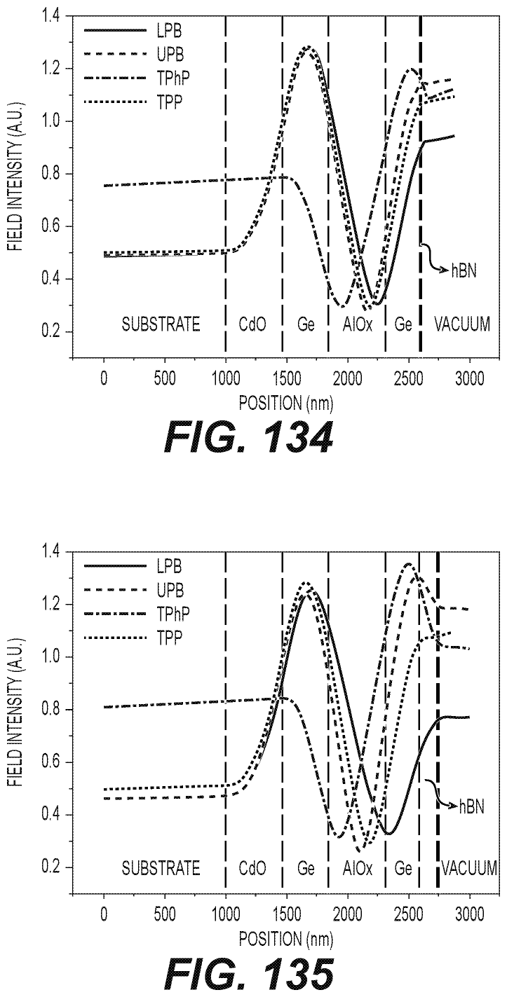

Section 7. Field distribution with different hBN thicknesses. Here, the field distribution of Tamm polariton absorbers is discussed. With thicker hBN, the field intensity becomes stronger, as shown in FIG. 132-FIG. 133, and in FIG. 134-FIG. 135. As such, the field distribution overlapping with the Tamm plasmon polariton mode (FIG. 134-FIG. 135) increases with thicker hBN, thus inducing stronger light-matter interaction and a more significant resonance splitting (FIG. 141).

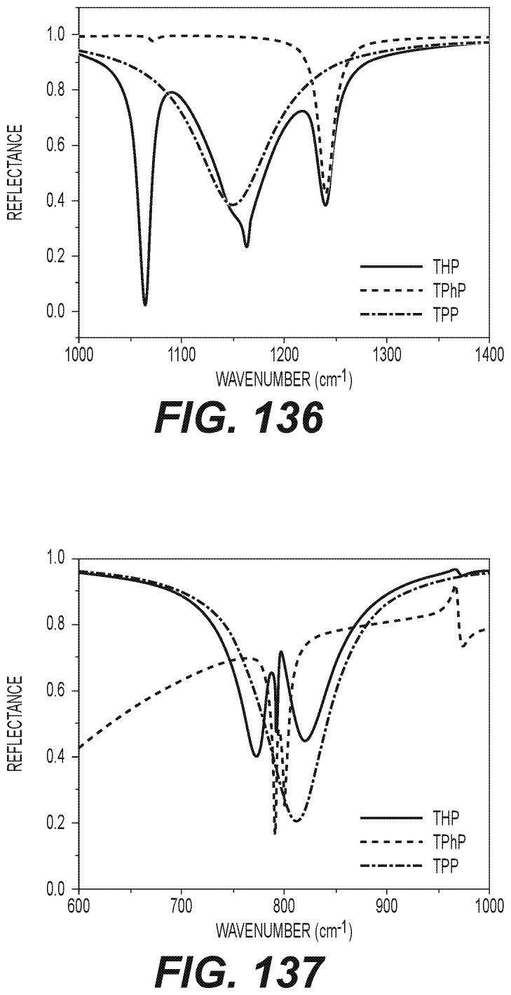

Section 8. Tann hybrid polariton-absorbers with different polar materials. Here, it is illustrated that Tamm hybrid polariton-absorbers can be realized with other polar materials, such as silicon dioxide and silicon carbide. For the case of SiO₂, the same geometry as in the main text was used: SiO₂-distributed Bragg reflector-CdO-substrate, because high-quality SiO₂ can be deposited with atomic layer deposition (ALD) on many substrates (Yoo D et al. Nature Photonics 2021, 15, 125-130). Tamm hybrid polariton spectrum is clearly different from Tamm plasmon polaritons or Tamm phonon polaritons, indicating a modal hybridization (FIG. 136). Noticeably, the Berreman mode (˜1240 cm⁻¹) is excited since SiO₂ is an isotropic media.

For the case of SiC, a different geometry was used: distributed Bragg reflector-CdO—SiC-silicon, because of the ability to deposit 3C—SiC on silicon substrates via CVD. Still, Tamm hybrid polaritons and coupled resonances are observed (FIG. 137). Therefore, the Tamm hybrid polaritons can be formed by various phonon-polariton supporting materials for applications in different frequency ranges.

Section 9. Comparisons among different modes supported in planar structures. Comparisons are summarized in Table 7.

TABLE 7
Comparisons among different modes supported by planar metasurfaces. SPP stands
for surface plasmon polaritons. Note: structures with similar numbers of layers
are compared. The angular dispersion is the b value in the main text.

| | | | Angular | | Demonstrated | |
|---|---|---|---|---|---|---|
| | | Normal | dispersion | | number of | |
| | | incident | (cm⁻¹/ | Spectral | designable | |
| Modes | Coupling | angle | degree²) | designability | peaks | Q-factor |
| Tamm | No | Yes | 0.06-0.1 | Good | 1+ | Low |
| plasmon | | | | | | |
| polaritons^{a} | | | | | | |
| Tamm | No | Yes | 0.016 | Poor (Only | Single | High |
| phonon | | | | designable | | |
| polaritons^{b} | | | | within | | |
| | | | | Reststrahlen | | |
| | | | | band) | | |
| Tamm | Yes | No | Larger than | Poor (only at | 2+ | Similar to |
| plasmon | | | Tamm | surface | | Tamm |
| polariton + | | | plasmon | plasmon | | plasmon |
| surface | | | polaritons | polariton | | polaritons |
| plasmon | | | | frequencies) | | |
| polaritons^{c} | | | | | | |
| Tamm | Yes | Yes | Not | Good | 2 | Lower than |
| plasmon | | | reported | | | Tamm |
| polariton + | | | | | | plasmon |
| graphene^{d} | | | | | | polaritons |
| Tamm | Yes | Yes | 0.02-0.04 | Medium | 2+ | Higher than |
| plasmon | | | | (extended | | Tamm |
| polariton + | | | | outside of | | plasmon |
| Tamm | | | | Reststrahlen | | polaritons |
| phonon | | | | band) | | and lower |
| polaritons | | | | | | than Tamm |
| (here) | | | | | | phonon |
| | | | | | | polaritons |

^{a}He M et al. Nature Materials 2021, 20, 1663-1669; Kaliteevski M et al. Physical Review B 2007, 76, 165415
^{b}Juneau-Fecteau A et al. Applied Physics Letters 2019, 114, 141101
^{c}Buz̆avaitė-Vertelienė E et al. Nanophotonics 2021, 10, 1565-1571.
^{d}Hu J et al. Optics express 2019, 27, 18642-18652.

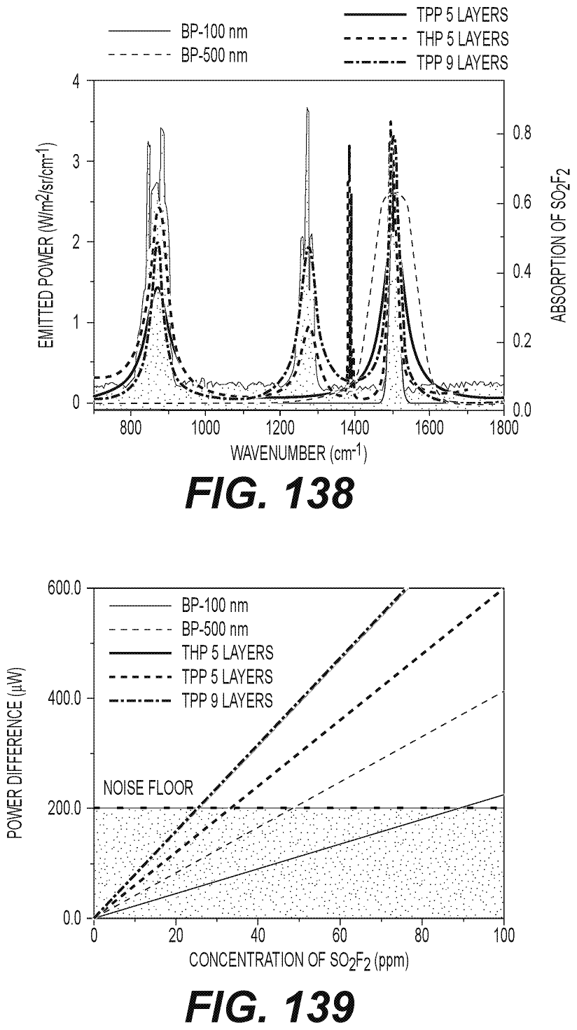

Section 10. Performances of Tamm polaritons for gas sensing. The performance of Tamm hybrid polaritons for non-dispersive infrared applications were theoretically evaluated following previous procedures. The principle of this calculation is: a certain working temperature (600° C.) of Tamm absorbers was assumed, making it work as a thermal emitter (Baranov D. G. et al. Nature materials, 2019, 18, 920-930). Then, the transmitted power through SO₂F₂ with different concentrations was calculated, which will be detected by a dual channel pyroelectric detector with a responsivity of 150000 V/W (https://www.boselec.com/wp-content/uploads/Linear/Heimann/HeimannLiterature/Heimann-Pyros-11-27-19.pdf). In general, the power change in a non-dispersive infrared device can be calculated by integrating absorption in the spectral domain, and the gas absorption is determined by the Beer-Lambert Law:

$$Transmission with {SO}_{2} {F}_{2} = exp ( - kcL ) \qquad Eq . ( S1 )$$

where k is the absorption coefficient (estimated from data from National Institute of Standards and Technology) (https://webbook.nist.gov/chemistry/#; https://webbook.nist.gov/cgi/cbook.cgi?ID=C2699798&Units=SI&Type=IR-SPEC&Index=0 #IR-SPEC), c is gas concentration and L is the sample optical path length (here assumed to be 10 cm). Based on this principle, the detector reading with different devices was calculated: Tamm plasmon polariton 5-layers (TPP-5). Tamm plasmon polariton 9-layers (TPP-9), Tamm hybrid polariton 5-layers (THP-5) from the main text. In addition, the performance was benchmarked with that of a standard non-dispersive infrared device featuring bandpass filter (BP) in the mid-infrared, which is centered on only one of the vibrational modes (1504 cm⁻¹) with 100 nm and 500 nm bandwidths, as shown in FIG. 138.

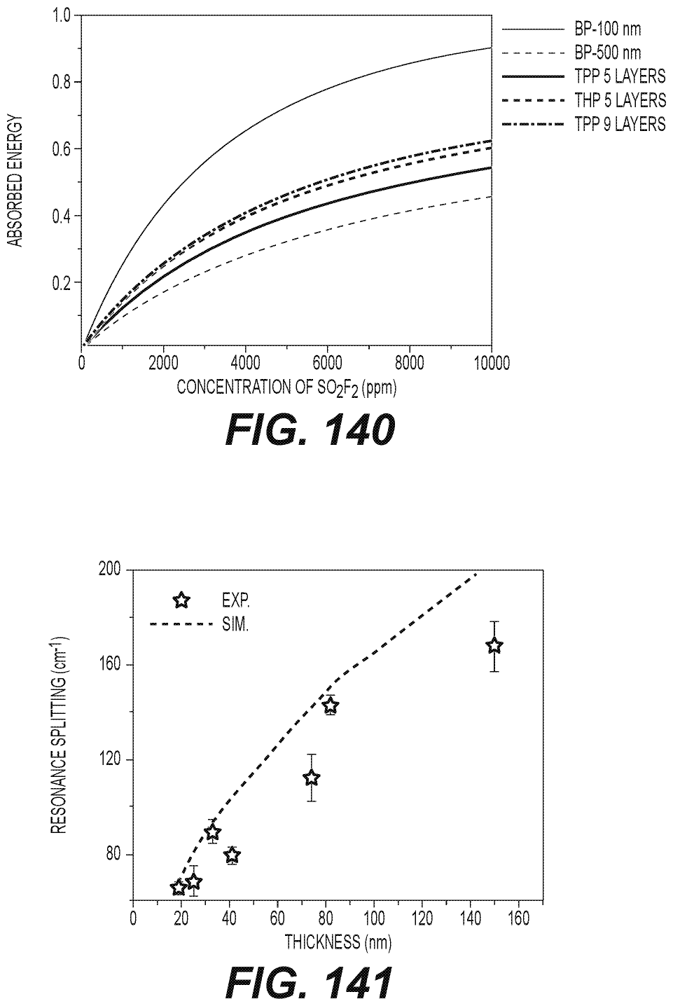

The performances are determined with two figures of merits: (1) sensitivity (detection limit), i.e., the minimum amount of sulfuryl fluoride can be detected; and (2) selectivity, i.e., relative power change when 1% of sulfuryl fluoride is present. Since the narrow bandpass filter only passes a small frequency range, a significant amount of energy that could be used to indicate the presence of gas is wasted, leading to the poorest detection limit (89 ppm) (FIG. 139). Meanwhile, since the bandwidth nearly fully falls within the chemical absorption band, it results in the best selectivity (90%, FIG. 140). To enhance the detection limit, more energy in the absorption band is included, and a wider bandwidth bandpass filter indeed improve the detection limit to 47 ppm. However, the wide bandwidth bandpass filter leads to the worst selectivity (45%) for the wide bandwidth. When the bandpass filter only features one transmission band, the trade-off between sensitivity and selectivity is avoidable.

To improve the detection limit while maintaining selectivity, Tamm emitters with emission frequencies overlapped with three vibrational modes simultaneously were employed, and the resulting detection limits from all cases are improved from single-band bandpass filter s, with the selectivity improved from 500 nm bandpass filter. It was found that the THP-5 provides nearly identical performance of TPP-9 design, which are both ˜25 ppm. In terms of selectivity, the relative power change per 1% gas is 62% and 60% for TPP-9 and THP-5, respectively. Notably, the infrared bandpass filters are mostly based on thin-film structures, and the fabrication of bandpass filter can involve over 8 μm thick (20+layers) material depositions (Zhou S et al. Coatings 2021, 11, 803), which are significantly higher than Tamm hybrid polariton devices. In summary, the THP-5 design provides an equivalent detection limit compared to TPP-9, which are the best in this set of comparisons. It is important to note that those multi-frequency emitters simultaneously enhance selectivity and detection limit compared to wide bandpass filter, which is not achievable with single-band bandpass filter s.

The designed structural parameters are listed below. Note that all structures employ alternating Ge and ZnSe layers assuming constant refractive indexes of 4.0 and 2.25, respectively.
TPP 5 layers: 572(Ge) 732 (ZnSe) 190(Ge) 391(ZnSe) 356(Ge) 400(CdO of 1.07×1020 cm-3). Total thickness of 2375 nm
TPP 9 layers: 516(Ge) 741(ZnSe) 119(Ge) 530(ZnSe) 545(Ge) 621(ZnSe) 244(Ge) 559(ZnSe) 429 (Ge) 400 (CdO of 6.9×1020 cm-3). Total thickness of 4700 nm
THP 5 layers: 320 (hBN) 656(Ge) 370(ZnSe) 843(Ge) 950(ZnSe) 545(Ge) 400 (CdO of 0.26×1020 cm-3). Total thickness of 4084 nm

### Example 6

An anisotropic scattering matrix method is utilized to describe the observable metrics for a multilayer planar semiconductor heterostructure. This avoids singularities associated with transfer matrix methods in lossy media, allowing the optimization algorithm to explore the parameter space robustly. This approach also allows both isotropic and uniaxial materials to be investigated.

Loss metrics were developed to optimize the design of mid-infrared emitters in the presence of target gases (e.g., those which are desired to be detected) and non-target gases (e.g., those which are desired to avoid detection). The optimization procedure aims to minimize the numerical value of the loss which has two components. The first, which is positive, measures the degree of overlap between the emissivity and the non-target gases. This is defined as the sum of the convolution of the emissivity and each of the non-target gas spectra weighted by the relative concentration of each gas at the working point. The second contribution measures the overlap between the emissivity and the target gas spectrum, and is the negation of the convolution of the two spectra. To compensate for the smaller emissivity in the non-target region as the optimization proceeds, the positive component is weighted with a tunable hyperparameter c which ensures both goals are achieved. The total loss is the sum of these quantities.

The Tensorflow ecosystem's excellent data processing libraries are exploited to stream molecular spectra from a local database built using the HITEMP and HITRAN open source libraries. Using Tensorflow Transform and Apache Beam it is possible to lazily stream in multiple spectrally dense molecular absorption curves with minimal overhead.

Tensorflow's automatic differentiation tools were used to rapidly optimize the loss metric using Newton's method. This allows the developed complex loss metric, as well as the individual convolution metrics for each gas, to be easily tracked.

### Example 7

For emitter/detector pairing, in some examples, the same design approach can be used for both, so there is no difference between the results for the emitter and detector given the same initial conditions.

In some examples, for emitter/detector pairing, the optimization approach for the detector can differ from that of the emitter. For example, rather than using the spectra to optimize the detectors, the emitter emission profiles can be used. Taking the same approach, the overlap with the matched emitter will be maximized while minimizing overlap with others. The optimization procedure will again minimize the numerical value of the two component loss. The positive contribution will, this time, measure overlap between the detector and unmatched emitters (a sum of the convolution of the detector's emissivity and each unmatched emitter's emissivity). The negative contribution is the negation of the convolution of the matched detector and emitter emissivities. As before, a hyperparameter will be introduced to weight the positive contributions. Compared to re-using the detector designs this will mean less signal is wasted as the detector peaks should end up being broader than the emitter ones.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

1. A Tamm polariton emitter comprising:
an aperiodic distributed Bragg reflector;
a layer comprising a conductive and/or polaritonic material; and
a substrate;
wherein the aperiodic distributed Bragg reflector is disposed on the layer of the conductive and/or polaritonic material;
wherein the layer of the conductive and/or polaritonic material is disposed on the substrate such that the layer of the conductive and/or polaritonic material is sandwiched between the substrate and the aperiodic distributed Bragg reflector, or wherein the aperiodic distributed Bragg reflector is disposed on the substrate such that the aperiodic distributed Bragg reflector is sandwiched between the substrate and the layer of the conductive and/or polaritonic material; and
wherein the aperiodic distributed Bragg reflector comprises a plurality of alternating layers of a first material having a first refractive index and a second material having a second refractive index, wherein the first refractive index and the second refractive index are different.

2.-24. (canceled)

25. The Tamm polariton emitter of claim 1, wherein the total number of layers is from 3 to 10,000.

26. The Tamm polariton emitter of claim 1, wherein each of the plurality of layers independently has an average thickness of from 1 nanometer (nm) to 100 millimeters (mm).

27. The Tamm polariton emitter of claim 1, wherein the Tamm polariton emitter is configured to selectively emit radiation at one or more frequencies.

28. (canceled)

29. (canceled)

30. The Tamm polariton emitter of claim 27, wherein the Tamm polariton emitter is configured to selectively emit radiation in the infrared spectral region.

31. (canceled)

32. The Tamm polariton emitter of claim 1, wherein the Tamm polariton emitter is configured to selectively emit radiation in the short-to long-wave infrared spectral region, in the mid-to long-wave infrared region, in the long-wave infrared region to the telecommunications band region, or a combination thereof.

33. (canceled)

34. (canceled)

35. (canceled)

36. (canceled)

37. (canceled)

38. (canceled)

39. A method of use of the Tamm polariton emitter of claim 1 in a free-space communication application, as a beacon, in a bar-code application, in an encryption application, in a sensing application, or a combination thereof.

40. (canceled)

41. (canceled)

42. (canceled)

43. A non-dispersive infrared sensor comprising:
the Tamm polariton emitter of claim 1, wherein the Tamm polariton emitter is configured to selectively emit radiation, wherein at least a portion of the radiation emitted by the Tamm polariton emitter corresponds to a rotational or vibrational resonance frequency of an analyte of interest; and
a detector configured to receive an electromagnetic signal from the Tamm polariton emitter and/or the analyte of interest.

44. The sensor of claim 43, further comprising a fluid cell extending from a proximal end to distal end and having an inlet and an outlet, wherein the Tamm polariton emitter is disposed towards the proximal end of the fluid cell and the detector is disposed towards the distal end of the fluid cell, such that, when the sensor is assembled together with a fluid sample, the fluid cell is configured to contain the fluid sample and the detector is configured to receive an electromagnetic signal from the Tamm polariton emitter and/or the fluid sample.

45.-51. (canceled)

52. The sensor of claim 44, wherein the fluid sample comprises a gaseous sample.

53. The sensor of claim 43, wherein the analyte of interest comprises a gas.

54. (canceled)

55. The sensor of claim 43, wherein the analyte of interest comprises a plurality of analytes, and:
the Tamm polariton emitter is configured to selectively emit radiation at a plurality of frequencies;
and wherein at least a portion of each of the plurality of frequencies corresponds to a rotational or vibrational resonance frequency of each of the plurality of analytes of interest, such that the sensor can detect the plurality of analytes simultaneously.

56. (canceled)

57. The sensor of claim 43, wherein the analyte of interest comprises a single analyte, and:
the Tamm polariton emitter is configured to selectively emit radiation at a plurality of frequencies;
and wherein at least a portion of each of the plurality of frequencies corresponds to a plurality of rotational or vibrational resonance frequencies of the analyte of interest, such that the sensor can detect the analyte of interest with high sensitivity.

58.-85. (canceled)

86. (canceled)

87. The Tamm polariton emitter of claim 1, wherein the layer of the conductive and/or polaritonic material comprises a metal, a transparent conducting oxide, a group III-V semiconductor, or a combination thereof.

88. The Tamm polariton emitter of claim 1, wherein the layer of the conductive and/or polaritonic material is disposed on the substrate such that the layer of the conductive and/or polaritonic material is sandwiched between the substrate and the aperiodic distributed Bragg reflector.

89. The Tamm polariton emitter of claim 1, wherein the aperiodic distributed Bragg reflector is disposed on the substrate such that the aperiodic distributed Bragg reflector is sandwiched between the substrate and the layer of the conductive and/or polaritonic material.

90. (canceled)

91. (canceled)

92. The Tamm polariton emitter of claim 1, further comprising a layer of a polar material disposed on top of the distributed Bragg reflector, such that the distributed Bragg reflector is sandwiched between the layer of the conductive and/or polaritonic material and the polar material.

93. The Tamm polariton emitter of claim 1, wherein the first material comprises Ge, wherein the second material comprises an aluminum oxide or ZnSe, or a combination thereof.

94. A sensor comprising the Tamm polariton emitter of claim 1.

95. The sensor of claim 43, wherein the sensor is filterless.
